(19) United States
(12) Patent Application Publication
(10) Pub. No.: US 2022/0089811 A1
(43) Pub. Date: Mar. 24, 2022

(54) COMPOSITION FOR FILM FORMATION, RESIST COMPOSITION, RADIATION-SENSITIVE COMPOSITION, METHOD FOR PRODUCING AMORPHOUS FILM, RESIST PATTERN FORMATION METHOD, COMPOSITION FOR UNDERLAYER FILM FORMATION FOR LITHOGRAPHY, METHOD FOR PRODUCING UNDERLAYER FILM FOR LITHOGRAPHY, AND CIRCUIT PATTERN FORMATION METHOD

(71) Applicant: Mitsubishi Gas Chemical Company, Inc., Tokyo (JP)

(72) Inventors: Tadashi OMATSU, Hiratsuka-shi, Kanagawa (JP); Hiroaki YAMAMOTO, Hiratsuka-shi, Kanagawa (JP); Junya HORIUCHI, Hiratsuka-shi, Kanagawa (JP); Takashi MAKINOSHIMA, Hiratsuka-shi, Kanagawa (JP); Masatoshi ECHIGO, Chiyoda-ku, Tokyo (JP)

(21) Appl. No.: 17/421,668

(22) PCT Filed: Jan. 10, 2020
(86) PCT No.: PCT/JP2020/000764

§ 371 Date: Jul. 8, 2021

(30) Foreign Application Priority Data
Jan. 11, 2019 (JP) 2019-003567

(51) Int. Cl. C08G 61/12; C08L 61/04; G03F 7/16; G03F 7/20; G03F 7/38; G03F 7/40; G03F 7/32

(52) U.S. Cl. CPC C08G 61/12; C08L 61/04; G03F 7/162; G03F 7/322; G03F 7/38; G03F 7/40; G03F 7/2006

(57) ABSTRACT

A composition for film formation containing a polycyclic polyphenolic resin having repeating units derived from at least one monomer selected from the group consisting of aromatic hydroxy compounds represented by the following formulae (1A) and (1B),
wherein the repeating units are linked to each other by a direct bond between aromatic rings.

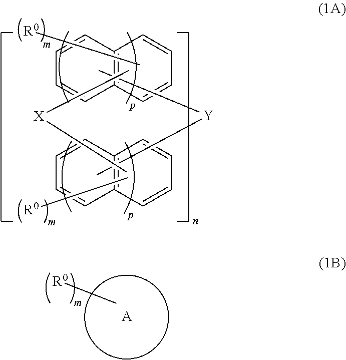

(In the formula (1A), X represents an oxygen atom, a sulfur atom, a single bond, or non-crosslinked state and Y represents a 2n-valent group having 1 to 60 carbon atoms, or a single bond, wherein when X is non-crosslinked state, Y represents the 2n-valent group; in the formula (1B), A represents a benzene ring or a fused ring; in the formulas (1A) and (1B), each R⁰ is independently an alkyl group having 1 to 40 carbon atoms and optionally having a substituent, an aryl group having 6 to 40 carbon atoms and optionally having a substituent, an alkenyl group having 2 to 40 carbon atoms and optionally having a substituent, an alkynyl group having 2 to 40 carbon atoms, an alkoxy group having 1 to 40 carbon atoms and optionally having a substituent, a halogen atom, a thiol group, or a hydroxy group, wherein at least one R⁰ is a hydroxy group, and each m is independently an integer of 1 to 9; and N is an integer of 1 to 4, and each p is independently an integer of 0 to 3.)

### TECHNICAL FIELD

The present invention relates to a composition for film formation, a resist composition, a radiation-sensitive composition, a method for producing an amorphous film, a resist pattern formation method, a composition for underlayer film formation for lithography, a method for producing an underlayer film for lithography, and a circuit pattern formation method.

### BACKGROUND ART

In the production of semiconductor devices, fine processing is practiced by lithography using photoresist materials. In recent years, further miniaturization based on pattern rules has been demanded along with increase in the integration and speed of LSI. Lithography using light exposure, which is currently used as a general purpose technique, is approaching the limit of essential resolution derived from the wavelength of a light source.

The light source for lithography used upon forming resist patterns has been shifted to ArF excimer laser (193 nm) having a shorter wavelength from KrF excimer laser (248 nm). However, as the miniaturization of resist patterns proceeds, the problem of resolution or the problem of collapse of resist patterns after development arises. Therefore, resists have been desired to have a thinner film. If resists merely have a thinner film in response to such a demand, it is difficult to obtain the film thicknesses of resist patterns sufficient for substrate processing. Therefore, there is a need for a process of preparing a resist underlayer film between a resist and a semiconductor substrate to be processed, and imparting functions as a mask for substrate processing to this resist underlayer film in addition to a resist pattern.

Various resist underlayer films for such a process are currently known. Examples thereof can include resist underlayer films for lithography having the selectivity of a dry etching rate close to that of resists, unlike conventional resist underlayer films having a fast etching rate. As a material for forming such resist underlayer films for lithography, an underlayer film forming material for a multilayer resist process containing a resin component having at least a substituent that generates a sulfonic acid residue by eliminating a terminal group under application of predetermined energy, and a solvent has been suggested (see, for example, Patent Literature 1). Another example thereof can include resist underlayer films for lithography having the selectivity of a dry etching rate smaller than that of resists. As a material for forming such resist underlayer films for lithography, a resist underlayer film material comprising a polymer having a specific repeat unit has been suggested (see, for example, Patent Literature 2). Further examples thereof can include resist underlayer films for lithography having the selectivity of a dry etching rate smaller than that of semiconductor substrates. As a material for forming such resist underlayer films for lithography, a resist underlayer film material comprising a polymer prepared by copolymerizing a repeat unit of an acenaphthylene and a repeat unit having a substituted or unsubstituted hydroxy group has been suggested (see, for example, Patent Literature 3).

Meanwhile, as materials having high etching resistance for this kind of resist underlayer film, amorphous carbon underlayer films formed by chemical vapour deposition (hereinafter also referred to as “CVD”) using methane gas, ethane gas, acetylene gas, or the like as a raw material are well known. However, resist underlayer film materials that can form resist underlayer films by a wet process such as spin coating or screen printing have been demanded from the viewpoint of a process.

Recently, layers to be processed having a complicated shape have been desired to form a resist underlayer film for lithography. Thus, there is a demand for a resist underlayer film material that can form an underlayer film excellent in embedding properties or film surface flattening properties.

As for methods for forming an intermediate layer used in the formation of a resist underlayer film in a three-layer process, for example, a method for forming a silicon nitride film (see, for example, Patent Literature 4) and a CVD formation method for a silicon nitride film (see, for example, Patent Literature 5) are known. Also, as intermediate layer materials for a three-layer process, materials comprising a silsesquioxane-based silicon compound are known (see, for example, Patent Literature 6 and Patent Literature 7).

The present inventors have suggested an underlayer film forming composition for lithography comprising a specific compound or resin (see, for example, Patent Literature 8).

Various optical component forming compositions have been suggested, and, for example, an acrylic resin (see, for example, Patent Literatures 9 to 10) and polyphenol having a specific structure derived from an allyl group (see, for example, Patent Literature 11) have been suggested.

### CITATION LIST

### Patent Literature

Patent Literature 1: Japanese Patent Laid-Open No. 2004-177668
Patent Literature 2: Japanese Patent Laid-Open No. 2004-271838
Patent Literature 3: Japanese Patent Laid-Open No. 2005-250434
Patent Literature 4: Japanese Patent Laid-Open No. 2002-334869
Patent Literature 5: International Publication No. WO 2004/066377
Patent Literature 6: Japanese Patent Laid-Open No. 2007-226170
Patent Literature 7: Japanese Patent Laid-Open No. 2007-226204
Patent Literature 8: International Publication No. WO 2013/024779
Patent Literature 9: Japanese Patent Laid-Open No. 2010-138393
Patent Literature 10: Japanese Patent Laid-Open No. 2015-174877
Patent Literature 11: International Publication No. WO 2014/123005

### SUMMARY OF INVENTION

### Technical Problem

As mentioned above, a large number of film forming materials for lithography have heretofore been suggested. However, none of these materials achieve both of heat resistance and etching resistance at high dimensions. Thus, the development of novel materials is required.

Also, a large number of compositions intended for optical members have heretofore been suggested. However, none of these compositions achieve all of heat resistance, transparency and an index of refraction at high dimensions. Thus, the development of novel materials is required.

The present invention has been made in light of the problems described above. That is, it is an object of the present invention to provide a composition for film formation, a resist composition, a radiation-sensitive composition, and a composition for underlayer film formation for lithography, which can exhibit excellent heat resistance and etching resistance, and to provide a method for producing an amorphous film, a resist pattern formation method, a method for producing an underlayer film for lithography, and a circuit pattern formation method using these compositions.

### Solution to Problem

The present inventors have, as a result of devoted examinations to solve the above problems, found out that use of a polycyclic polyphenolic resin having a specific structure can solve the above problems, leading to completion of the present invention.

Specifically, the present invention includes the following aspects.

[1]

A composition for film formation comprising a polycyclic polyphenolic resin having repeating units derived from at least one monomer selected from the group consisting of aromatic hydroxy compounds represented by the following formulae (1A) and (1B),

wherein the repeating units are linked to each other by a direct bond between aromatic rings:

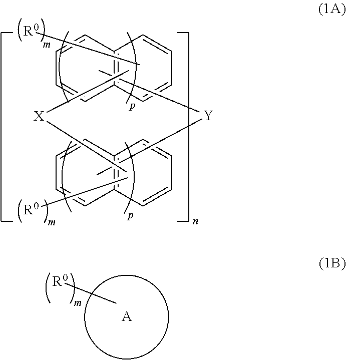

wherein X represents an oxygen atom, a sulfur atom, a single bond, or non-crosslinked state and Y represents a 2n-valent group having 1 to 60 carbon atoms, or a single bond, wherein when X is non-crosslinked state, Y represents the 2n-valent group; A represents a benzene ring or a fused ring; each R⁰ is independently an alkyl group having 1 to 40 carbon atoms and optionally having a substituent, an aryl group having 6 to 40 carbon atoms and optionally having a substituent, an alkenyl group having 2 to 40 carbon atoms and optionally having a substituent, an alkynyl group having 2 to 40 carbon atoms and optionally having a substituent, an alkoxy group having 1 to 40 carbon atoms and optionally having a substituent, a halogen atom, a thiol group, or a hydroxy group, wherein at least one R⁰ is a hydroxy group, and each m is independently an integer of 1 to 9; and n is an integer of 1 to 4, and each p is independently an integer of 0 to 3.
[2]

The composition for film formation according to [1], wherein the aromatic hydroxy compound represented by the formula (1A) is an aromatic hydroxy compound represented by the following formula (1):

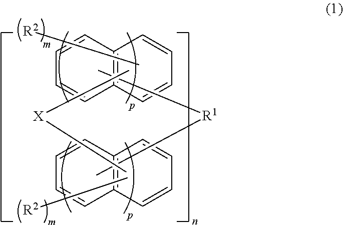

wherein X, m, n, and p are as defined in the formula (1A), R¹ is as defined in Y in the formula (1A), and each R² is independently an alkyl group having 1 to 40 carbon atoms, an aryl group having 6 to 40 carbon atoms, an alkenyl group having 2 to 40 carbon atoms, an alkynyl group having 2 to 40 carbon atoms and optionally having a substituent, an alkoxy group having 1 to 40 carbon atoms, a halogen atom, a thiol group, or a hydroxy group, wherein at least one R² is a hydroxy group.
[3]

The composition for film formation according to [2], wherein the aromatic hydroxy compound represented by the formula (1) is an aromatic hydroxy compound represented by the following formula (1-1):

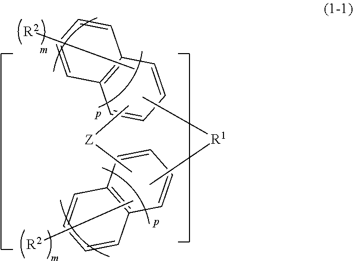

wherein Z represents an oxygen atom or a sulfur atom, and R¹, R², m, p and n are as defined in the formula (1).
[4]

The composition for film formation according to [3], wherein the aromatic hydroxy compound represented by the formula (1-1) is an aromatic hydroxy compound represented by the following formula (1-2):

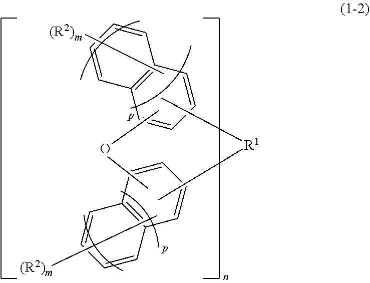

wherein R¹, R², m, p and n are as defined in the formula (1).
[5]

The composition for film formation according to [4], wherein the aromatic hydroxy compound represented by the formula (1-2) is an aromatic hydroxy compound represented by the following formula (1-3):

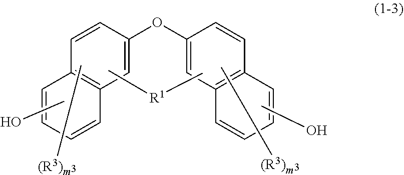

wherein R¹ is as defined in the formula (1), each R³ is independently an alkyl group having 1 to 40 carbon atoms, an aryl group having 6 to 40 carbon atoms, an alkenyl group having 2 to 40 carbon atoms, an alkynyl group having 2 to 40 carbon atoms and optionally having a substituent, an alkoxy group having 1 to 40 carbon atoms, a halogen atom, or a thiol group, and each m³ is independently an integer of 0 to 5.
[6]

The composition for film formation according to [1], wherein the aromatic hydroxy compound represented by the formula (1A) is an aromatic hydroxy compound represented by the following formula (2):

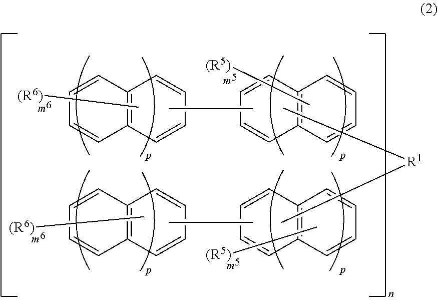

wherein R¹ is as defined in Y in the formula (1A), R³, n, and p are as defined in the formula (1A), each R⁶ is independently a hydrogen atom, an alkyl group having 1 to 34 carbon atoms, an aryl group having 6 to 34 carbon atoms, an alkenyl group having 2 to 34 carbon atoms, an alkynyl group having 2 to 40 carbon atoms and optionally having a substituent, an alkoxy group having 1 to 34 carbon atoms, a halogen atom, a thiol group, or a hydroxy group, each m⁵ is independently an integer of 1 to 6, each m⁶ is independently an integer of 1 to 7, wherein at least one R⁵ is a hydroxy group.
[7]

The composition for film formation according to [6], wherein the aromatic hydroxy compound represented by the formula (2) is an aromatic hydroxy compound represented by the following formula (2-1):

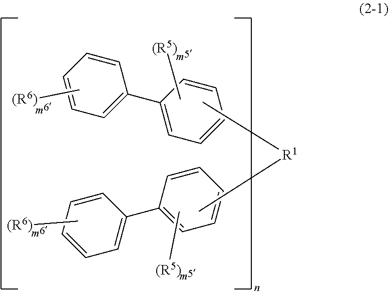

wherein R¹, R⁵, R⁶, and n are as defined in the formula (2), each m^{5′} is independently an integer of 1 to 4, and each m^{6′} is independently an integer of 1 to 5, wherein at least one R⁵ is a hydroxy group.
[8]

The composition for film formation according to [7], wherein the aromatic hydroxy compound represented by the formula (2-1) is an aromatic hydroxy compound represented by the following formula (2-2):

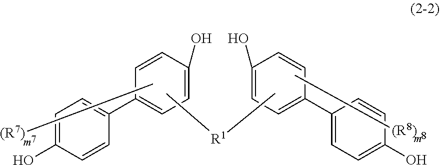

wherein R¹ is as defined in the formula (2), each of R⁷ and R⁸ are independently a hydrogen atom, an alkyl group having 1 to 40 carbon atoms, an aryl group having 6 to 40 carbon atoms, an alkenyl group having 2 to 40 carbon atoms, an alkynyl group having 2 to 40 carbon atoms and optionally having a substituent, an alkoxy group having 1 to 40 carbon atoms, a halogen atom, a thiol group, or a hydroxy group, and each of m⁷ and m⁸ are independently an integer of 0 to 7.
[9]

The composition for film formation according to any one of [1] to [8], wherein the polycyclic polyphenolic resin further has a modified portion derived from a crosslinking compound.

[10]

The composition for film formation according to [9], wherein the crosslinking compound is an aldehyde or a ketone.

[11]

The composition for film formation according to any one of [1] to [10], wherein the polycyclic polyphenolic resin has a weight-average molecular weight of 400 to 100,000.

[12]

The composition for film formation according to any one of [2] to [11], wherein R¹ is a group represented by R^{A}—R^{B}, wherein R^{A} is a methine group, and R^{B} is an aryl group having 6 to 30 carbon atoms and optionally having a substituent.

[13]

The composition for film formation according to any one of [1] to [12], wherein A in the formula (1B) is the fused ring.

[14]

A resist composition comprising the composition for film formation according to any one of [1] to [13].

[15]

The resist composition according to [14], further comprising at least one selected from the group consisting of a solvent, an acid generating agent, and an acid diffusion controlling agent.

[16]

A method for forming a resist pattern, comprising:

forming a resist film on a substrate using the resist composition according to [14] or [15];

exposing at least a portion of the formed resist film; and

developing the exposed resist film, thereby forming the resist pattern.

[17]

A radiation-sensitive composition comprising the composition for film formation according to any one of [1] to [13], an optically active diazonaphthoquinone compound, and a solvent,

wherein a content of the solvent is 20 to 99% by mass based on 100% by mass in total of the radiation-sensitive composition, and

a content of a solid content except for the solvent is 1 to 80% by mass based on 100% by mass in total of the radiation-sensitive composition.

[18]

The radiation-sensitive composition according to [17], wherein a content ratio of the polycyclic polyphenolic resin, the optically active diazonaphthoquinone compound, and a further optional component based on 100% by mass of the solid content is 1 to 99% by mass/99 to 1% by mass/0 to 98% by mass in terms of polycyclic polyphenolic resin/optically active diazonaphthoquinone compound/further optional component.

[19]

The radiation-sensitive composition according to [17] or [18], wherein the radiation-sensitive composition is capable of forming an amorphous film by spin coating.

[20]

A method for producing an amorphous film, comprising forming an amorphous film on a substrate using the radiation-sensitive composition according to any one of [17] to [19].

[21]

A method for forming a resist pattern, comprising:

forming a resist film on a substrate using the radiation-sensitive composition according to any one of [17] to [19];

exposing at least a portion of the formed resist film; and

developing the exposed resist film, thereby forming the resist pattern.

[22]

A composition for underlayer film formation for lithography comprising the composition for film formation according to any one of [1] to [13].

[23]

The composition for underlayer film formation for lithography according to [22], further comprising at least one selected from the group consisting of a solvent, an acid generating agent, and a crosslinking agent.

[24]

A method for producing an underlayer film for lithography, comprising forming the underlayer film on a substrate using the composition for underlayer film formation for lithography according to [22] or [23].

[25]

A method for forming a resist pattern, comprising:

forming an underlayer film on a substrate using the composition for underlayer film formation for lithography according to [22] or [23];

forming at least one photoresist layer on the underlayer film; and

irradiating a predetermined region of the photoresist layer with radiation for development, thereby forming the resist pattern.

[26]

A method for forming a circuit pattern, comprising:

forming an underlayer film on a substrate using the composition for underlayer film formation for lithography according to [22] or [23];

forming an intermediate layer film on the underlayer film using a resist intermediate layer film material containing a silicon atom;

forming at least one photoresist layer on the intermediate layer film;

irradiating a predetermined region of the photoresist layer with radiation for development, thereby forming a resist pattern;

etching the intermediate layer film with the resist pattern as a mask, thereby forming an intermediate layer film pattern;

etching the underlayer film with the intermediate layer film pattern as an etching mask, thereby forming an underlayer film pattern; and

etching the substrate with the underlayer film pattern as an etching mask, thereby forming a pattern on the substrate.

[27]

A composition for optical member formation comprising the composition for film formation according to any one of [1] to [13].

[28]

The composition for optical member formation according to [27], further comprising at least one selected from the group consisting of a solvent, an acid generating agent, and a crosslinking agent.

### Advantageous Effects of Invention

According to the present invention, it is possible to provide a composition for film formation, a resist composition, a radiation-sensitive composition, and a composition for underlayer film formation for lithography, which are excellent in heat resistance and/or etching resistance and/or optical characteristics, and to provide a method for producing an amorphous film, a resist pattern formation method, a method for producing an underlayer film for lithography, and a circuit pattern formation method using these compositions.

### DESCRIPTION OF EMBODIMENTS

An embodiment for carrying out the present invention (hereinafter referred to as “present embodiment”) will be described in detail below, but the present invention is not limited to this, and various modifications can be made without departing from the spirit thereof.

### [Composition for Film Formation]

A composition for film formation of the present embodiment contains a polycyclic polyphenolic resin. The polycyclic polyphenolic resin according to the present embodiment is a polycyclic polyphenolic resin having repeating units derived from at least one monomer selected from the group consisting of aromatic hydroxy compounds represented by the following formulae (1A) and (1B), wherein the repeating units are linked to each other by a direct bond between aromatic rings. Since the composition for film formation of the present embodiment is configured as described above, it can exhibit excellent heat resistance and etching resistance.

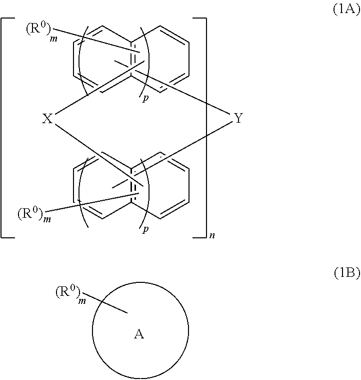

(In the formula (1A), X represents an oxygen atom, a sulfur atom, a single bond, or non-crosslinked state and Y represents a 2n-valent group having 1 to 60 carbon atoms, or a single bond, wherein when X is non-crosslinked state, Y represents the 2n-valent group; in the formula (1B), A represents a benzene ring or a fused ring; in the formulas (1A) and (1B), each R⁰ is independently an alkyl group having 1 to 40 carbon atoms and optionally having a substituent, an aryl group having 6 to 40 carbon atoms and optionally having a substituent, an alkenyl group having 2 to 40 carbon atoms and optionally having a substituent, an alkynyl group having 2 to 40 carbon atoms and optionally having a substituent, an alkoxy group having 1 to 40 carbon atoms and optionally having a substituent, a halogen atom, a thiol group, or a hydroxy group, wherein at least one R⁰ is a hydroxy group, and each m is independently an integer of 1 to 9; and n is an integer of 1 to 4, and each p is independently an integer of 0 to 3.)

The “film” as used herein refers to a film that can be applied to, for example, a film for lithography, an optical component, and the like (but not limited thereto), and the size and shape thereof are not particularly limited, and typically, the film has a general form as a film for lithography or an optical component. That is, the “composition for film formation” refers to a precursor of such a film, and is clearly distinguished from the “film” in its form and/or composition. Further, the “lithography film” is a concept that broadly includes a film for lithography applications such as a permanent film for resist and an underlayer film for lithography.

### (Polycyclic Polyphenolic Resin)

The polycyclic polyphenolic resin according to the present embodiment typically has the following characteristics (1) to (4), but is not limited thereto.

(1) The polycyclic polyphenolic resin according to the present embodiment has excellent solubility in an organic solvent (particularly, a safe solvent). Therefore, for example, when the polycyclic polyphenolic resin according to the present embodiment is used as a film forming material for lithography, films for lithography can be formed by a wet process such as spin coating or screen printing.
(2) In the polycyclic polyphenolic resin according to the present embodiment, the carbon concentration is relatively high and the oxygen concentration is relatively low. In addition, since the polycyclic polyphenolic resin according to the present embodiment has a phenolic hydroxy group in the molecule, it is useful for formation of a cured product through the reaction with a curing agent, but it can also form a cured product on its own through the crosslinking reaction of the phenolic hydroxy group upon baking at a high temperature. Due to the above, the polycyclic polyphenolic resin according to the present embodiment can exhibit high heat resistance, and when used as a film forming material for lithography, degradation of the film upon baking at a high temperature is suppressed and a film for lithography excellent in etching resistance to oxygen plasma etching and the like can be formed.
(3) The polycyclic polyphenolic resin according to the present embodiment can exhibit high heat resistance and etching resistance, as described above, and also has excellent adhesiveness to a resist layer and a resist intermediate layer film material. Therefore, when the polycyclic polyphenolic resin according to the present embodiment is used as a film forming material for lithography, films for lithography excellent in resist pattern formability can be formed. The term “resist pattern formability” herein refers to a property in which there are no major defects in the resist pattern shape and both resolution and sensitivity are excellent.
(4) The polycyclic polyphenolic resin according to the present embodiment has high refractive index ascribable to its high aromatic ring density, and is prevented from being stained by heat treatment in a wide range from a low temperature to a high temperature, and is excellent in transparency. Therefore, the polycyclic polyphenolic resin according to the present embodiment is also useful as various optical component forming materials.

It is considered that the polycyclic polyphenolic resin according to the present embodiment can be preferably applied as a film forming material for lithography due to such properties, and thus the above desired characteristics are imparted to the composition for film formation of the present embodiment. The composition for film formation of the present embodiment is not particularly limited as long as it contains the above polycyclic polyphenolic resin. That is, any optional component may be contained at any mixing ratio, and can be appropriately regulated according to a specific application of the composition for film formation.

Hereinafter, the above formulas (1A) and (1B) will be described in detail.

In the formula (1A), X represents an oxygen atom, a sulfur atom, a single bond or non-crosslinked state. X is preferably an oxygen atom from the viewpoint of heat resistance.

In the formula (1A), Y represents a 2n-valent group having 1 to 60 carbon atoms, or a single bond, wherein when X is non-crosslinked state, Y represents the 2n-valent group.

The 2n-valent group having 1 to 60 carbon atoms refers to, for example, a 2n-valent hydrocarbon group, and the hydrocarbon group may have various functional groups described later as substituents. Further, the 2n-valent hydrocarbon group refers to an alkylene group having 1 to 60 carbon atoms when n is 1, an alkanetetrayl group having 1 to 60 carbon atoms when n is 2, an alkanehexayl group having 2 to 60 carbon atoms when n is 3, and an alkaneoctayl group having 3 to 60 carbon atoms when n is 4. Examples of the 2n-valent hydrocarbon group include in which an 2n+1 valent hydrocarbon group is bonded to a linear hydrocarbon group, a branched hydrocarbon group, or an alicyclic hydrocarbon group. Herein, the alicyclic hydrocarbon group also includes a bridged alicyclic hydrocarbon group.

Examples of the 2n+1-valent hydrocarbon group include, but are not limited to, a 3-valent methine group and an ethyne group.

Further, the 2n-valent hydrocarbon group may have a double bond, a heteroatom, and/or an aryl group having 6 to 59 carbon atoms. Further, Y may contain a group derived from a compound having a fluorene skeleton such as fluorene or benzofluorene, but as used herein, the term “aryl group” is used to refer to a group that does not contain a group derived from a compound having a fluorene skeleton such as fluorene or benzofluorene.

In the present embodiment, the 2n-valent group may contain a halogen group, a nitro group, an amino group, a hydroxy group, an alkoxy group, a thiol group, or an aryl group having 6 to 40 carbon atoms. Furthermore, the 2n-valent group may contain an ether bond, a ketone bond, an ester bond, or a double bond.

In the present embodiment, from the viewpoint of heat resistance, the 2n-valent group preferably includes a branched hydrocarbon group or an alicyclic hydrocarbon group rather than a linear hydrocarbon group, and more preferably includes an alicyclic hydrocarbon group. Further, in the present embodiment, it is particularly preferably that the 2n-valent group has an aryl group having 6 to 60 carbon atoms.

Examples of the linear hydrocarbon group and the branched hydrocarbon group which may be contained in the 2n-valent group as a substituent include, but are not particularly limited to, an unsubstituted methyl group, an ethyl group, a n-propyl group, an i-propyl group, a n-butyl group, an i-butyl group, a t-butyl group, a n-pentyl group, a n-hexyl group, a n-dodecyl group, and a barrel group.

Examples of an alicyclic hydrocarbon group and an aromatic group having 6 to 60 carbon atoms which may be contained in the 2 n-valent group as a substituent include, but are not particularly limited to, an unsubstituted phenyl group, a naphthalene group, a biphenyl group, an anthracyl group, a pyrenyl group, a cyclohexyl group, a cyclododecyl group, a dicyclopentyl group, a tricyclodecyl group, an adamantyl group, a phenylene group, a naphthalenediyl group, a biphenyldiyl group, an anthracenediyl group, a pyrendiyl group, a cyclohexanediyl group, a cyclododecanediyl group, a dicyclopentanediyl group, a tricyclodecanediyl group, an adamantanediyl group, a benzenetriyl group, a naphthalenetriyl group, a biphenyltriyl group, an anthracenetriyl group, a pyrenetriyl group, a cyclohexanetriyl group, a cyclododecanetriyl group, a dicyclopentanetriyl group, a tricyclodecanetriyl group, an adamantanetriyl group, a benzenetetrayl group, a naphthalenetetrayl group, a biphenyltetrayl group, an anthracenetetrayl group, a pyrenetetrayl group, a cyclohexanetetrayl group, a cyclododecanetetrayl group, a dicyclopentanetetrayl group, a tricyclodecantetrayl group, and an adamantanetetrayl group.

Each R⁰ is independently an alkyl group having 1 to 40 carbon atoms and optionally having a substituent, an aryl group having 6 to 40 carbon atoms and optionally having a substituent, an alkenyl group having 2 to 40 carbon atoms and optionally having a substituent, an alkynyl group having 2 to 40 carbon atoms and optionally having a substituent, an alkoxy group having 1 to 40 carbon atoms and optionally having a substituent, a halogen atom, a thiol group, or a hydroxy group. The alkyl group may be either linear, branched or cyclic.

Here, at least one R⁰ is a hydroxy group.

Examples of the alkyl group having 1 to 40 carbon atoms include, but are not limited to, a methyl group, an ethyl group, a n-propyl group, an i-propyl group, a n-butyl group, an i-butyl group, a t-butyl group, a n-pentyl group, a n-hexyl group, a n-dodecyl group, and a barrel group.

Examples of the aryl group having 6 to 40 carbon atoms include, but are not limited to, a phenyl group, a naphthalene group, a biphenyl group, an anthracyl group, a pyrenyl group, and a perylene group.

Examples of the alkenyl group having 2 to 40 carbon atoms include, but are not limited to, an ethynyl group, a propenyl group, a butynyl group, and a pentynyl group.

Examples of the alkynyl group having 2 to 40 carbon atoms include, but are not limited to, an acetylene group, an ethynyl group.

Examples of the alkoxy group having 1 to 40 carbon atoms include, but are not limited to, a methoxy group, an ethoxy group, a propoxy group, a butoxy group, and a pentoxy group.

Each m is independently an integer of 1 to 9. From the viewpoint of solubility, m is preferably 1 to 6, more preferably 1 to 4, and from the viewpoint of availability of raw materials, still more preferably 1.

n is an integer of 1 to 4. From the viewpoint of solubility, n is preferably 1 to 2, and from the viewpoint of availability of raw materials, still more preferably 1.

Each p is independently an integer of 0 to 3. From the viewpoint of heat resistance, p is preferably 1 to 2, and from the viewpoint of availability of raw materials, still more preferably 1.

In the present embodiment, as the aromatic hydroxy compound, those represented by any of the formulas (1A) and (1B) can be used alone, or two or more kinds thereof can be used together. In the present embodiment, from the viewpoint of achieving both solvent solubility and heat resistance, it is preferable to adopt the compound represented by the formula (1A) as the aromatic hydroxy compound. Further, from the viewpoint of achieving both solvent solubility and heat resistance, it is also preferable to adopt the compound represented by the formula (1B) as the aromatic hydroxy compound.

In the present embodiment, the aromatic hydroxy compound represented by the formula (1A) is preferably the compound represented by the following formula (1) from the viewpoint of ease of production.

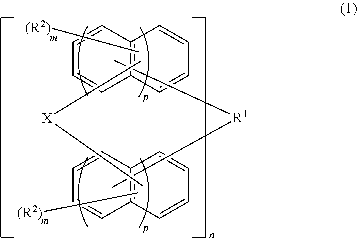

(In the formula (1), X, m, n, and p are as defined in the formula (1A), R¹ is as defined in Y in the formula (1A), and each R² is independently an alkyl group having 1 to 40 carbon atoms, an aryl group having 6 to 40 carbon atoms, an alkenyl group having 2 to 40 carbon atoms, an alkynyl group having 2 to 40 carbon atoms, an alkoxy group having 1 to 40 carbon atoms, a halogen atom, a thiol group, or a hydroxy group, wherein at least one R² is a hydroxy group.)

The aromatic hydroxy compound represented by the formula (1) is preferably an aromatic hydroxy compound represented by the following formula (1-1) from the viewpoint of heat resistance.

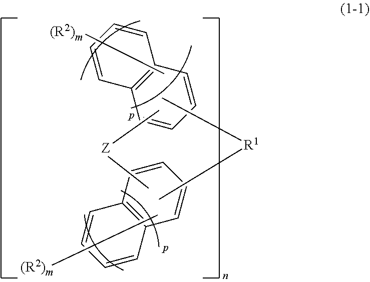

(In the formula (1-1), Z represents an oxygen atom or a sulfur atom, and R¹, R², m, p and n are as defined in the formula (1).)

Furthermore, the aromatic hydroxy compound represented by the formula (1-1) is preferably an aromatic hydroxy compound represented by the following formula (1-2) from the viewpoint of availability of raw materials.

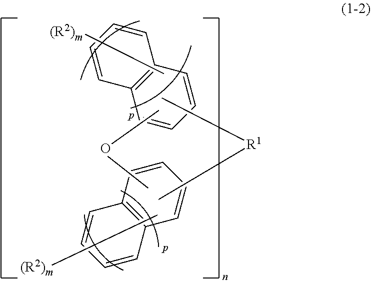

(In the formula (1-2), R¹, R², m, p and n are as defined in the formula (1).)

Furthermore, the aromatic hydroxy compound represented by the formula (1-2) is preferably an aromatic hydroxy compound represented by the following formula (1-3) from the viewpoint of improving solubility.

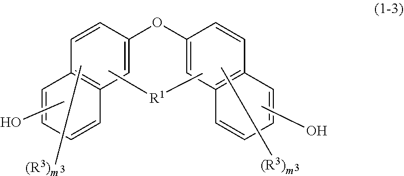

(In the formula (1-3), R¹ is as defined in the formula (1), each R³ is independently an alkyl group having 1 to 40 carbon atoms, an aryl group having 6 to 40 carbon atoms, an alkenyl group having 2 to 40 carbon atoms, an alkynyl group having 2 to 40 carbon atoms, an alkoxy group having 1 to 40 carbon atoms, a halogen atom, or a thiol group, and each m³ is independently an integer of 0 to 5.)

Further, the aromatic hydroxy compound represented by the formula (1A) is preferably an aromatic hydroxy compound represented by the following formula (2) from the viewpoint of dissolution stability.

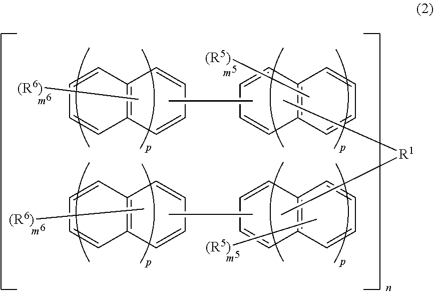

(In the formula (2), R¹ is as defined in Y in the formula (1A), R⁵, n, and p are as defined in the formula (1A), each R⁶ is independently a hydrogen atom, an alkyl group having 1 to 34 carbon atoms, an aryl group having 6 to 34 carbon atoms, an alkenyl group having 2 to 34 carbon atoms, an alkynyl group having 2 to 34 carbon atoms, an alkoxy group having 1 to 34 carbon atoms, a halogen atom, a thiol group, or a hydroxy group, each m⁵ is independently an integer of 1 to 6, each m⁶ is independently an integer of 1 to 7, wherein at least one R⁵ is a hydroxy group.)

Furthermore, the aromatic hydroxy compound represented by the formula (2) is preferably an aromatic hydroxy compound represented by the following formula (2-1) from the viewpoint of dissolution stability.

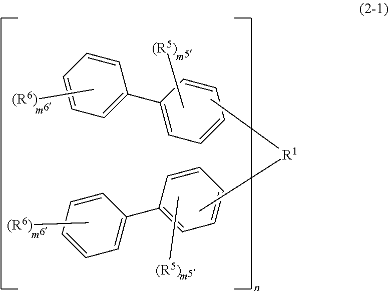

(In the formula (2-1), R¹, R⁵, R⁶, and n are as defined in the formula (2), each m^{5′} is independently an integer of 1 to 4, and each m^{6′} is independently an integer of 1 to 5, wherein at least one R⁵ is a hydroxy group.)

In the formula (2) or formula (2-1), at least one R⁶ is preferably a hydroxy group from the viewpoint of dissolution stability.

Furthermore, the aromatic hydroxy compound represented by the formula (2-1) is preferably an aromatic hydroxy compound represented by the following formula (2-2) from the viewpoint of availability of raw materials.

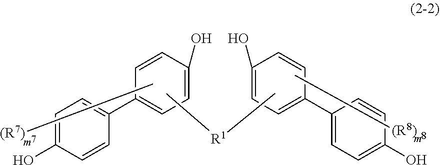

(In the formula (2-2), R¹ is as defined in the formula (2), each of R⁷ and R⁸ are independently a hydrogen atom, an alkyl group having 1 to 40 carbon atoms, an aryl group having 6 to 40 carbon atoms, an alkenyl group having 2 to 40 carbon atoms, an alkynyl group having 2 to 34 carbon atoms, an alkoxy group having 1 to 40 carbon atoms, a halogen atom, a thiol group, or a hydroxy group, and each of m⁷ and m⁸ are independently an integer of 0 to 7.)

In the formula (1), the formula (1-1), the formula (1-2), the formula (1-3), the formula (2), the formula (2-1), or the formula (2-2), it is preferable that the R¹ is a group represented by R^{A}—R^{B}, in which R^{A} is a methine group, and R^{B} is an aryl group having 6 to 30 carbon atoms and optionally having a substituent, from the viewpoint of having both further high heat resistance and solubility. In the present embodiment, examples of the aryl group having 6 to 30 carbon atoms include, but are not limited to, a phenyl group, a naphthalene group, a biphenyl group, an anthracyl group, and a pyrenyl group. As described above, the group derived from a compound having a fluorene skeleton such as fluorene or benzofluorene is not included in the “aryl group having 6 to 30 carbon atoms”.

Specific examples of the aromatic hydroxy compound represented by the formula (1A), the formula (1), the formula (1-1), the formula (1-2), the formula (1-3), the formula (2), the formula (2-1), or the formula (2-2) will be listed below, but are not limited thereto.

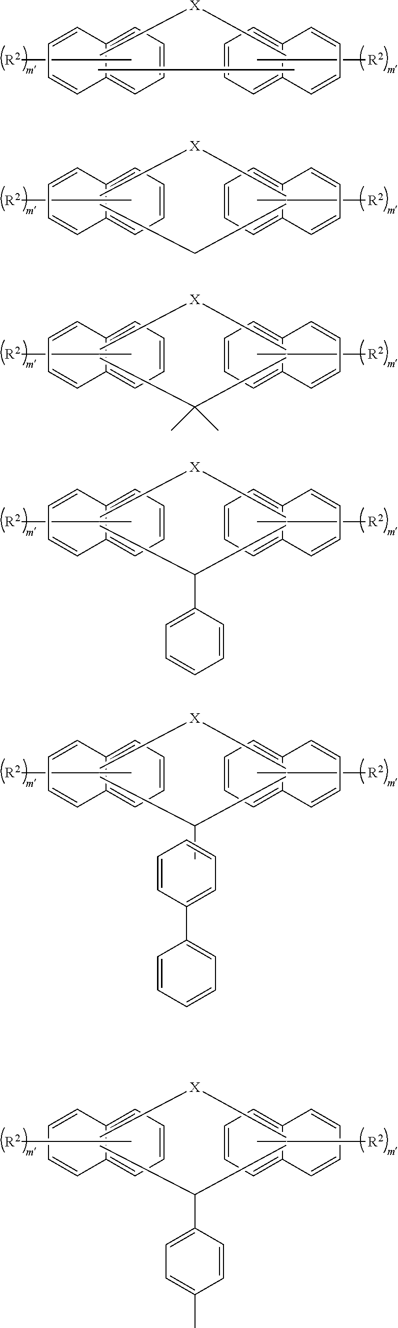

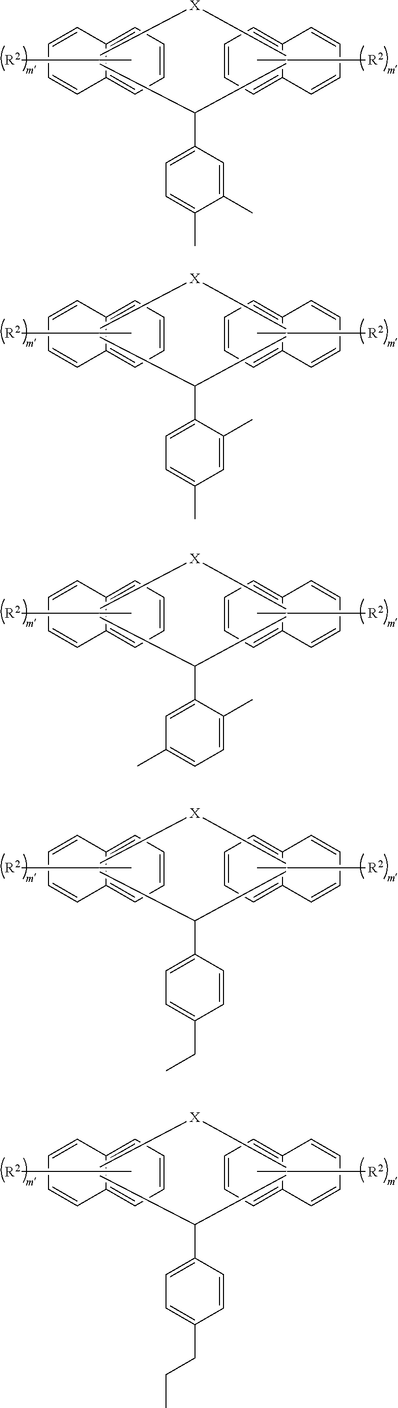

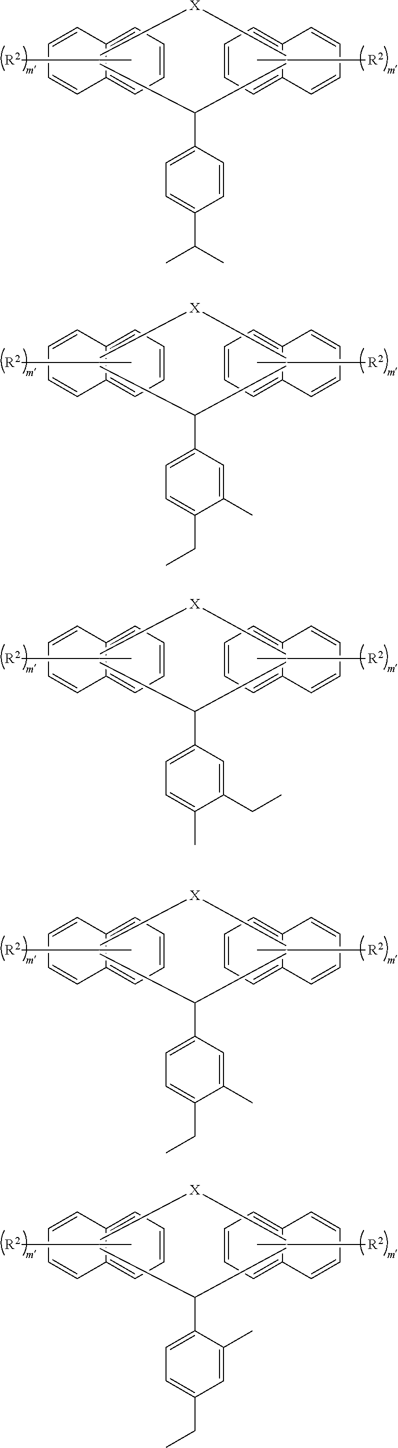

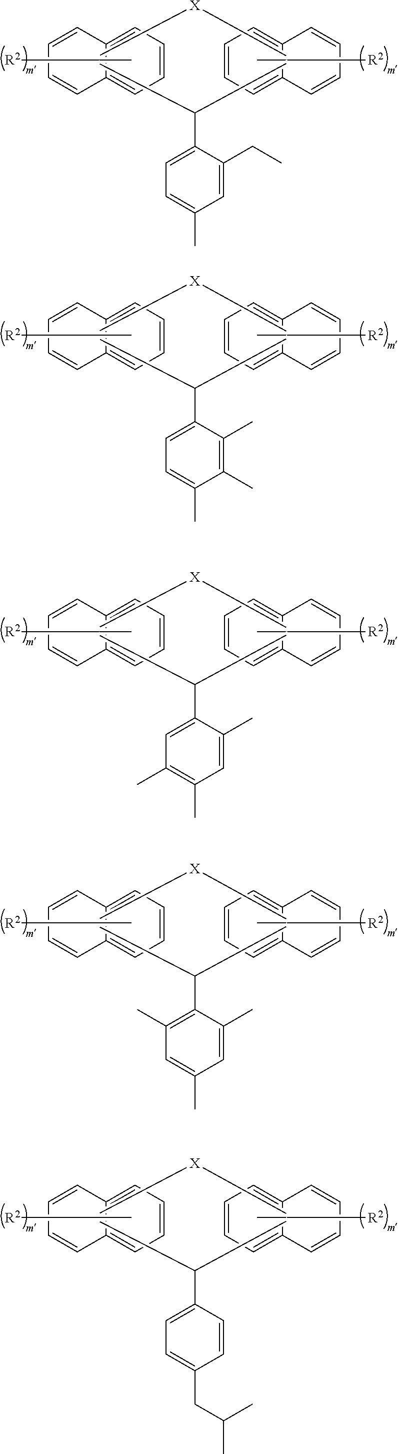

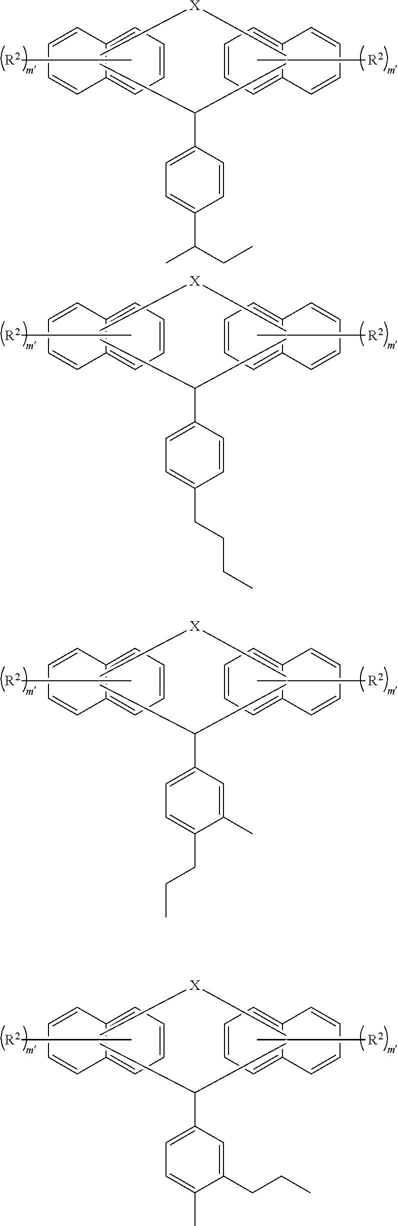

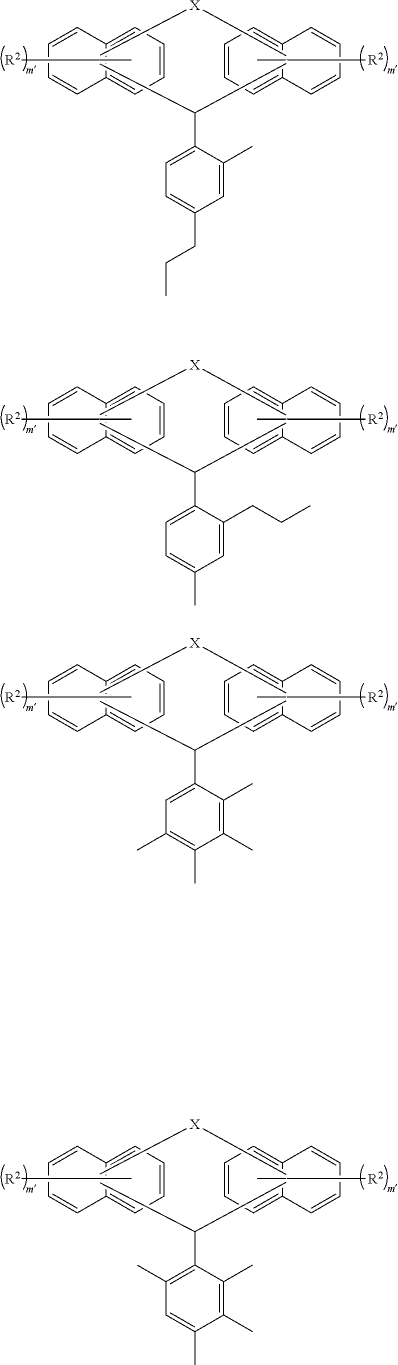

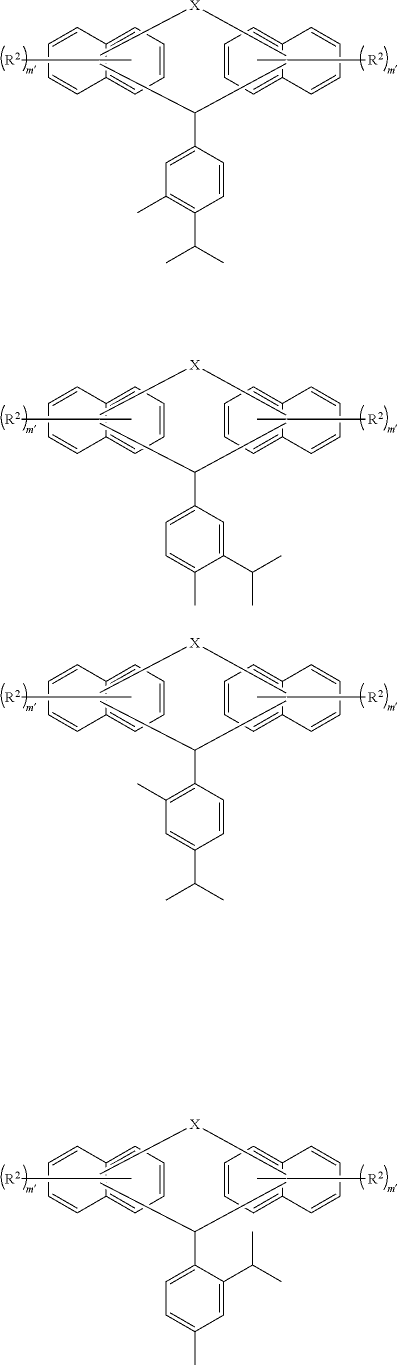

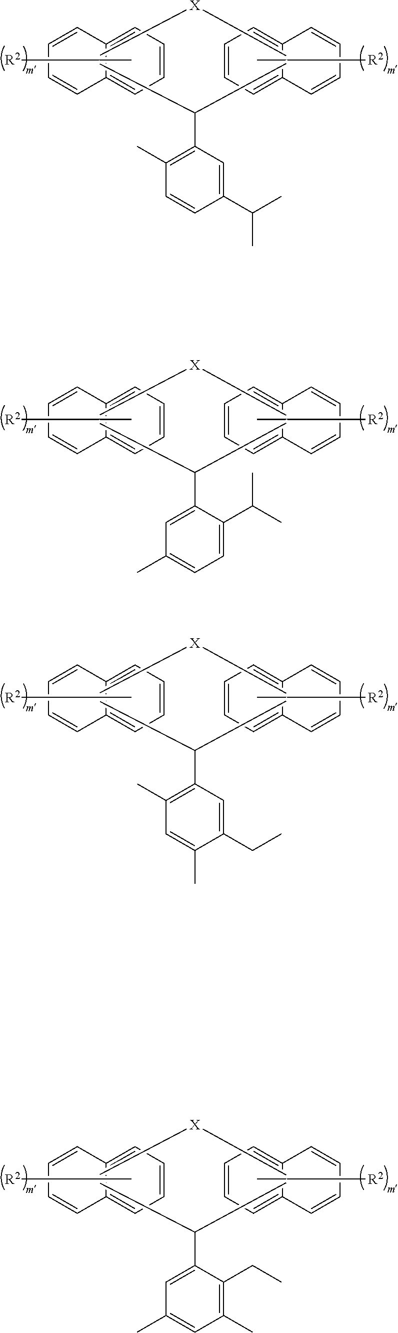

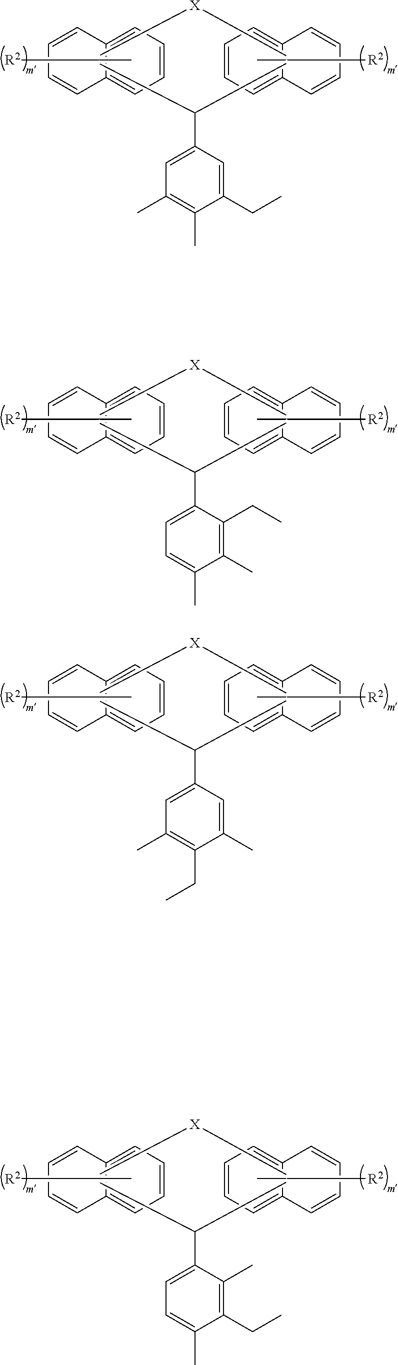

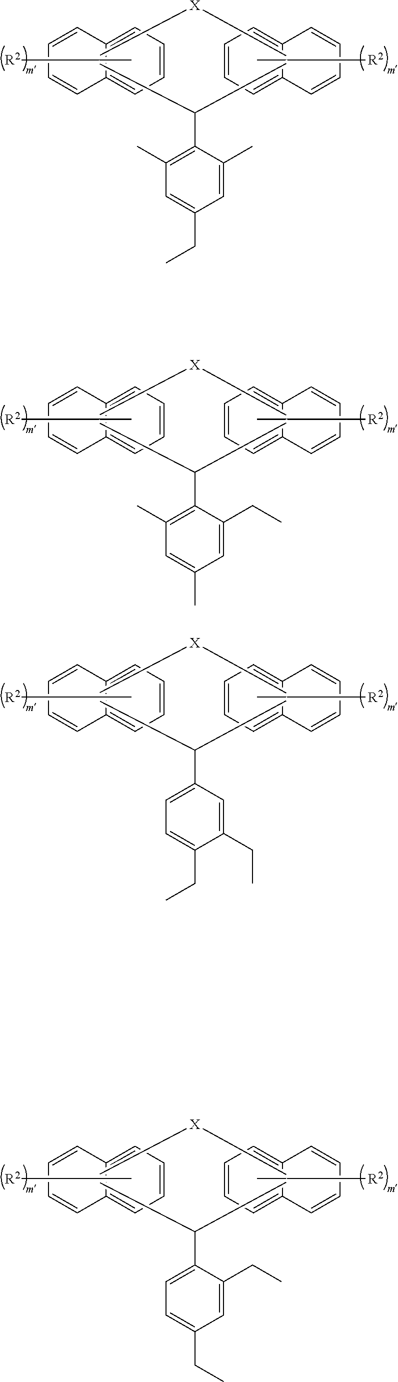

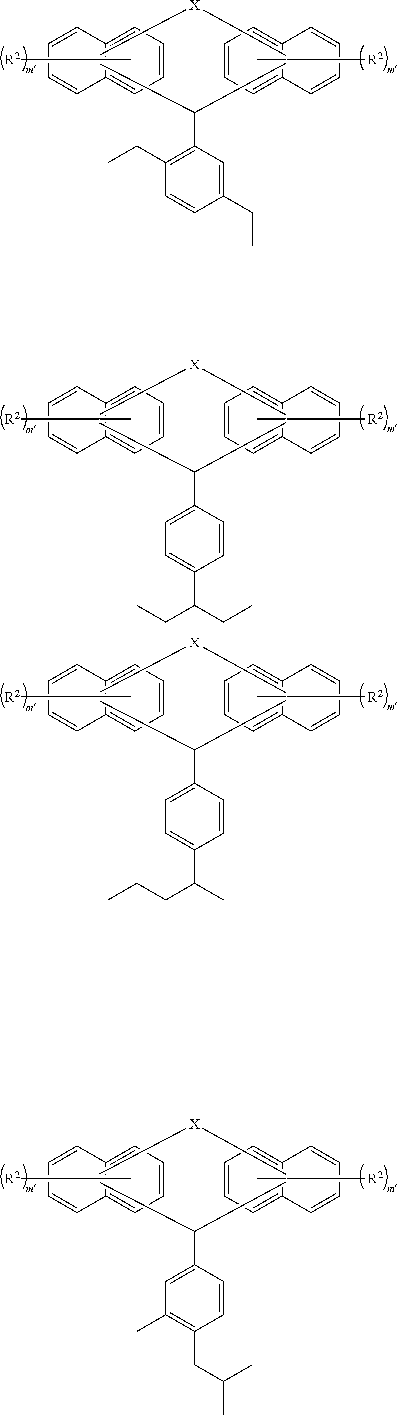

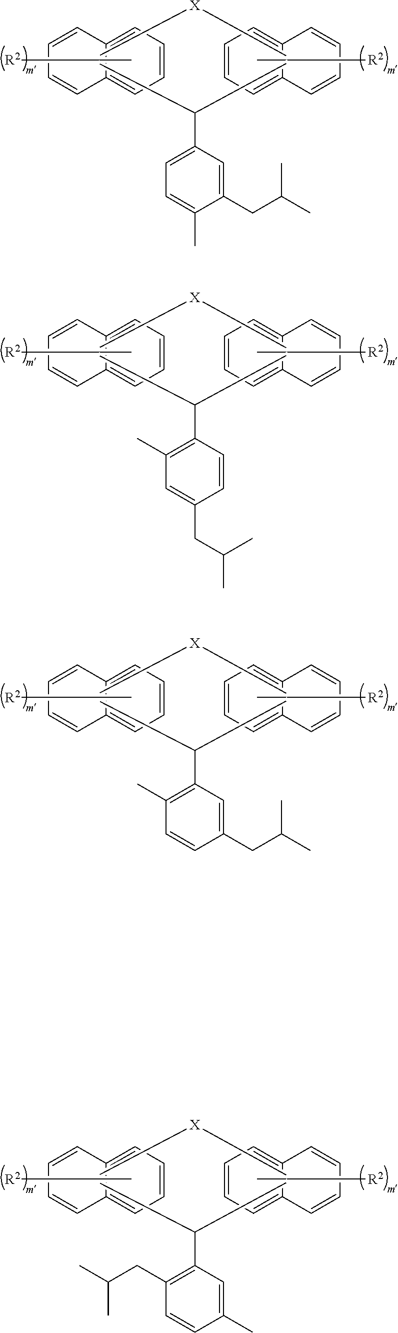

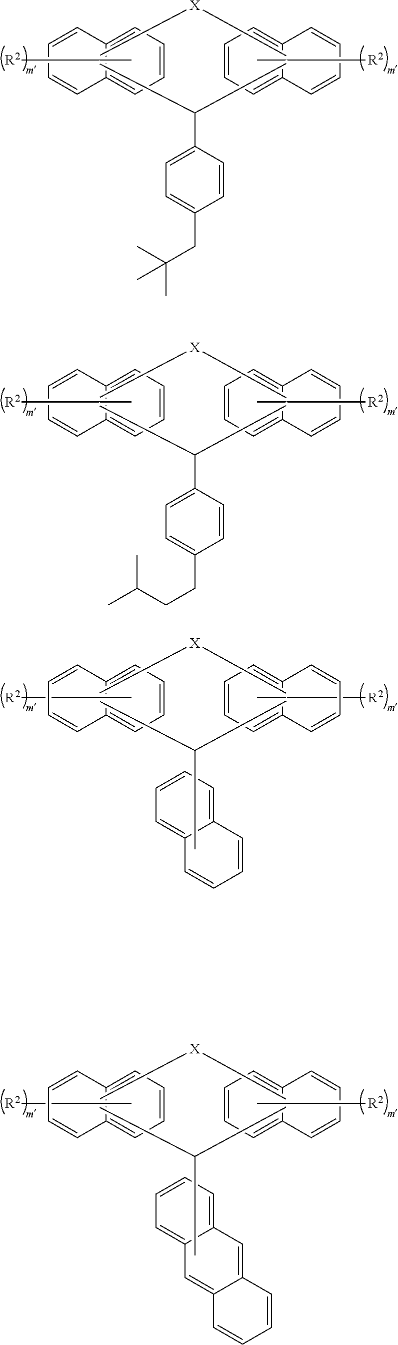

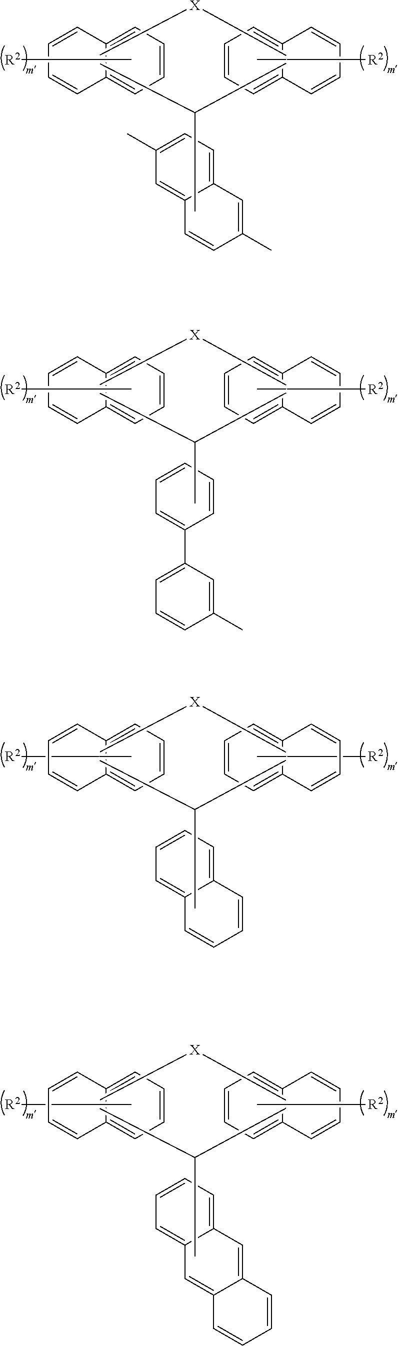

In the formulas, R² and X are as defined in the formula (1). m′ is an integer of 1 to 7. Here, at least one R² is a hydroxy group.

Specific examples of the aromatic hydroxy compound according to the present embodiment will be further listed below, but are not limited thereto.

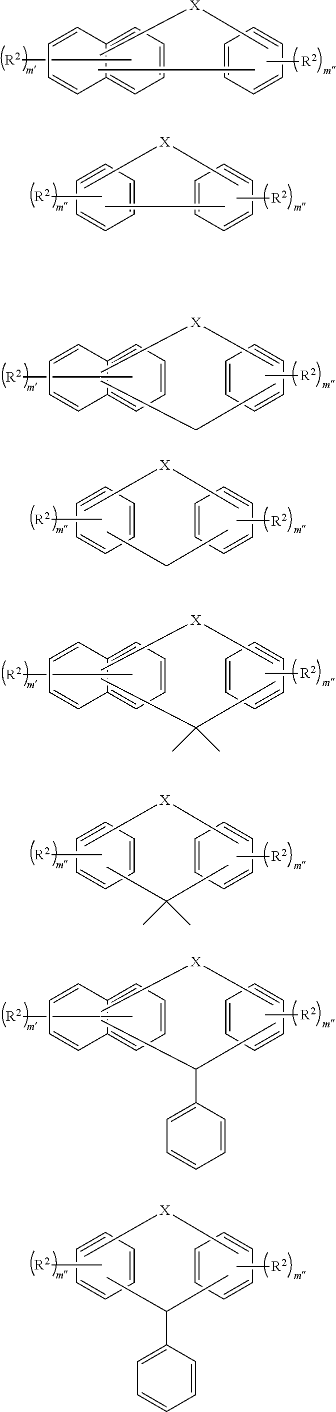

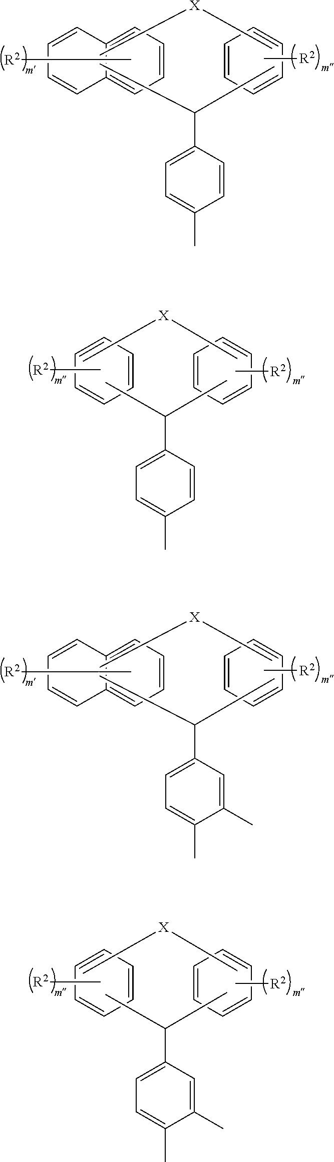

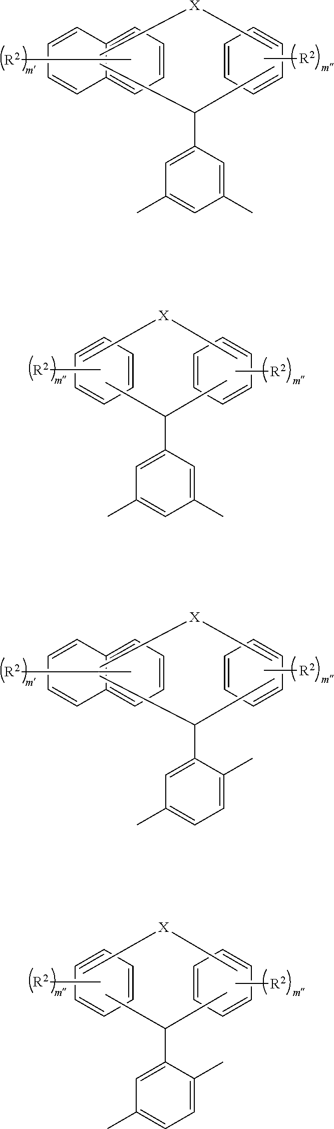

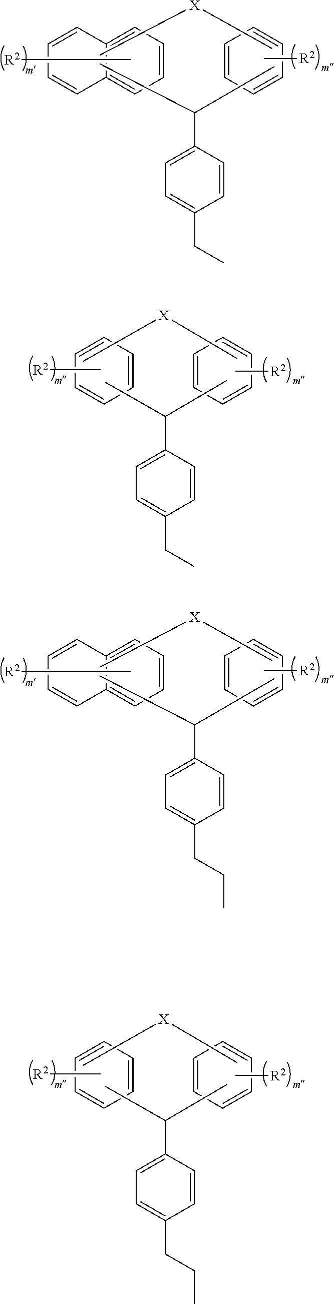

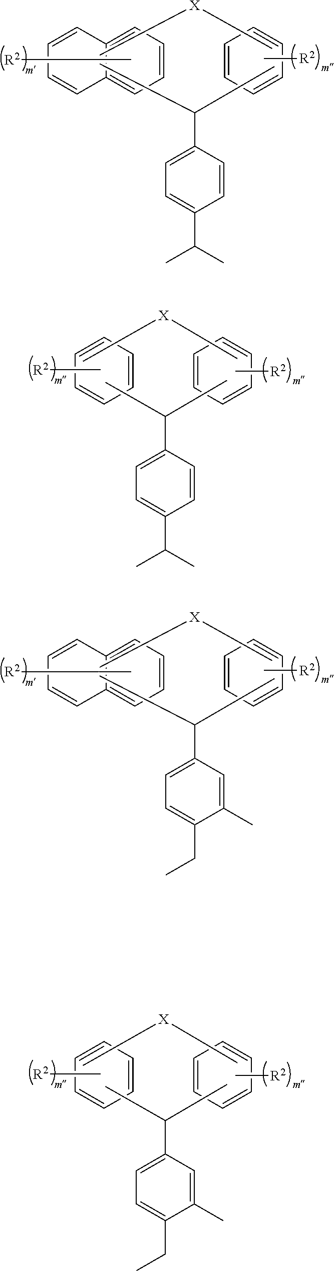

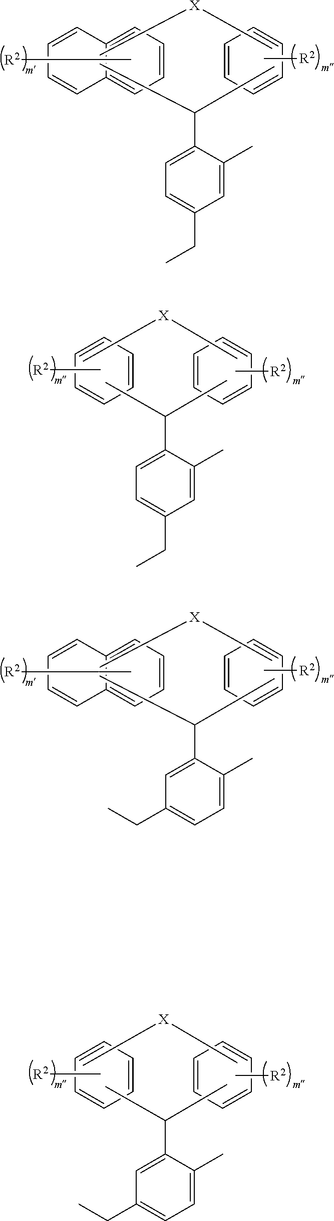

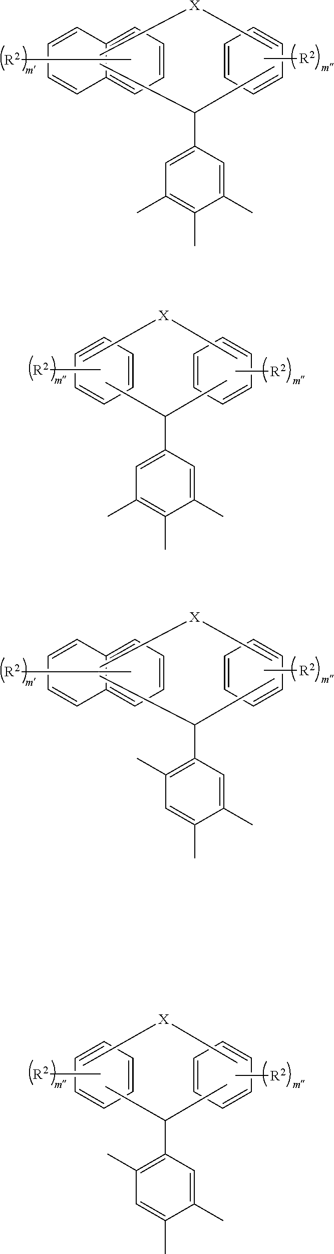

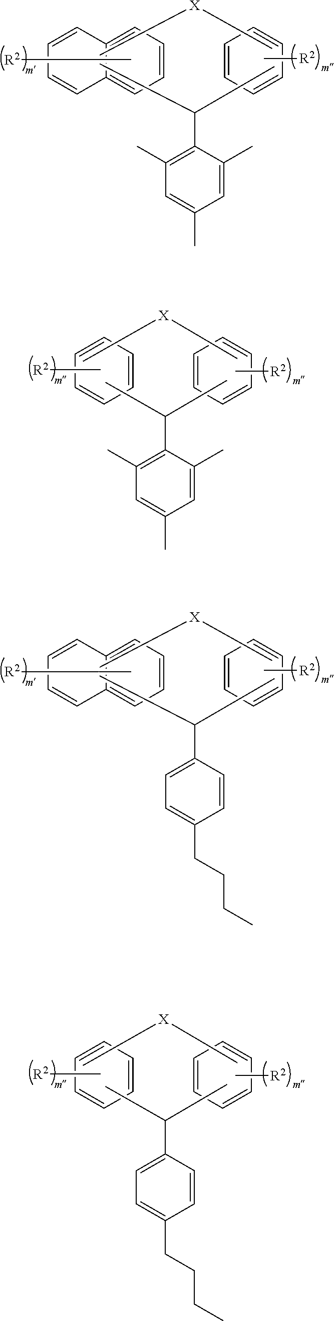

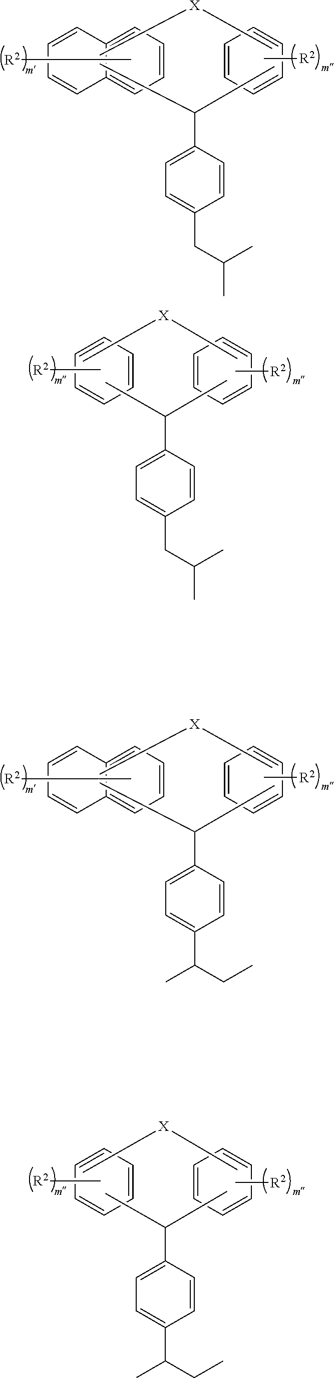

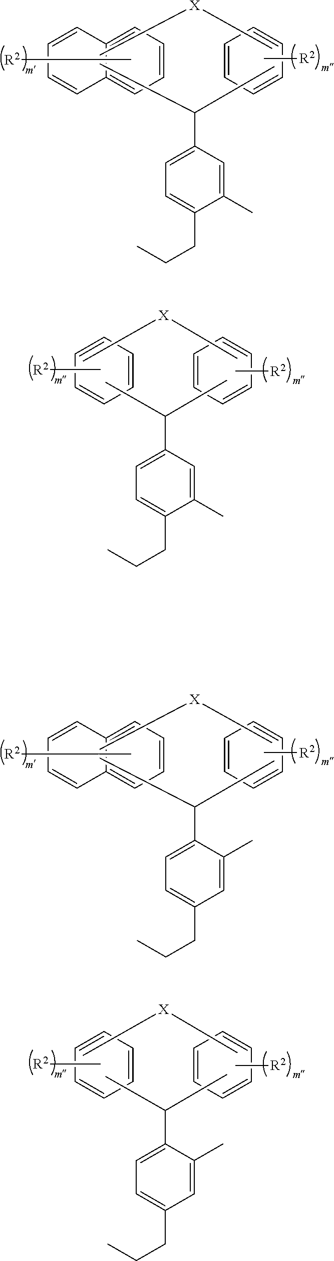

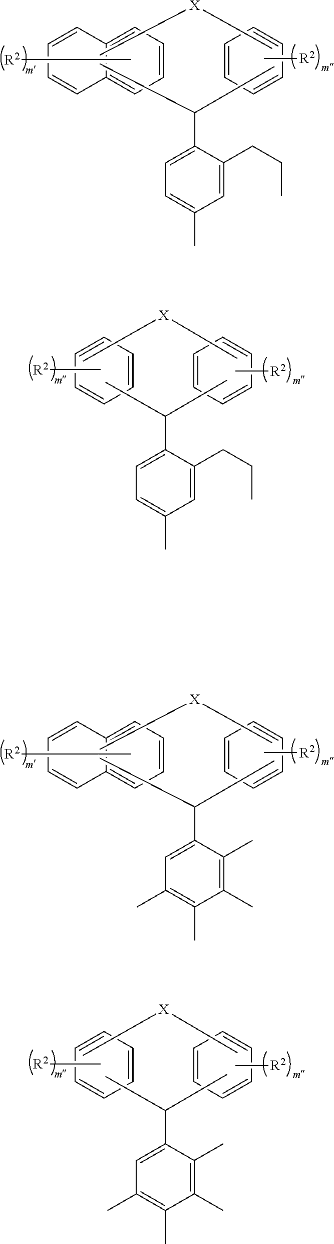

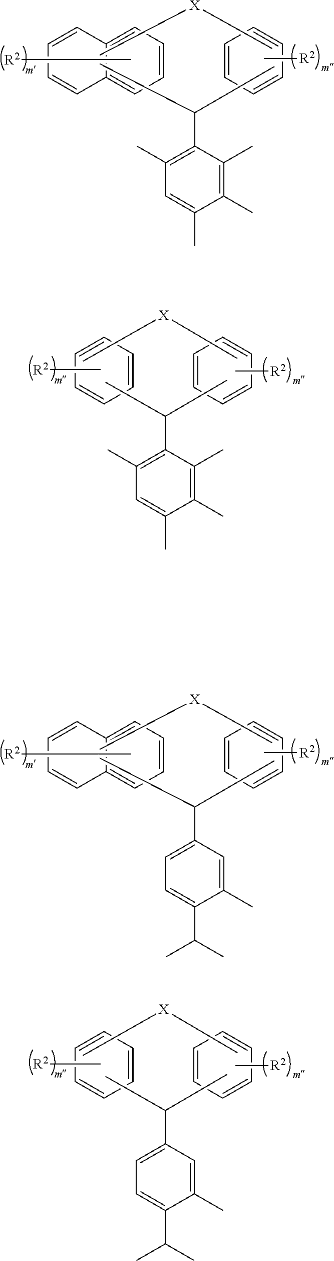

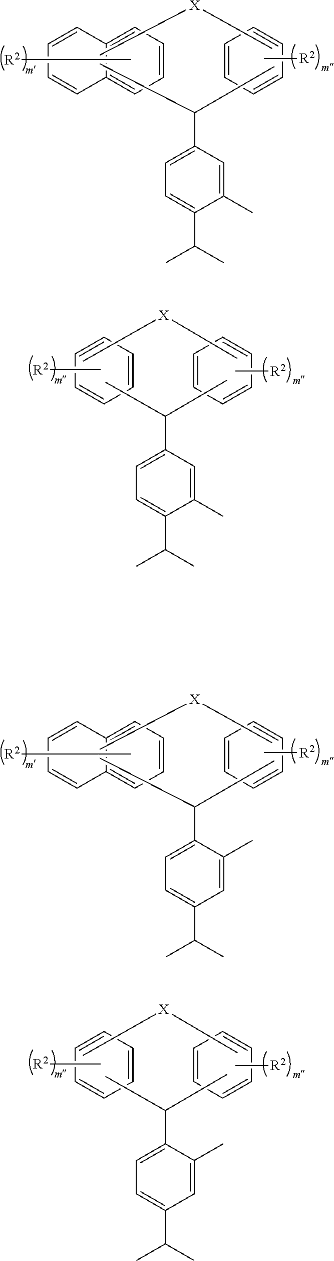

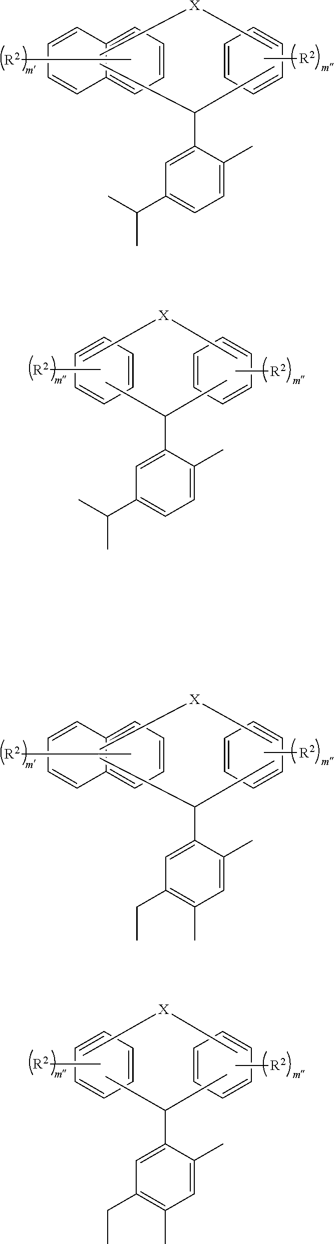

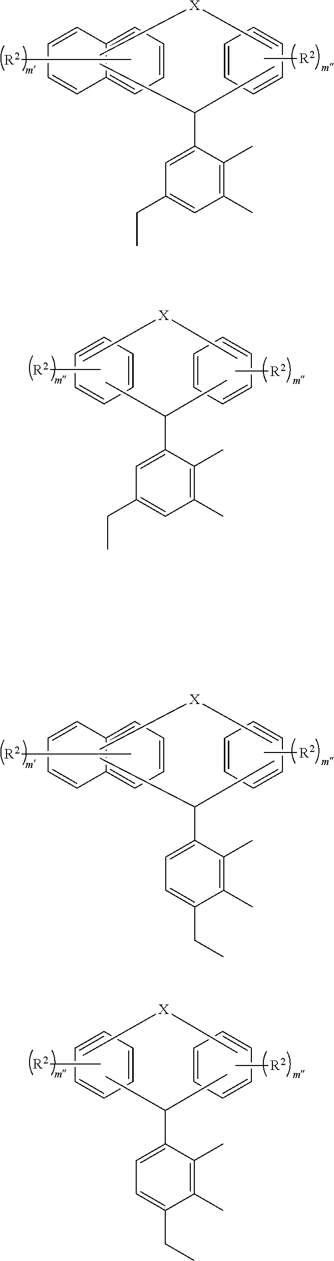

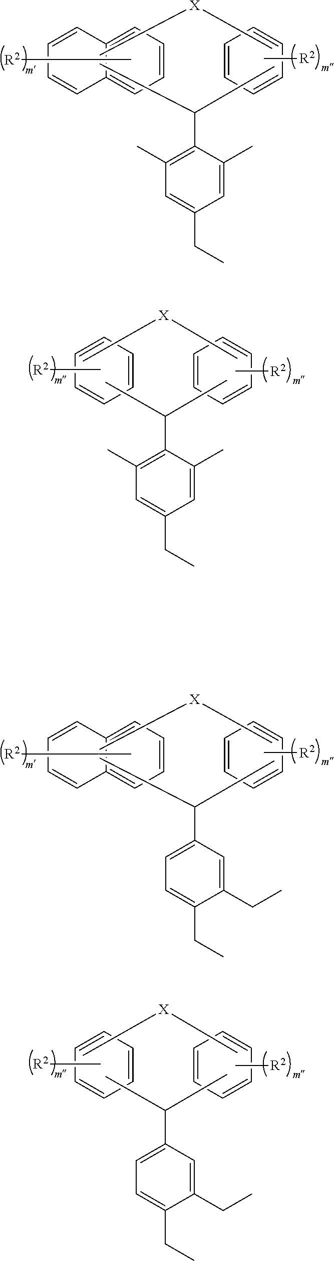

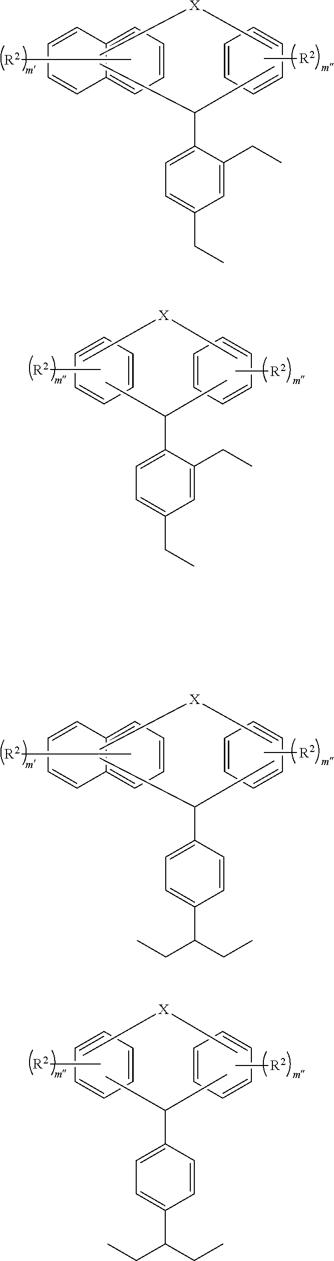

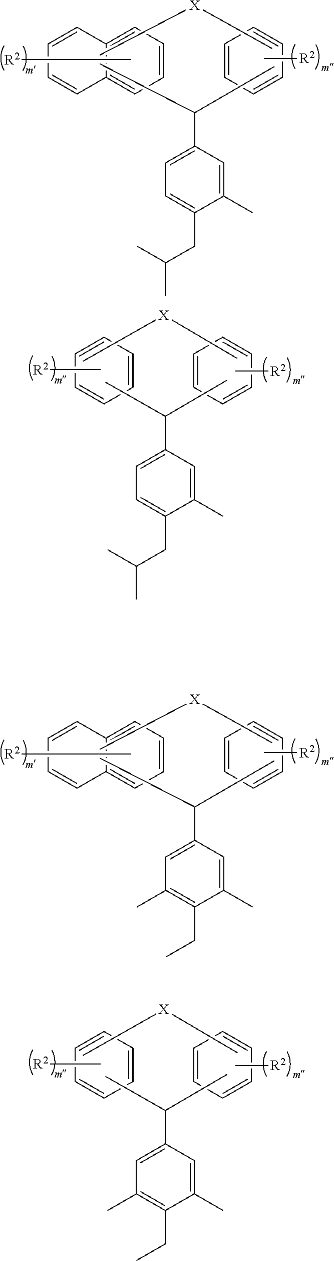

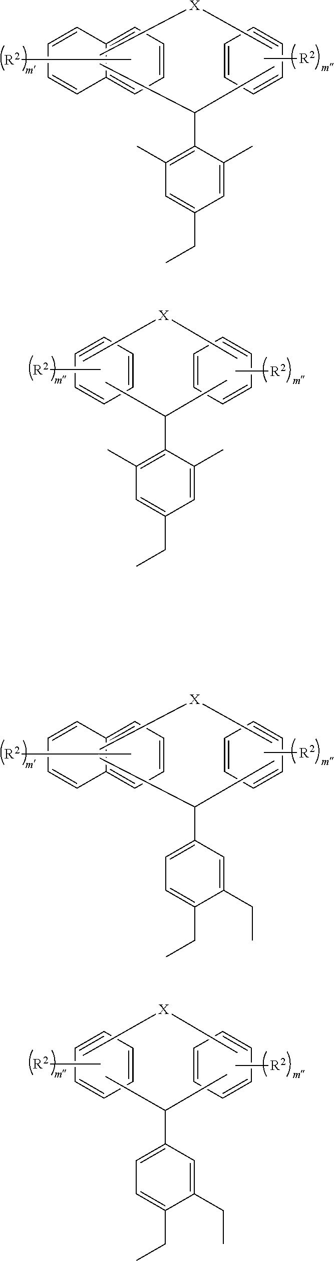

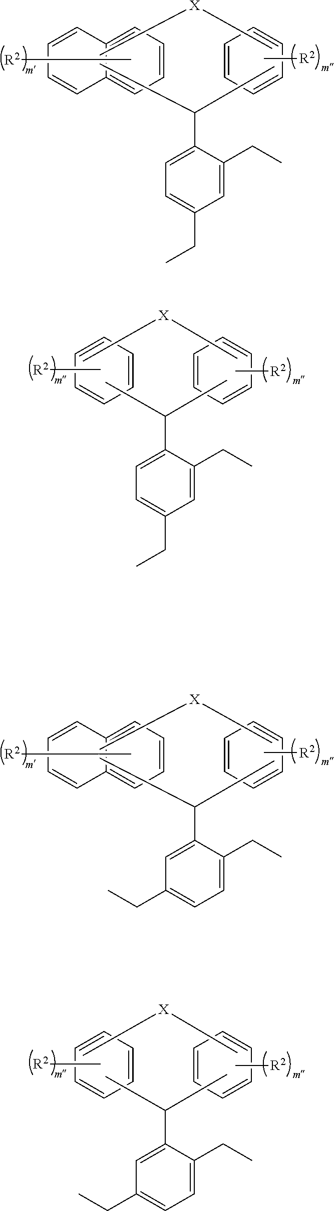

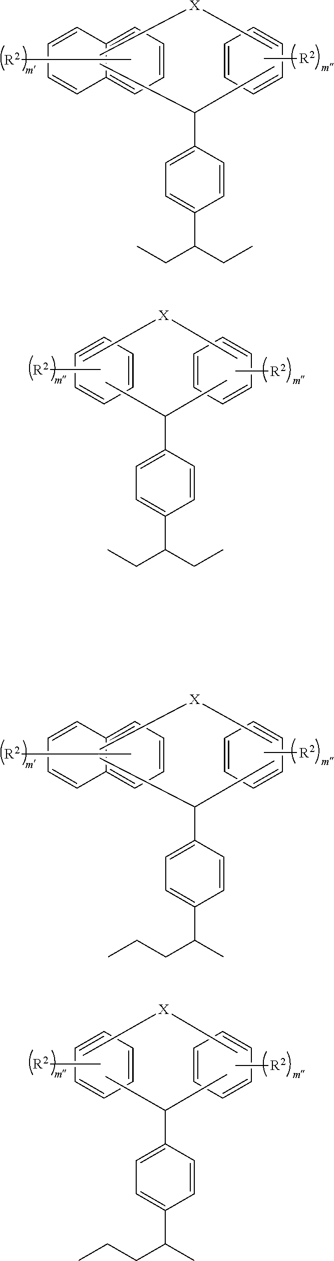

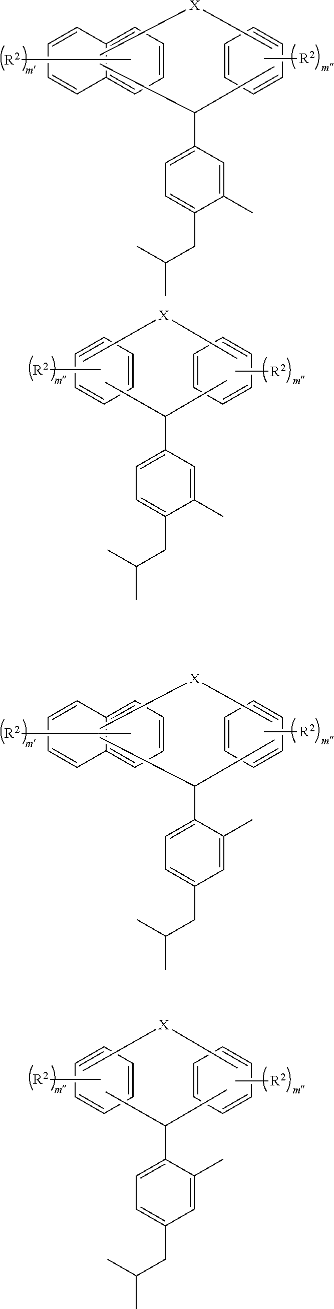

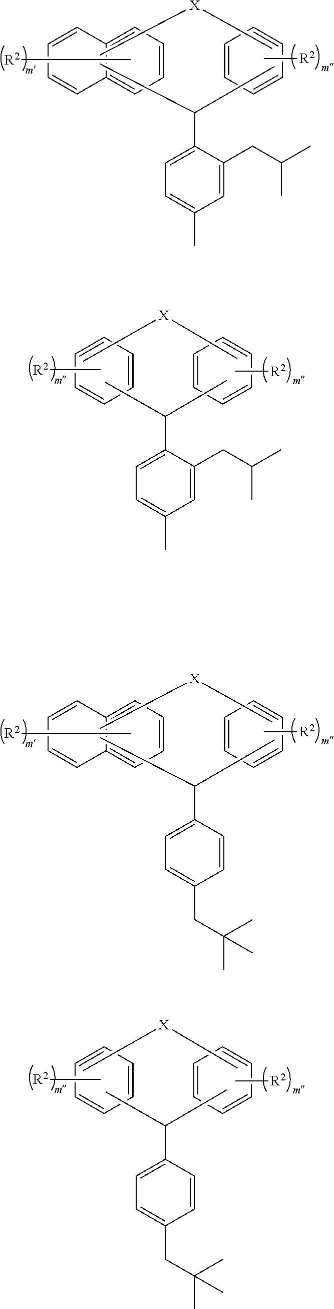

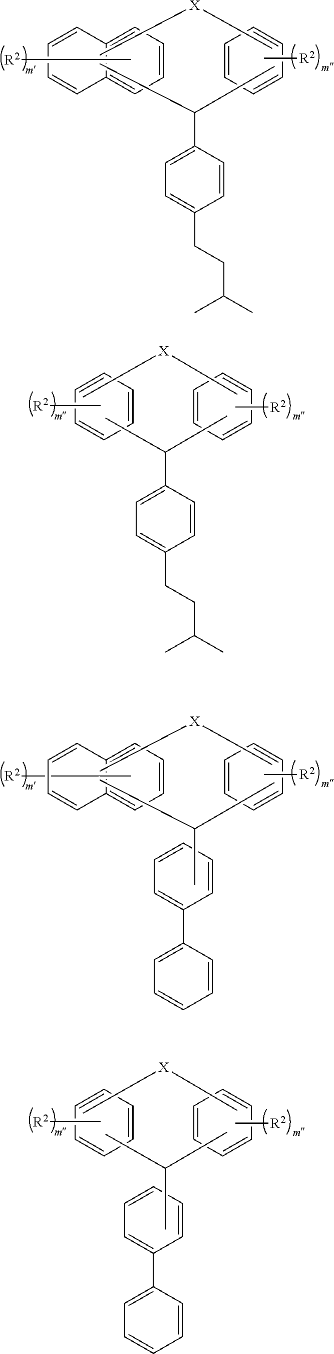

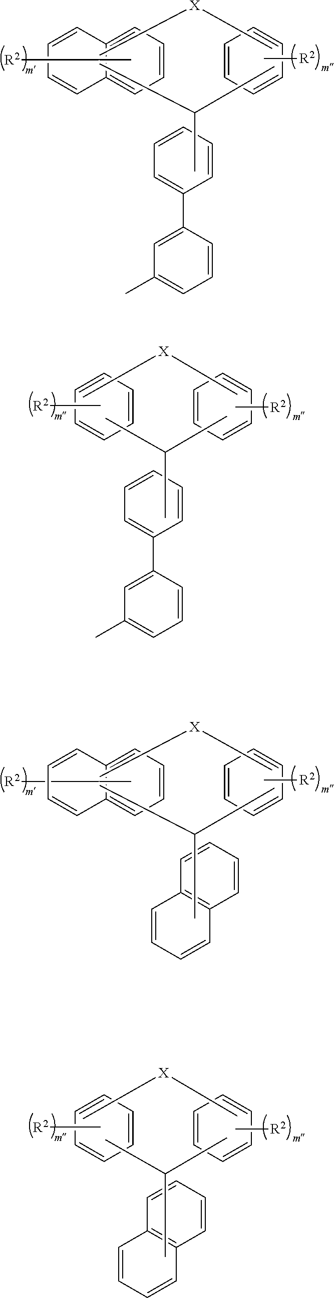

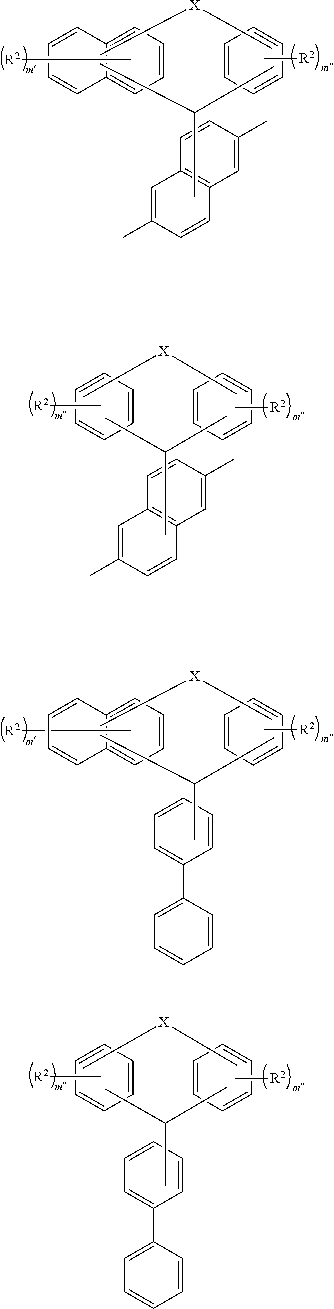

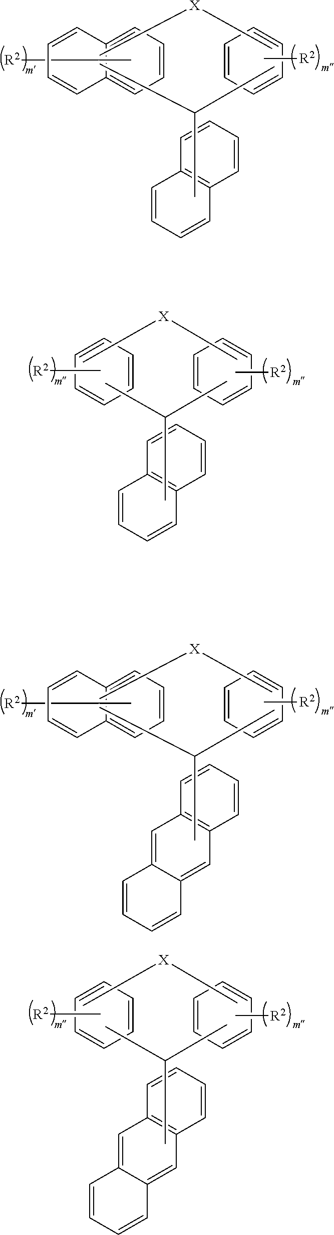

In the formulas, R² and X are as defined in the formula (1).

m′ is an integer of 1 to 7, and m″ is an integer of 1 to 5. Here, at least one R² is a hydroxy group.

Specific examples of the aromatic hydroxy compound according to the present embodiment will be further listed below, but are not limited thereto.

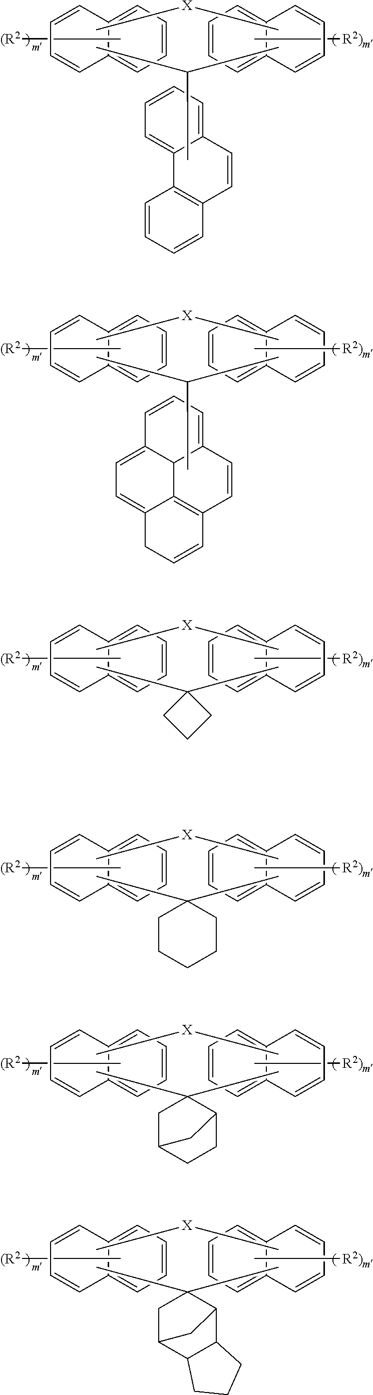

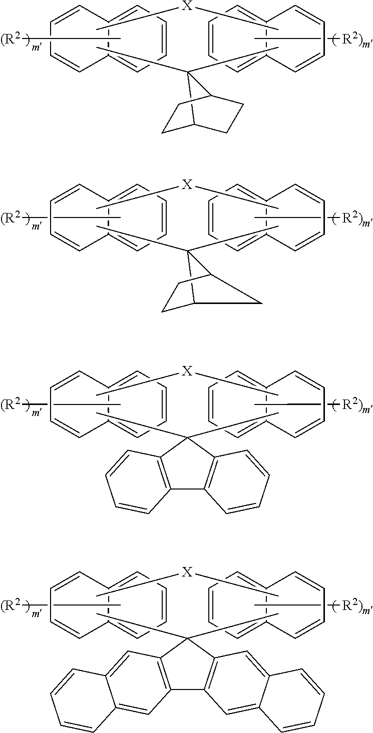

In the formula, R², X, and m′ are as defined in the above. Here, at least one R² is a hydroxy group.

Specific examples of the aromatic hydroxy compound according to the present embodiment will be further listed below, but are not limited thereto.

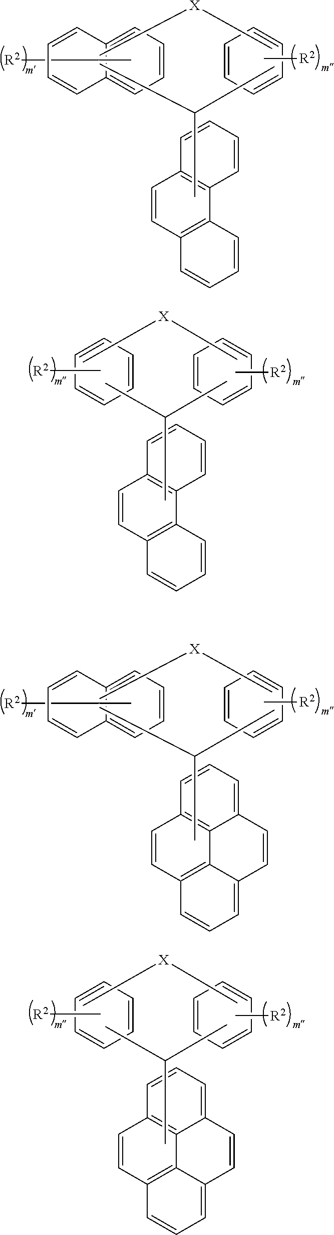

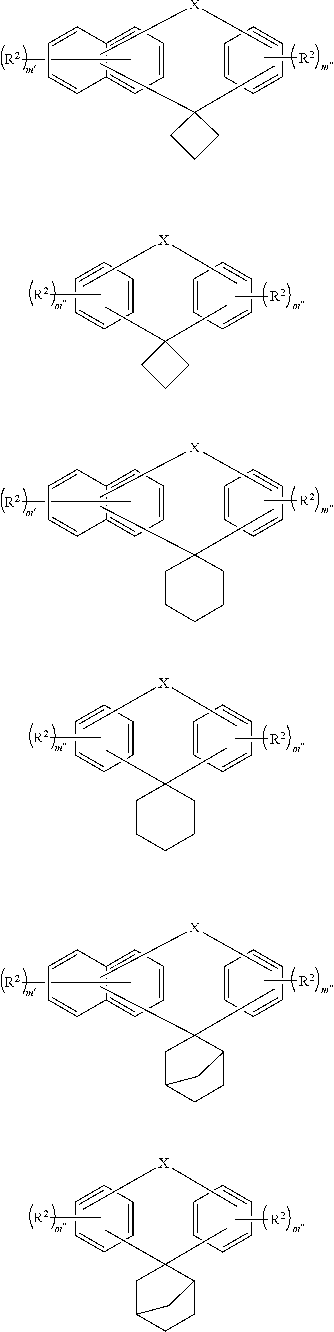

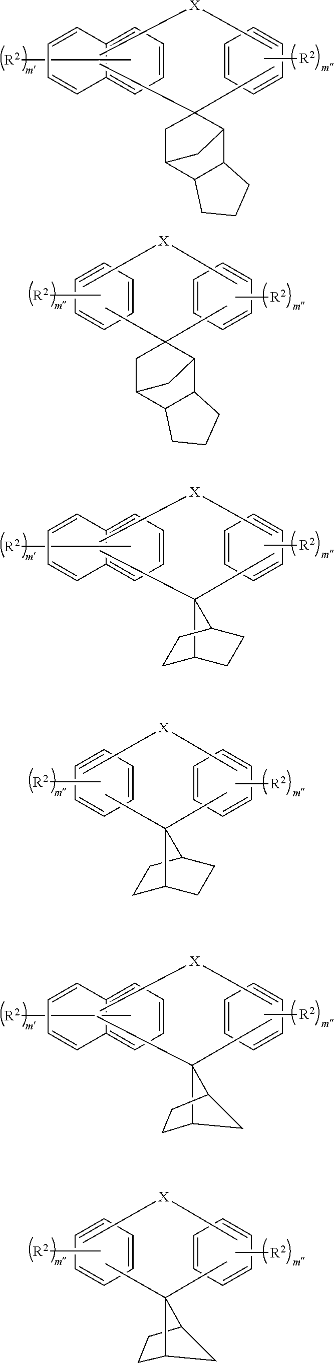

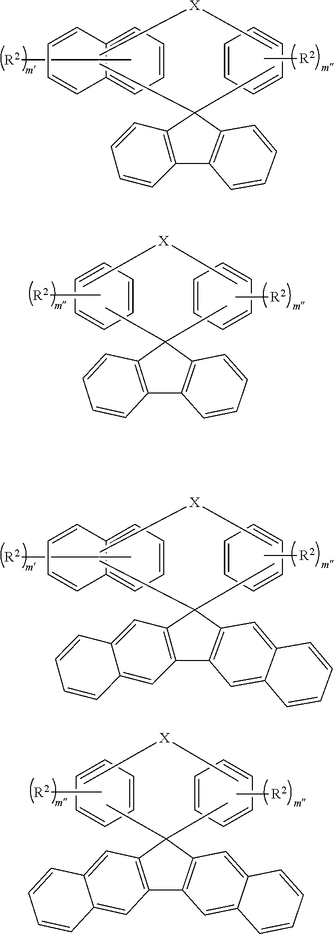

In the formulas, R² and X are as defined in the formula (1). m′ is an integer of 1 to 7. m″ is an integer of 1 to 5. Here, at least one R² is a hydroxy group.

Specific examples of the aromatic hydroxy compound according to the present embodiment will be further listed below, but are not limited thereto.

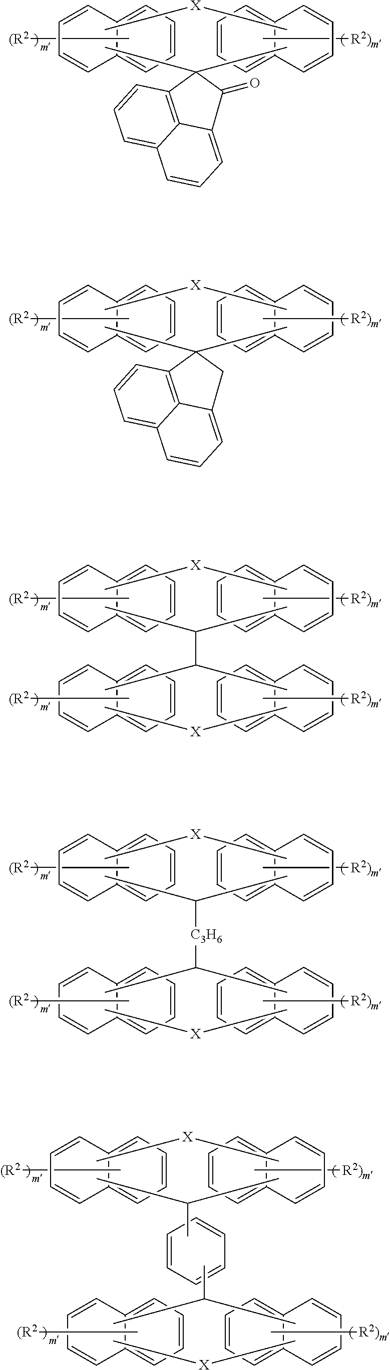

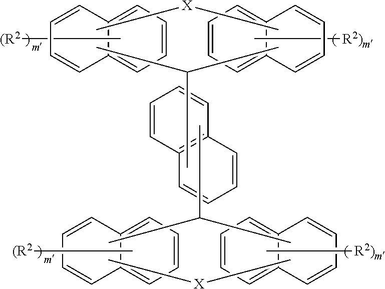

In the formula, R² and X are as defined in the formula (1) m′ is an integer of 1 to 7. Here, at least one R² is a hydroxy group.

Specific examples of the aromatic hydroxy compound according to the present embodiment will be further listed below, but are not limited thereto.

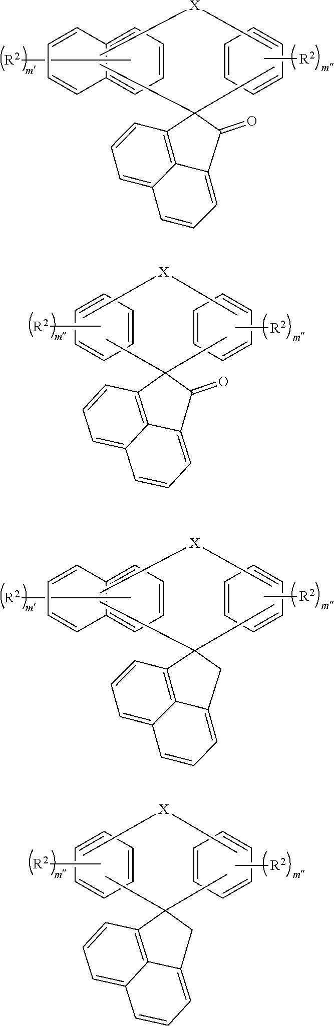

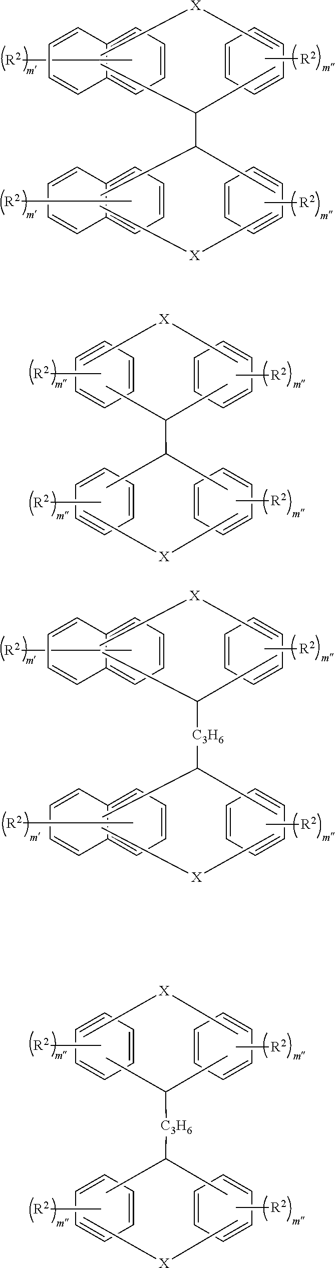

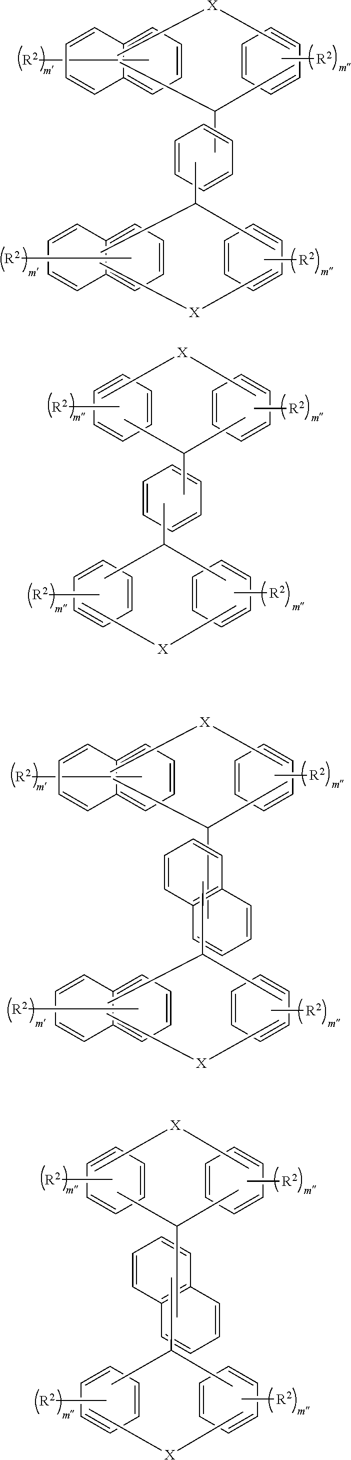

In the formulas, R² and X are as defined in the formula (1) m′ is an integer of 1 to 7. m″ is an integer of 1 to 5. Here, at least one R² is a hydroxy group.

Specific examples of the aromatic hydroxy compound according to the present embodiment will be further listed below, but are not limited thereto.

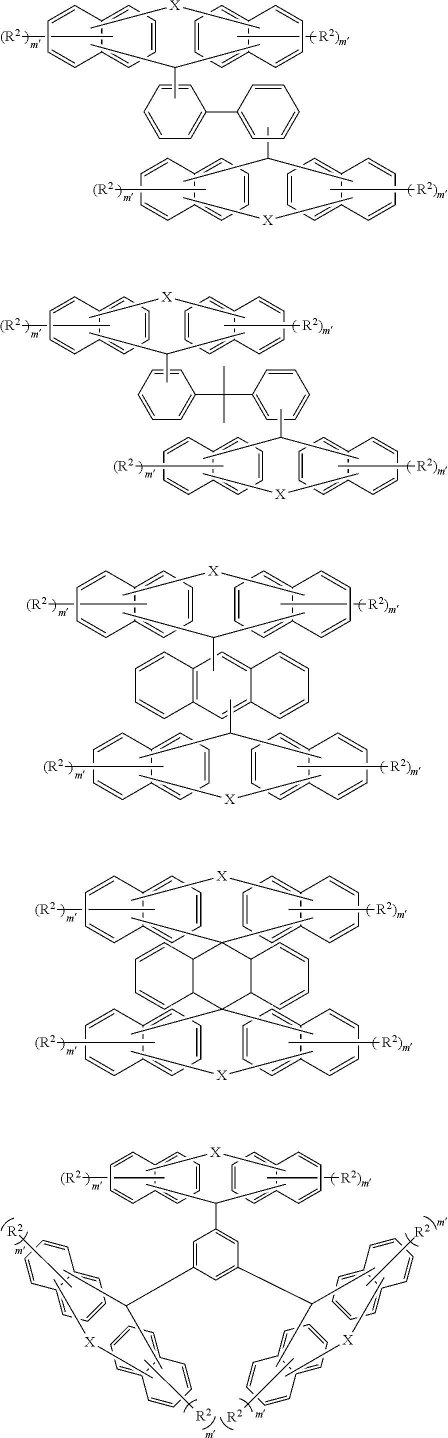

In the formula, R² and X are as defined in the formula (1). m′ is an integer of 1 to 7. Here, at least one R² is a hydroxy group.

Specific examples of the aromatic hydroxy compound according to the present embodiment will be further listed below, but are not limited thereto.

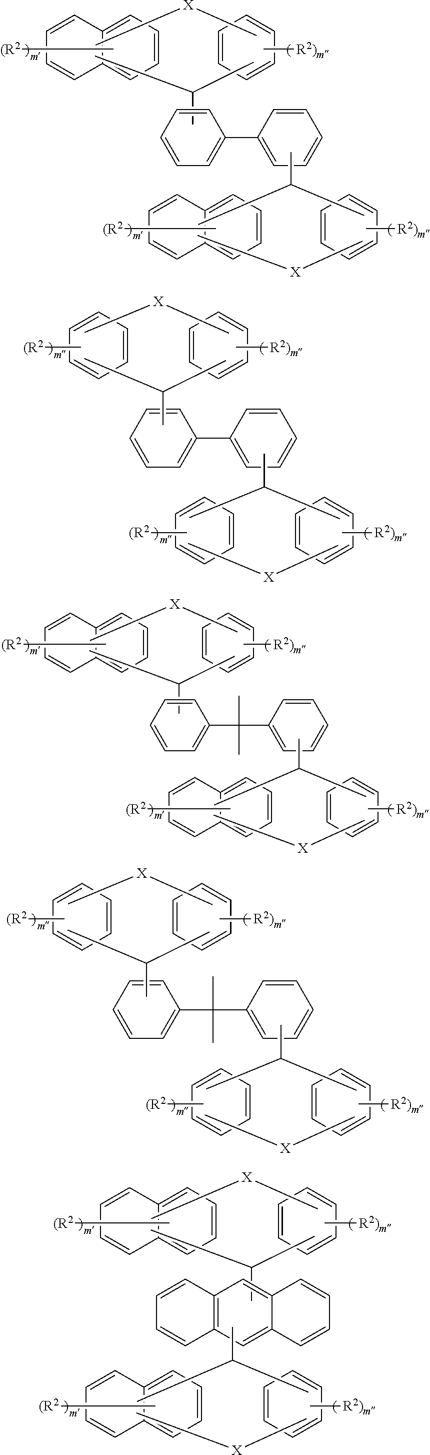

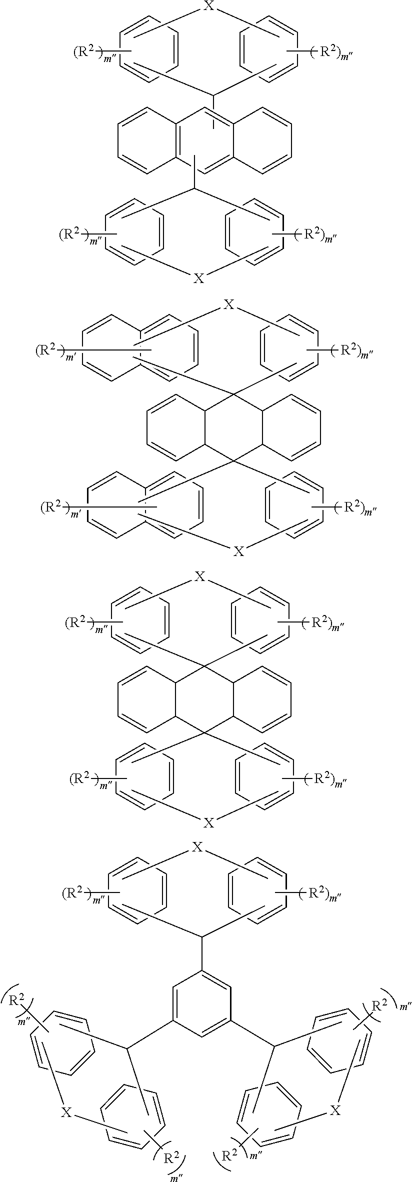

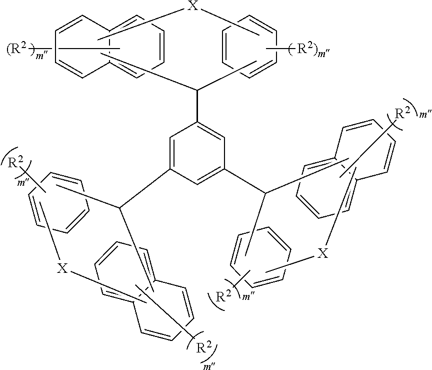

In the formulas, R² and X are as defined in the formula (1). m′ is an integer of 1 to 7. m″ is an integer of 1 to 5. Here, at least one R² is a hydroxy group.

Specific examples of the compound represented by the formula (2) will be listed below, but are not limited thereto.

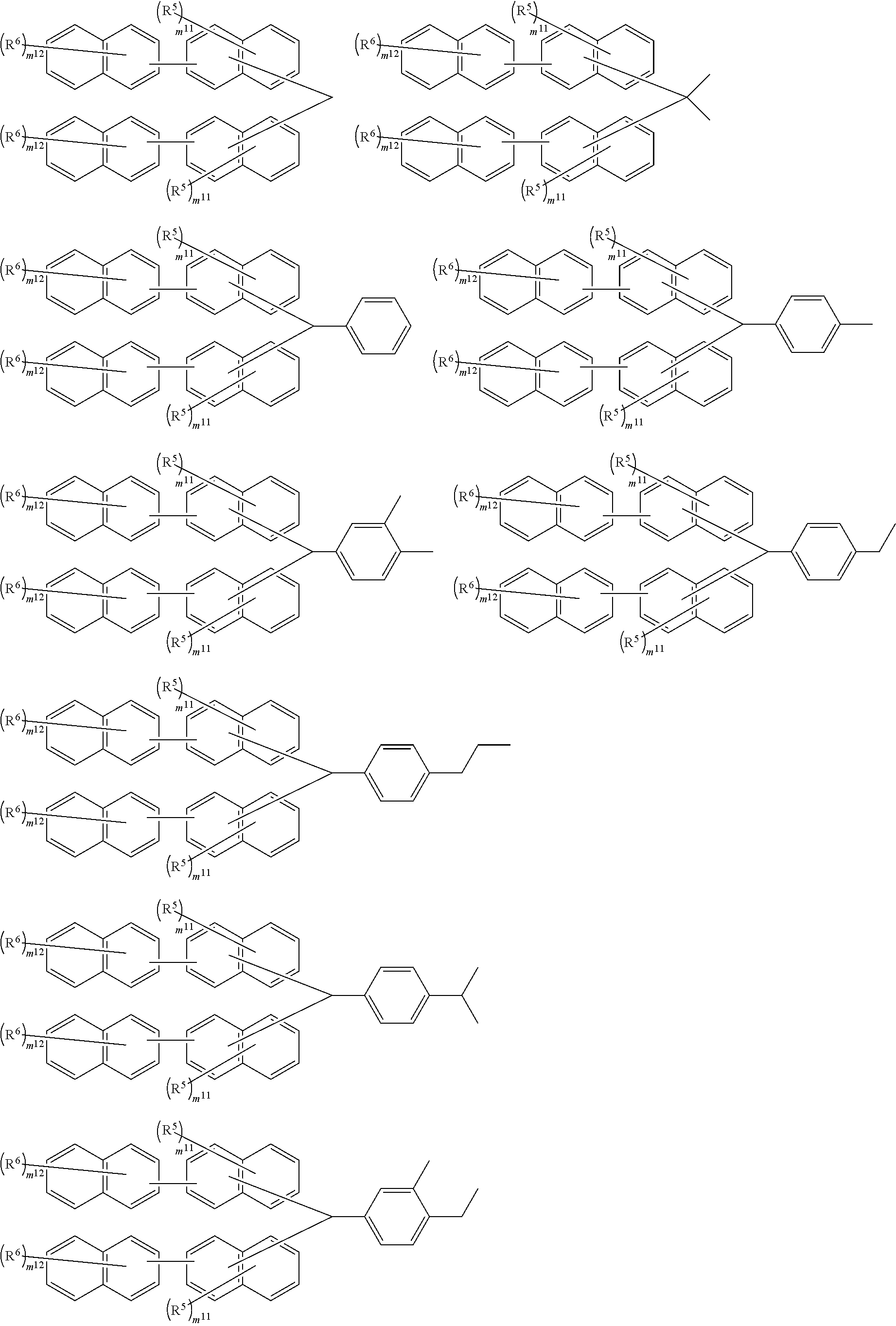

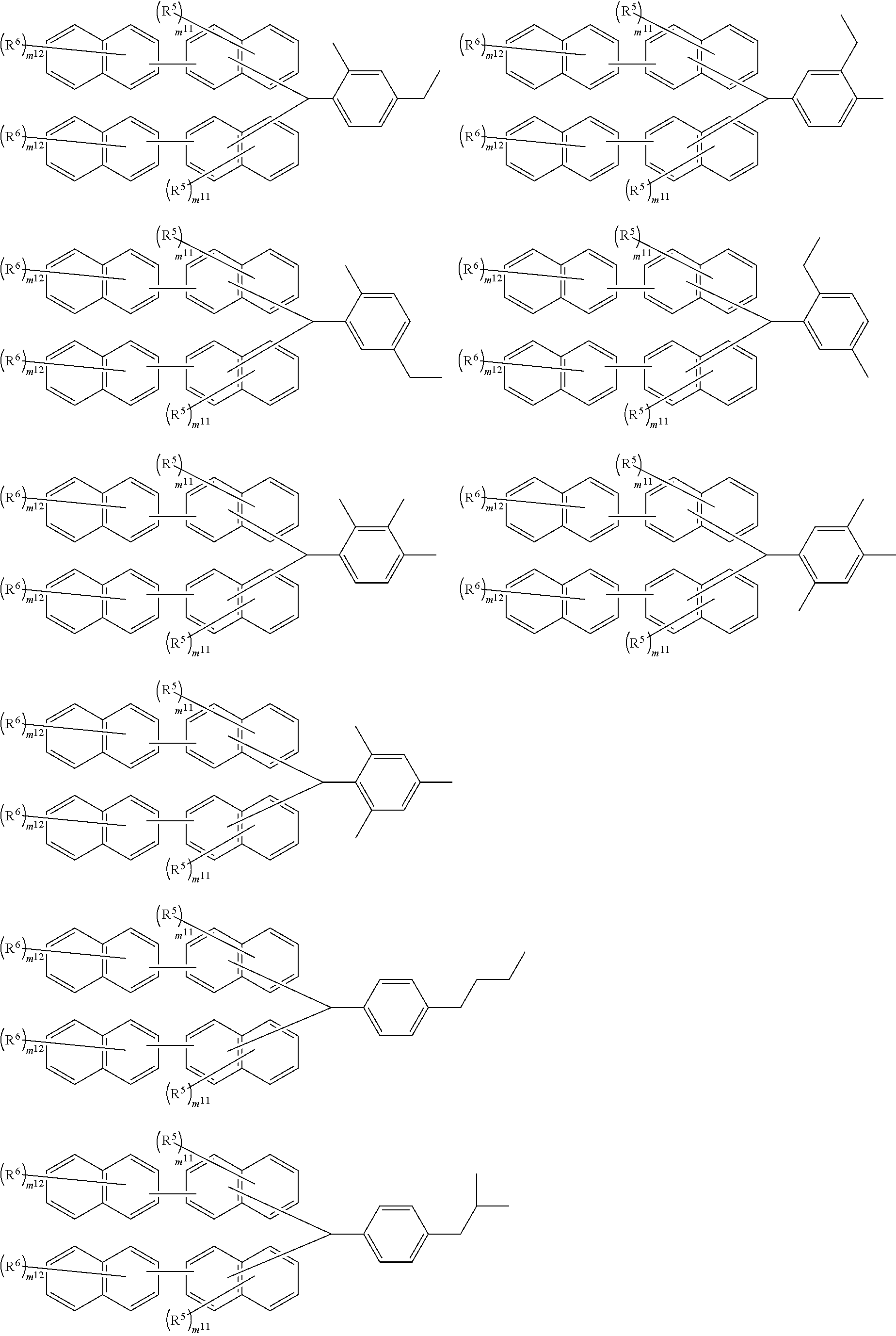

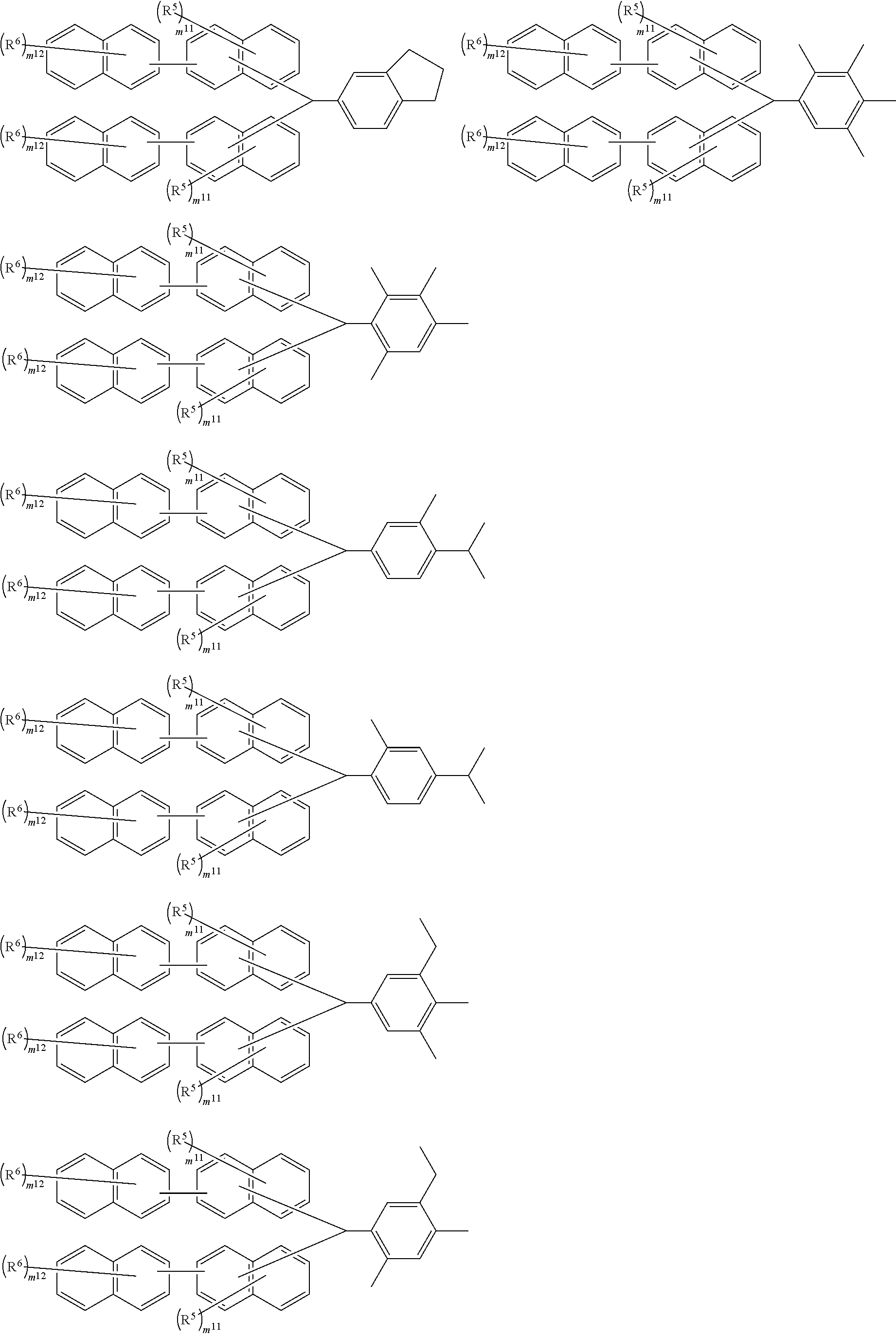

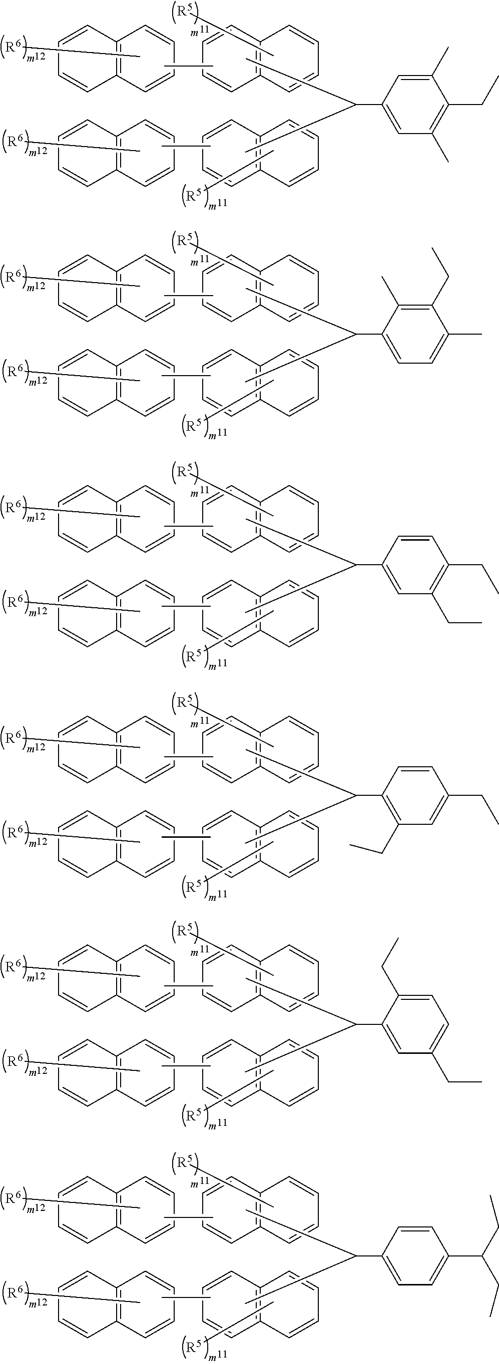

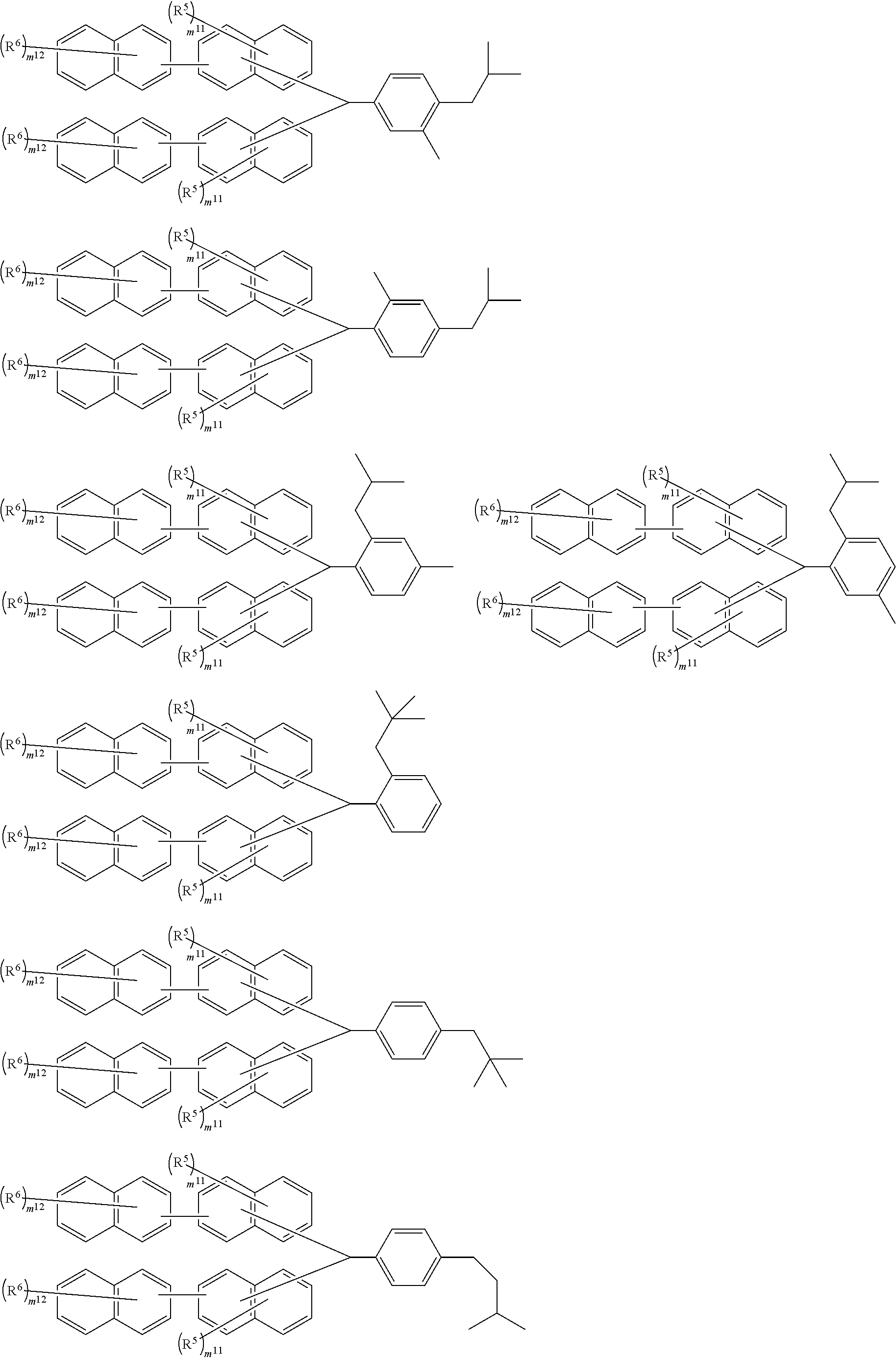

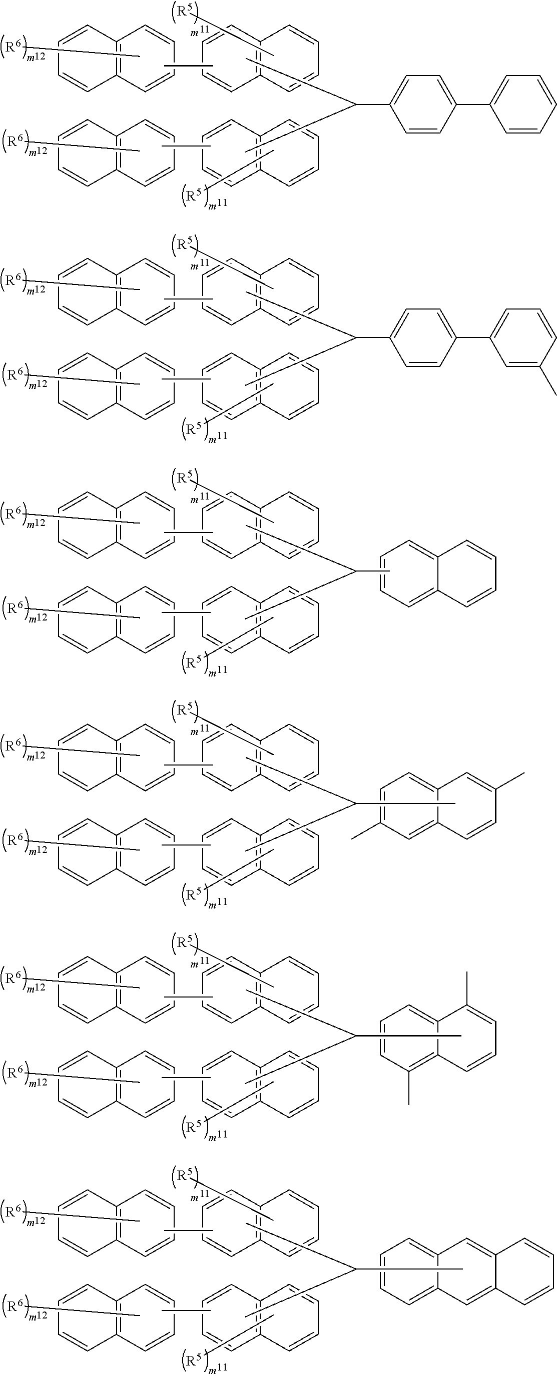

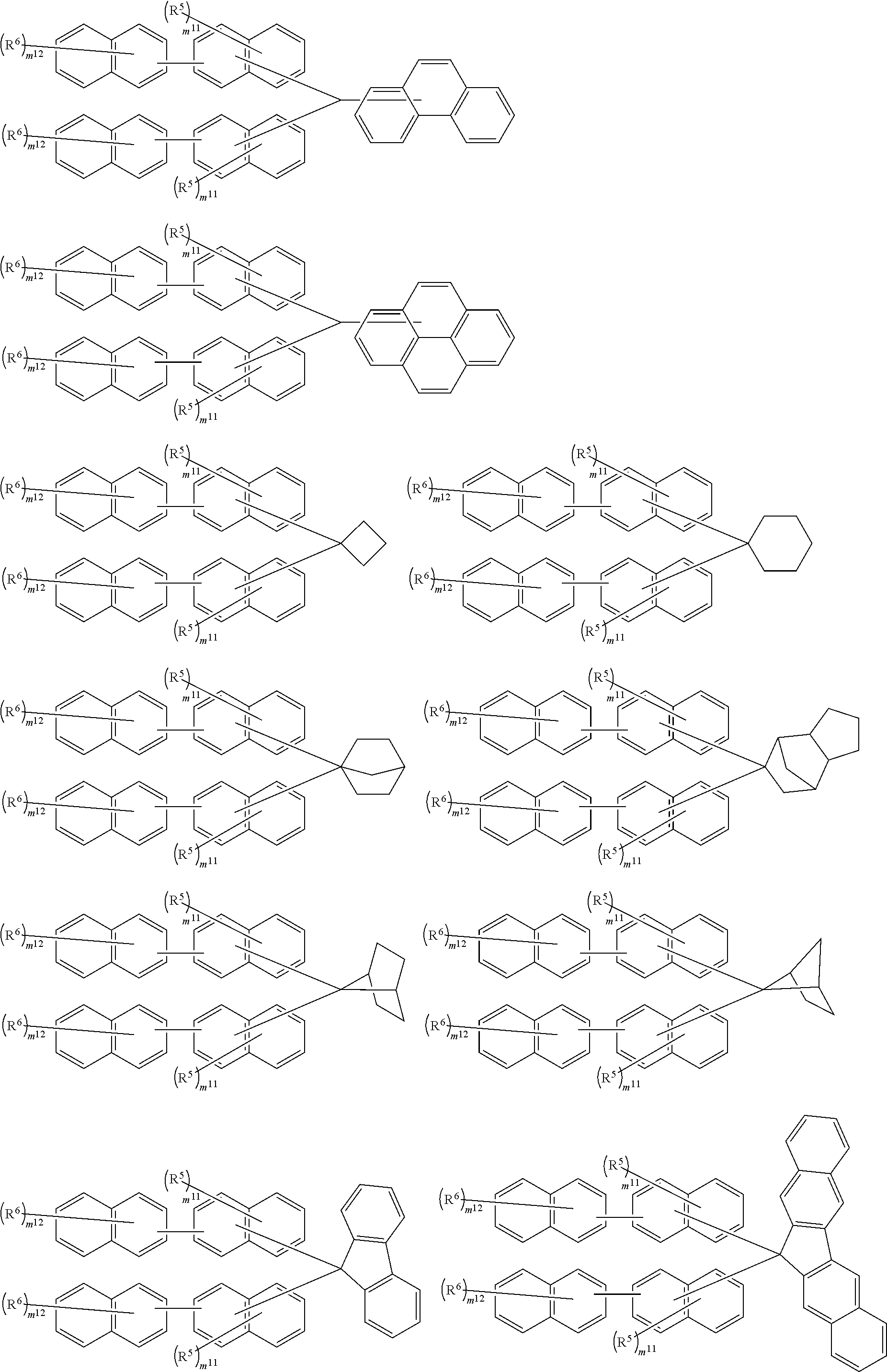

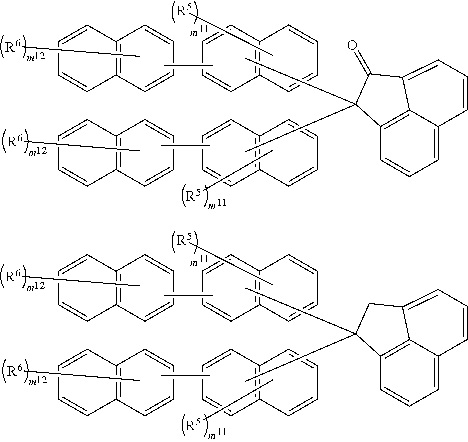

In the aromatic hydroxy compounds, R⁵ and R⁶ are as defined in the above formula (3).

m¹¹ is an integer of 0 to 6, m¹² is an integer of 0 to 7, and not all m¹¹ and m¹² are 0 at the same time.

Here, at least one R⁵ and R⁶ is a hydroxy group.

Specific examples of the aromatic hydroxy compound according to the present embodiment will be further listed below, but are not limited thereto.

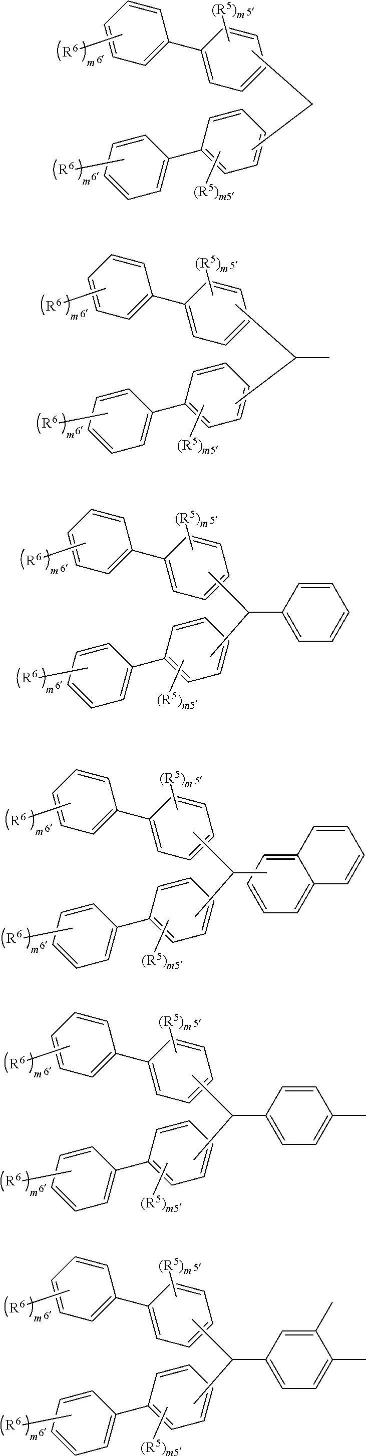

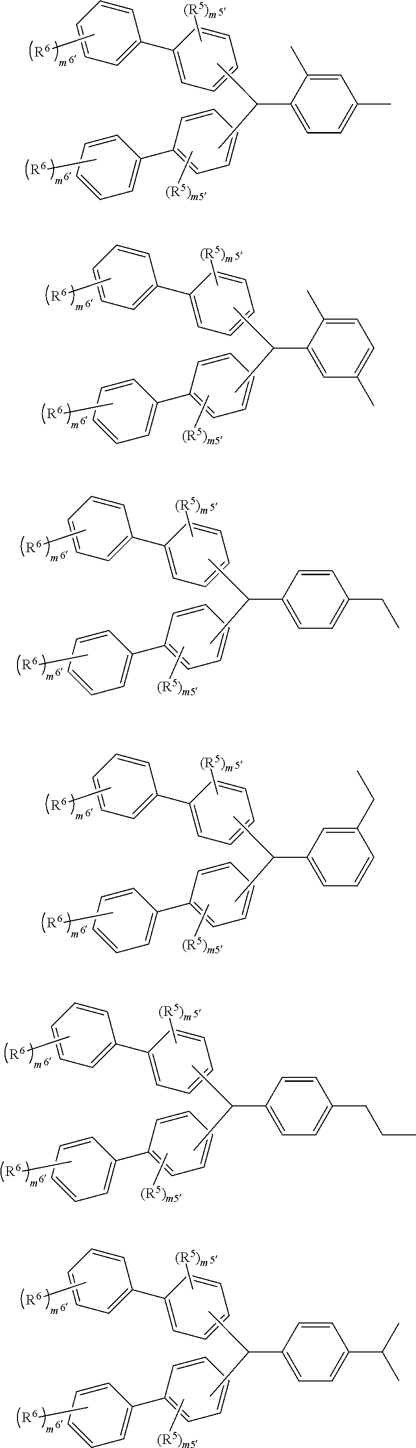

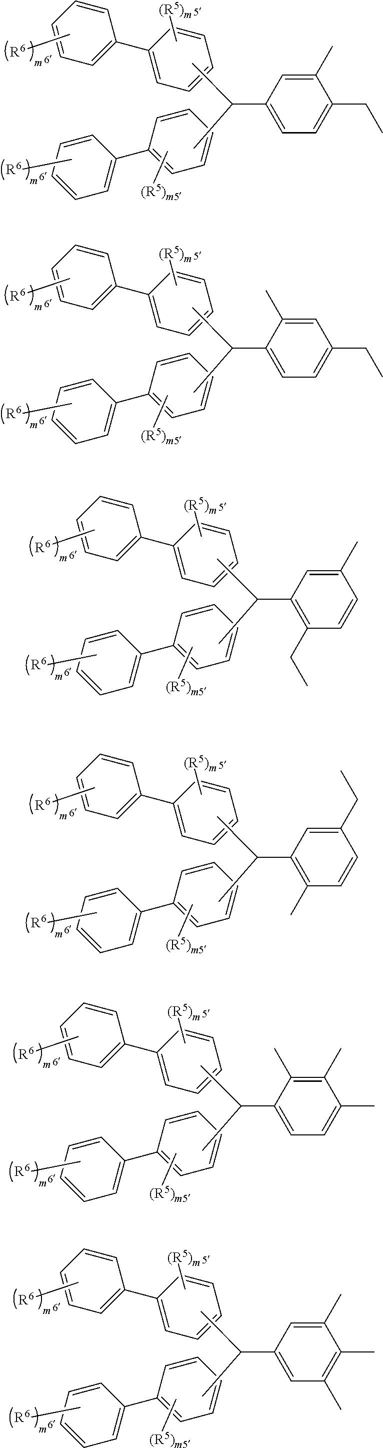

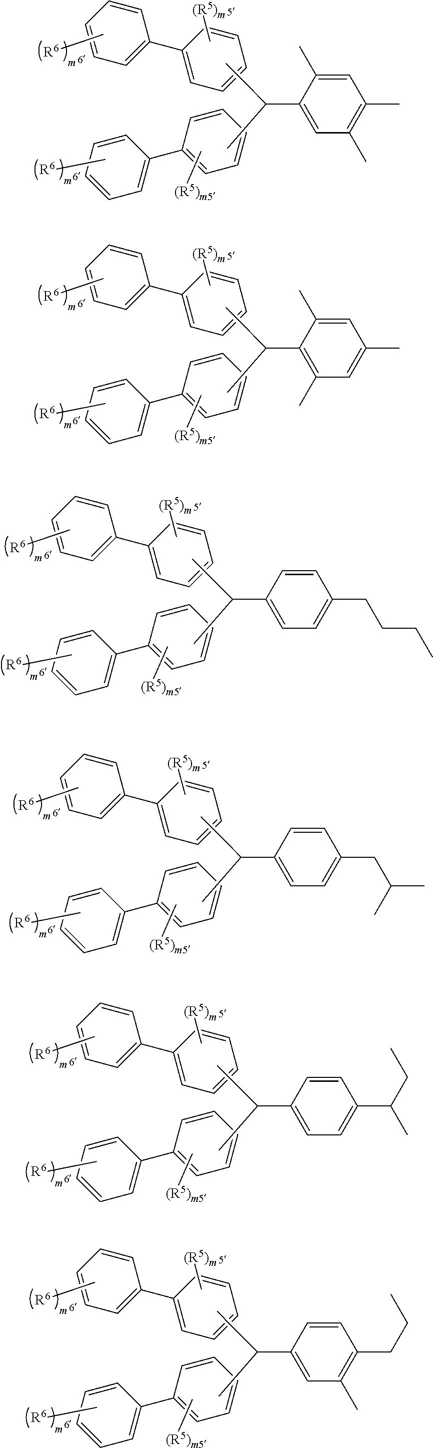

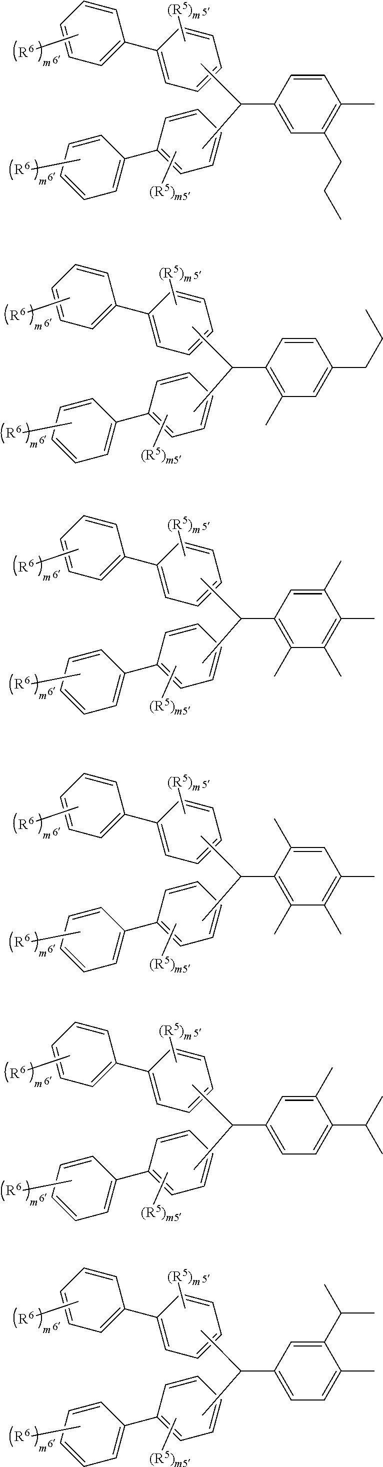

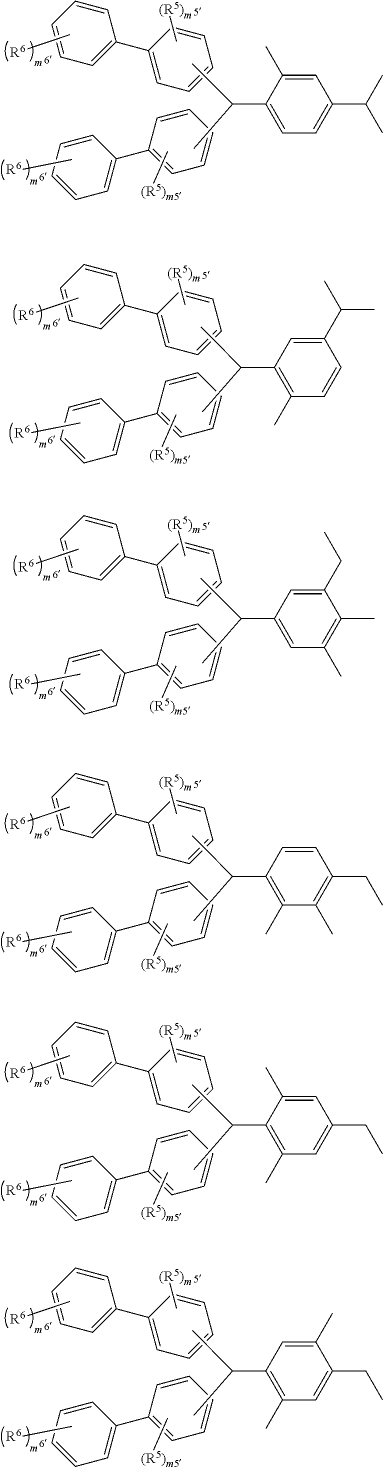

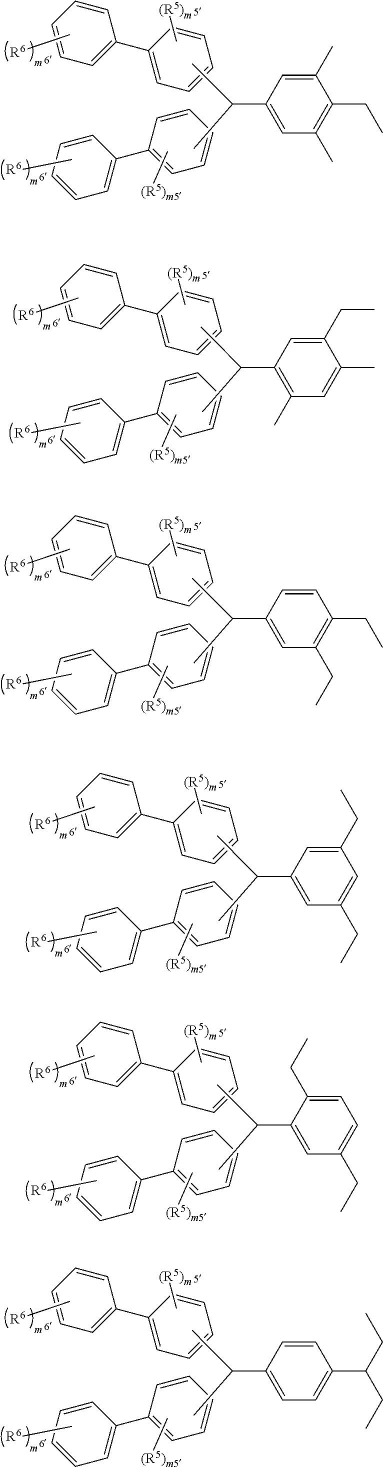

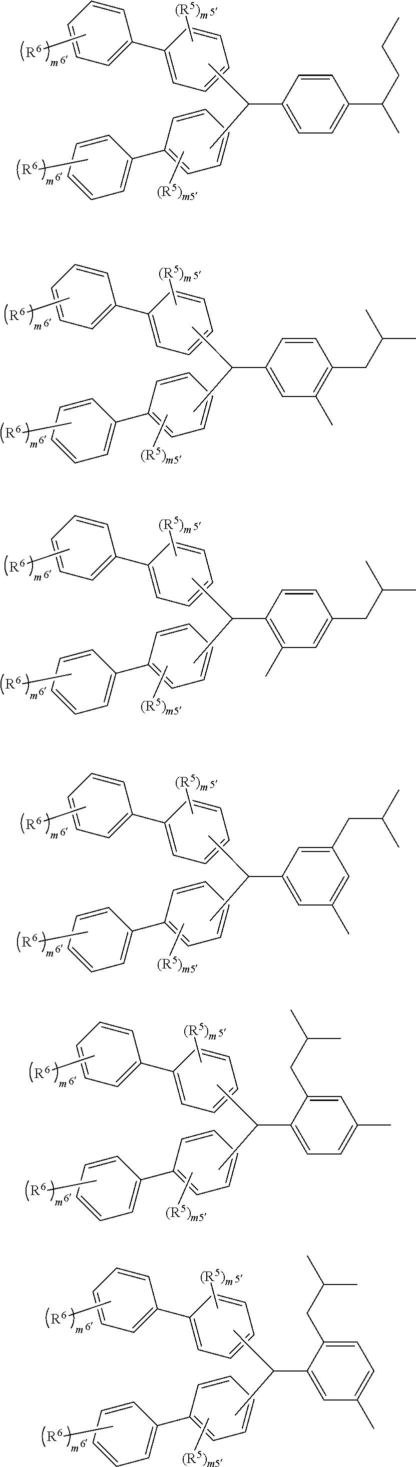

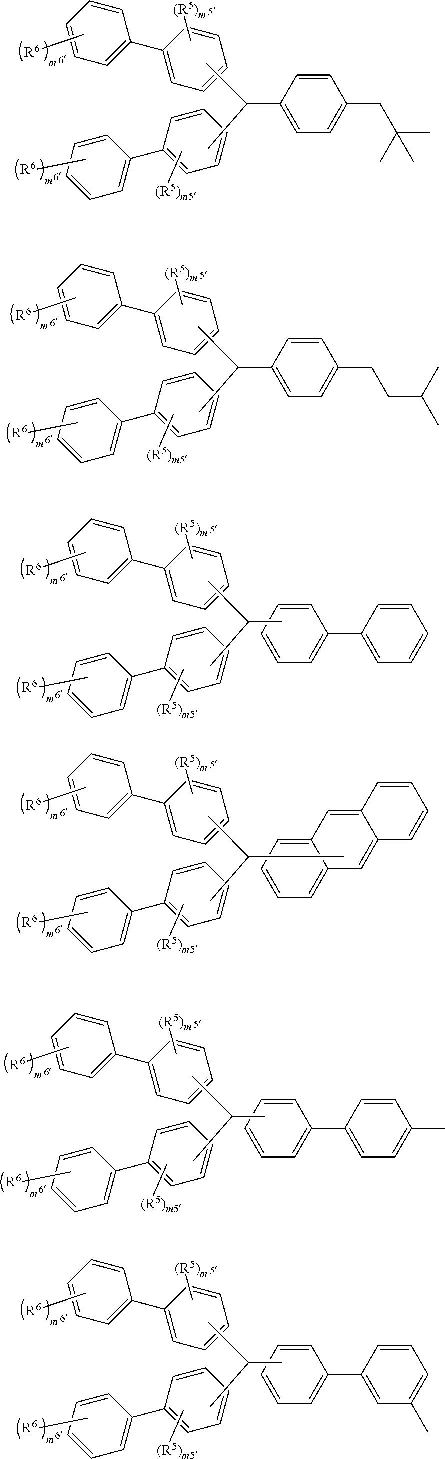

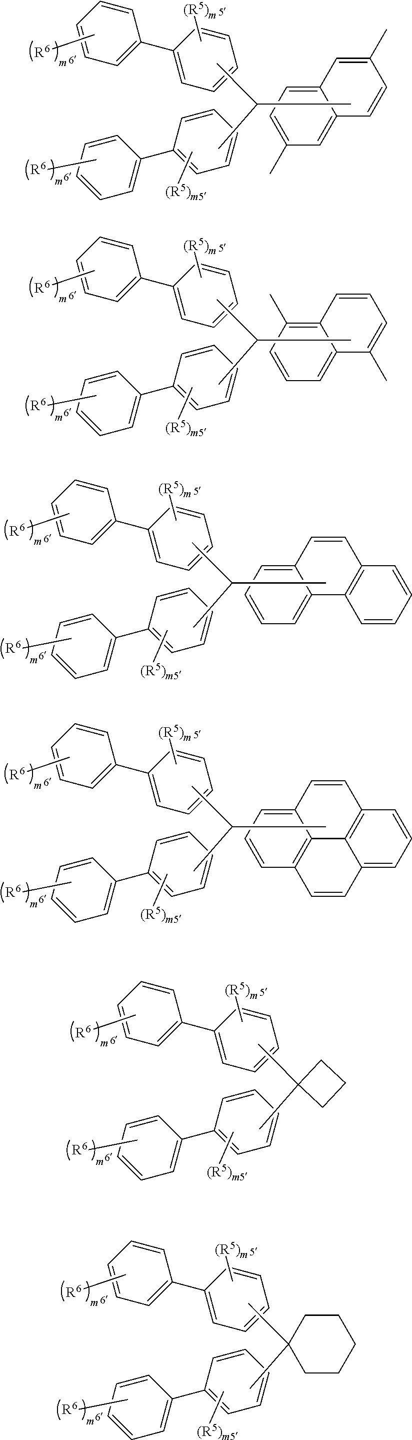

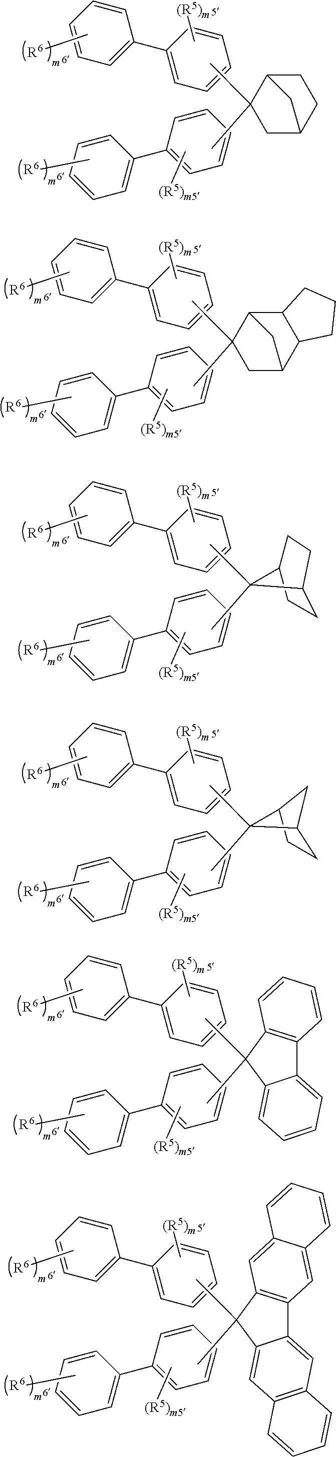

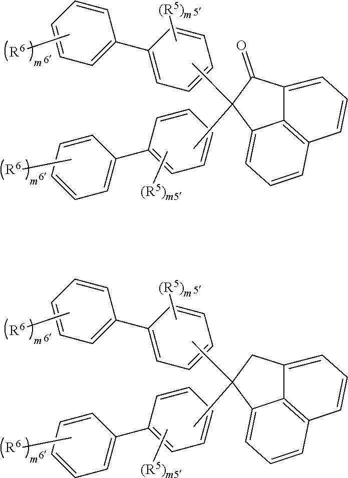

In the aromatic hydroxy compounds, R³ and R⁶ are as defined in the above formula (3).

Each m^{5′} independently an integer of 0 to 4, each m^{6′} is independently an integer of 0 to 5, and not all m^{3′} and m^{6′} are 0 at the same time.

Here, at least one R³ and R⁶ is a hydroxy group.

Specific examples of the aromatic hydroxy compound according to the present embodiment will be further listed below, but are not limited thereto.

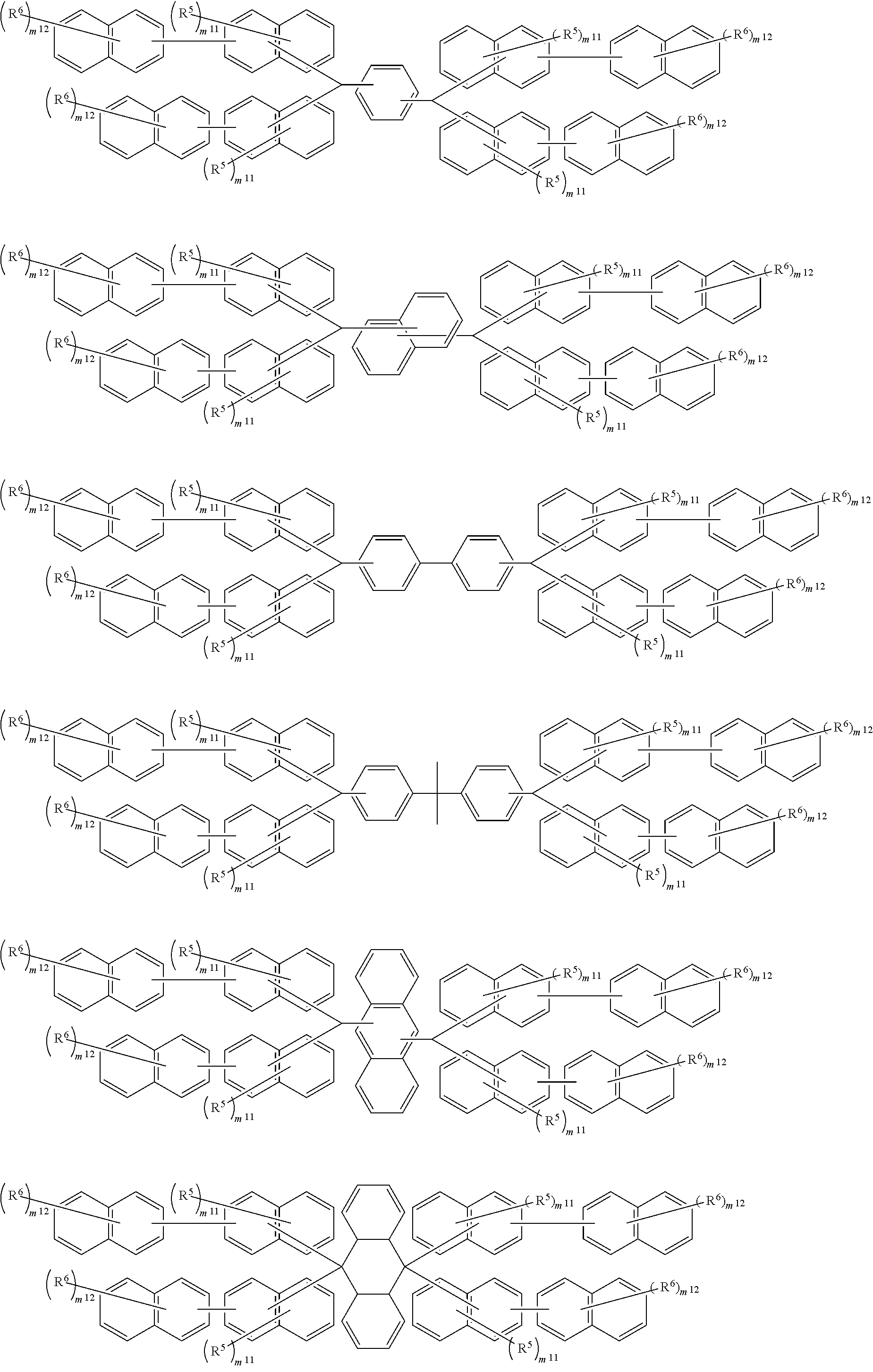

In the aromatic hydroxy compounds, R⁵ and R⁶ are as defined in the above formula (3).

m¹¹ is an integer of 0 to 6, m¹² is an integer of 0 to 7, and not all m¹¹ and m¹² are 0 at the same time.

Here, at least one R³ and R⁶ is a hydroxy group.

Specific examples of the aromatic hydroxy compound according to the present embodiment will be further listed below, but are not limited thereto.

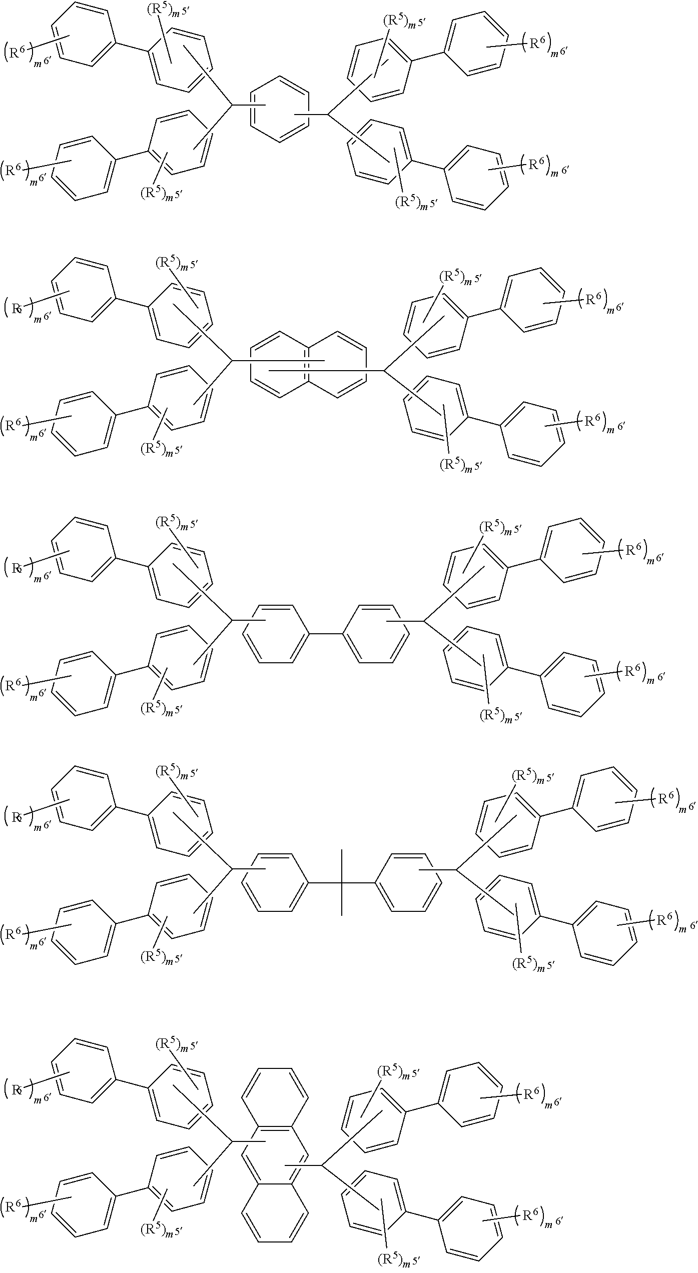

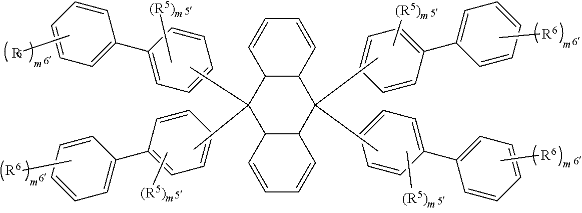

In the aromatic hydroxy compounds, R³ and R⁶ are as defined in the above formula (3).

m^{5′} is an integer of 0 to 4, m^{6′} is an integer of 0 to 5, and not all m^{5′} and m^{6′} are 0 at the same time.

Here, at least one R⁵ and R⁶ is a hydroxy group.

From the viewpoint of dissolution stability and improvement in curability, all R⁵ are preferably hydroxy groups, and from the viewpoint of further improving the dissolution stability and curability, all R⁶ are preferably hydroxy groups.

Further, A in the formula (1B) is not particularly limited, but may be, for example, a benzene ring, or any of various known fused rings such as naphthalene, anthracene, naphthacene, pentacene, benzopyrene, chrysene, pyrene, triphenylene, corannulene, coronene, and ovalene. In the present embodiment, A is preferably any of various fused rings such as naphthalene, anthracene, naphthacene, pentacene, benzopyrene, chrysene, pyrene, triphenylene, corannulene, coronene, and ovalene, from the viewpoint of heat resistance. Further, A is preferably naphthalene or anthracene because the n-value and the k-value at wavelengths 193 nm used in ArF exposure are low and pattern transferability tends to be excellent.

Examples of the above A include, in addition to the aromatic hydrocarbon rings described above, heterocycles such as pyridine, pyrrole, pyridazine, thiophene, imidazole, furan, pyrazole, oxazole, triazole, thiazole, or benzo-fused rings thereof.

In the present embodiment, the above A is preferably an aromatic hydrocarbon ring or a heterocycle, and more preferably an aromatic hydrocarbon ring.

Further, A in the formula (1B) is not particularly limited, but may be, for example, a benzene ring, or various known fused rings such as naphthalene, anthracene, naphthacene, pentacene, benzopyrene, chrysene, pyrene, triphenylene, corannulene, coronene, and ovalene. In the present embodiment, preferred examples of the aromatic hydroxy compound represented by the formula (1B) include aromatic hydroxy compounds represented by the following formulas (1B′) and (1B″).

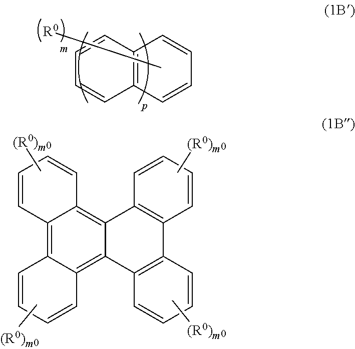

(In the formula (1B′), R⁰, m, and p are as defined in the description of the formula (1A). Further, in the formula (1B″), R⁰ is as defined in the description of the formula (1A), m⁰ is an integer of 0 to 4, and all m⁰ are not 0 at the same time.

Specific examples of the aromatic hydroxy compound represented by the formula (1B′) will be listed below, but are not limited thereto.

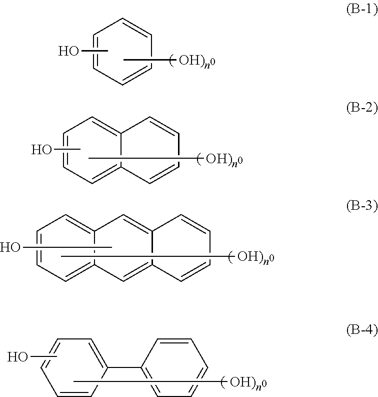

In the formula (B-1), n⁰ is an integer of 0 to 4, in the formula (B-2), n⁰ is an integer of 0 to 6, and in the formulas (B-3) to (B-4), n⁰ is an integer of 0 to 8.

Among the aromatic hydroxy compounds represented by formulas (B-1) to (B-4), those represented by formulas (B-3) to (B-4) are preferred from the viewpoint of improving etching resistance. Further, from the viewpoint of optical characteristics, those represented by (B-2) to (B-3) are preferred. Furthermore, from the viewpoint of flatness, those represented by (B-1) to (B-2) and (B-4) are preferred, and those represented by (B-4) are more preferred.

From the viewpoint of heat resistance, any one carbon atom of the aromatic ring having a phenolic hydroxy group is preferably involved in direct bonding between aromatic rings.

Specific examples of the aromatic hydroxy compound represented by the formula (1B″) will be listed below, but are not limited thereto.

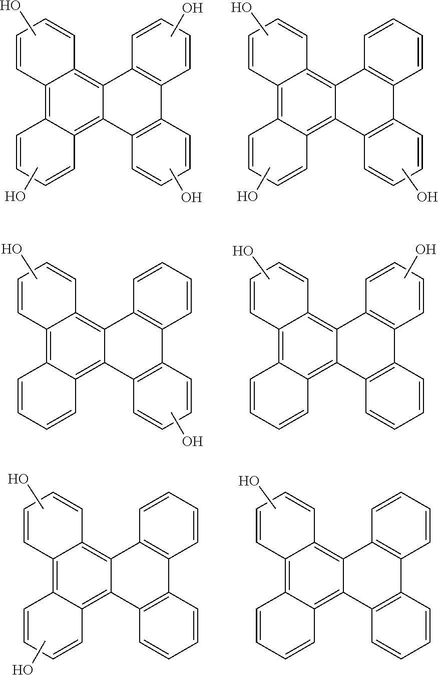

In addition to the above, an aromatic hydroxy compound represented by the following B-5 can also be used as a specific example of the formula (1B) from the viewpoint of further improving the etching resistance.

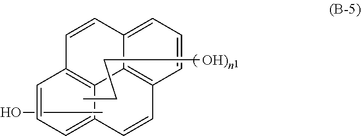

(In the formula (B-5), n¹ is an integer of 0 to 8.)

In the polycyclic polyphenolic resin of the present embodiment, the number and ratio of the respective repeating units are not particularly limited, but are preferably appropriately regulated in consideration of the application and the following values of molecular weight.

The mass-average molecular weight of the polycyclic polyphenolic resin in the present embodiment is not particularly limited, but is preferably in the range of 400 to 100,000, more preferably 500 to 15,000, and still more preferably 3200 to 12,000.

The range of the ratio of the mass-average molecular weight (Mw) to the number-average molecular weight (Mn) (Mw/Mn) is not particularly limited because the ratio required varies depending on the application, but as those having a more homogeneous molecular weight, for example, those having a ratio in the range of 3.0 or less are preferable, those having a ratio in the range of 1.05 or more and 3.0 or less are more preferable, those having a ratio in the range of 1.05 or more and less than 2.0 are particularly preferable, and those having a ratio in the range of 1.05 or more and less than 1.5 are yet still further preferable from the viewpoint of heat resistance.

The binding order of the repeating units of the polycyclic polyphenolic resin in the present embodiment in the resin is not particularly limited. For example, two or more of only the unit derived from the aromatic hydroxy compound represented by the formula (1A) may be contained as a repeating unit, two or more of only the unit derived from the aromatic hydroxy compound represented by the formula (1B) may be contained as a repeating unit, or two or more of the unit derived from the aromatic hydroxy compound represented by the formula (1A) and the unit derived from the aromatic hydroxy compound represented by the formula (1B) may be contained as one repeating unit.

The position at which the repeating units are directly bonded to each other in the polycyclic polyphenolic resin in the present embodiment is not particularly limited, and when the repeating unit is represented by the general formula (1A), any one carbon atom to which the phenolic hydroxy group and other substituents are not bonded is involved in the direct bonding between the monomers.

From the viewpoint of heat resistance, any one carbon atom of the aromatic ring having a phenolic hydroxy group is preferably involved in direct bonding between aromatic rings.

The polycyclic polyphenolic resin according to the present embodiment may contain a repeating unit having an ether bond formed by condensation of a phenolic hydroxy group within a range not impairing performance according to the application. A ketone structure may also be included.

The polycyclic polyphenolic resin according to the present embodiment preferably has high solubility in a solvent from the viewpoint of easier application to a wet process, etc. More specifically, in the case of using 1-methoxy-2-propanol (PGME) and/or propylene glycol monomethyl ether acetate (PGMEA) as a solvent, it is preferable that the polycyclic polyphenolic resin according to the present embodiment have a solubility of 1% by mass or more in the solvent at a temperature of 23° C., more preferably 5% by mass or more, and still more preferably 10% by mass or more. Here, the solubility in PGME and/or PGMEA is defined as “mass of the resin/(mass of the resin+mass of the solvent)×100 (% by mass)”. For example, 10 g of the polycyclic polyphenolic resin is evaluated as being dissolved in 90 g of PGMEA when the solubility of the polycyclic polyphenolic resin in the PGMEA is “10% by mass or more”; 10 g of the resin is evaluated as being not dissolved in 90 g of PGMEA when the solubility is “less than 10% by mass”.

### [Method for Producing Polycyclic Polyphenol]

A method for producing the polycyclic polyphenolic resin in the present embodiment is not limited to the following, but may include, for example, a step of polymerizing one or more of the aromatic hydroxy compounds in the presence of an oxidizing agent.

In carrying out such a step, the contents of K. Matsumoto, Y. Shibasaki, S. Ando and M. Ueda, Polymer, 47, 3043 (2006) can be referred to as appropriate. That is, in the oxidative polymerization of the β-naphthol type monomer, the C—C coupling at the α-position is selectively caused by an oxidative coupling reaction in which a radical subjected to one-electron oxidation due to the monomer is coupled, and for example, regioselective polymerization can be performed by using a copper/diamine type catalyst.

The oxidizing agent according to the present embodiment is not particularly limited as long as it causes an oxidative coupling reaction, and examples thereof include metal salts containing copper, manganese, iron, cobalt, ruthenium, lead, nickel, silver, tin, chromium, palladium, or the like; peroxides such as hydrogen peroxide or perchloric acids; and organic peroxides. Among these, metal salts or metal complexes containing copper, manganese, iron or cobalt can be preferably used.

Metals such as copper, manganese, iron, cobalt, ruthenium, lead, nickel, silver, tin, chromium or palladium can also be used as oxidizing agents by reduction in the reaction system. These are included in metal salts.

For example, an aromatic hydroxy compound represented by the general formula (1A) is dissolved in organic solvents, metallic salts containing copper, manganese or cobalt are added thereto, and the mixture is reacted with, for example, oxygen or an oxygen-containing gas to carry out oxidative polymerization, to obtain a desired polycyclic polyphenolic resin.

According to the method for producing a polycyclic polyphenolic resin by oxidative polymerization as described above, it is relatively easy to control the molecular weight, and since a resin having a small molecular weight distribution can be obtained without leaving a raw material monomer or a low molecular component accompanying the increase in the molecular weight, it tends to be advantageous from the viewpoint of high heat resistance and low sublimation.

As the metal salts, halides such as copper, manganese, cobalt, ruthenium, chromium and palladium, carbonates, acetates, nitrates or phosphates can be used.

The metal complex is not particularly limited, and any of known ones can be used. Specific examples thereof include, but are not limited to, complex catalysts containing copper described in Japanese Patent Laid-Open No. 36-18692, Japanese Patent Laid-Open No. 40-13423, Japanese Patent Laid-Open No. 49-490; complex catalysts containing manganese described in Japanese Patent Laid-Open No. 40-30354, Japanese Patent Laid-Open No. 47-5111, Japanese Patent Laid-Open No. 56-32523, Japanese Patent Laid-Open No. 57-44625, Japanese Patent Laid-Open No. 58-19329, Japanese Patent Laid-Open No. 60-83185; and complex catalysts containing cobalt described in Japanese Patent Laid-Open No. 45-23555.

Examples of organic peroxides include, but are not limited to, t-butyl hydroperoxide, di-t-butyl peroxide, cumene hydroperoxide, dicumyl peroxide, peracetic acid, and perbenzoic acid.

The oxidizing agents can be used alone or can be used in combination. The use amount thereof is not particularly limited, but is preferably 0.002 mol to 10 mol, more preferably 0.003 mol to 3 mol, and still more preferably 0.005 mol to 0.3 mol, based on 1 mol of the aromatic hydroxy compound. That is, the oxidizing agent according to the present embodiment can be used at a low concentration with respect to the monomer.

In the present embodiment, it is preferable to use a base in addition to the oxidizing agent used in the step of oxidative polymerization. The base is not particularly limited, and any of known bases can be used, and specific examples thereof include inorganic bases such as alkali metal hydroxides, alkaline earth metal hydroxides, and alkali metal alkoxides, and organic bases such as primary to tertiary monoamine compounds and diamines. These can be used alone, or can be used in combination.

The oxidation method is not particularly limited, and there is a method of directly using oxygen gas or air, but air oxidation is preferable from the viewpoint of safety and cost. In the case of oxidation using air under atmospheric pressure, a method of introducing air by bubbling into a liquid in a reaction solvent is preferable from the viewpoint of improving the rate of oxidative polymerization and increasing the molecular weight of the resin.

Further, the oxidizing reaction of the present embodiment can also be a reaction under pressurized conditions, and 2 kg/cm² to 15 kg/cm² are preferable from the viewpoint of accelerating reaction, and 3 kg/cm² to 10 kg/cm² are more preferable from the viewpoint of safety and controllability.

In the present embodiment, the oxidation reaction of the aromatic hydroxy compound can be performed even in the absence of a reaction solvent, but it is generally preferable to perform the reaction in the presence of a solvent. As the solvent, as long as there is no problem in obtaining the polycyclic polyphenolic resin according to the present embodiment, various known solvents can be used as long as it dissolve the catalyst to some extent. Generally, alcohols such as methanol, ethanol, propanol, and butanol; ethers such as dioxane, tetrahydrofuran, or ethylene glycol dimethyl ether; solvents such as amides or nitriles; ketones such as acetone, methyl ethyl ketone, methyl isobutyl ketone, cyclohexanone, and cyclopentanone; or mixtures thereof with water are used. Further, the reaction can also be carried out with hydrocarbons such as benzene, toluene or hexane which are not immiscible with water or in a two phase system of those and water.

The reaction conditions may be appropriately adjusted according to the substrate concentration, the type and concentration of the oxidizing agent, but the reaction temperature can be set to a relatively low temperature, preferably 5 to 150° C., and more preferably 20 to 120° C. The reaction time is preferably from 30 minutes to 24 hours, more preferably from 1 hour to 20 hours. The stirring method during the reaction is not particularly limited, and may be any of shaking and stirring using a rotator or a stirring blade. This step may be carried out in a solvent or in an air stream as long as the stirring conditions satisfy the above conditions.

The polycyclic polyphenolic resin according to the present embodiment is preferably obtained as a crude product by the above oxidation reaction, and then further purified to remove the residual oxidizing agent. That is, from the viewpoint of prevention of degradation of the resin over time and storage stability, it is preferable to avoid residues of metal salts or metal complexes containing copper, manganese, iron, or cobalt mainly used as metal oxidizing agents derived from the oxidizing agent.

The residual amount of metals derived from the oxidizing agent is preferably less than 10 ppm, more preferably less than 1 ppm, and still more preferably less than 500 ppb. When the residual amount is the 10 ppm or more, there is a tendency that it is possible to prevent a decrease in solubility of the resins in the solutions due to degradation of the resins, and there is a tendency that it is possible to prevent an increase in haze of the solutions. On the other hand, when the residual amount is less than 500 ppb, there is a tendency that the composition can be used without impairing storage stability even in the form of solutions. Thus, in the present embodiment, it is particularly preferable that the content of the impurity metals is less than 500 ppb for each metallic species.

The purification method includes, but is not particularly limited to, the steps of: obtaining a solution (S) by dissolving the polycyclic polyphenolic resin in a solvent; and extracting impurities in the resin by bringing the obtained solution (S) into contact with an acidic aqueous solution (a first extraction step), wherein the solvent used in the step of obtaining the solution (S) contains an organic solvent that does not inadvertently mix with water.

According to the purification method, the contents of various metals that may be contained as impurities in the resin can be reduced.

More specifically, the resin is dissolved in an organic solvent that does not inadvertently mix with water to obtain the solution (S), and further, extraction treatment can be performed by bringing the solution (S) into contact with an acidic aqueous solution. Thereby, metal components contained in the solution (S) are transferred to the aqueous phase, then the organic phase and the aqueous phase are separated, and thus the resin having a reduced metal content can be obtained.

The solvent that does not inadvertently mix with water used in the purification method is not particularly limited, but is preferably an organic solvent that is safely applicable to semiconductor production processes, and specifically it is an organic solvent having a solubility in water at room temperature of less than 30%, and more preferably is an organic solvent having a solubility of less than 20% and particularly preferably less than 10%. The amount of the organic solvent used is preferably 1 to 100 times the total mass of the resin to be used.

Specific examples of the solvent that does not inadvertently mix with water include, but are not limited to, ethers such as diethyl ether and diisopropyl ether, esters such as ethyl acetate, n-butyl acetate, and isoamyl acetate; ketones such as methyl ethyl ketone, methyl isobutyl ketone, ethyl isobutyl ketone, cyclohexanone, cyclopentanone, 2-heptanone, and 2-pentanone; glycol ether acetates such as ethylene glycol monoethyl ether acetate, ethylene glycol monobutyl ether acetate, propylene glycol monomethyl ether acetate (PGMEA), and propylene glycol monoethyl ether acetate; aliphatic hydrocarbons such as n-hexane and n-heptane; aromatic hydrocarbons such as toluene and xylene; and halogenated hydrocarbons such as methylene chloride and chloroform. Among these, toluene, 2-heptanone, cyclohexanone, cyclopentanone, methyl isobutyl ketone, propylene glycol monomethyl ether acetate, ethyl acetate, and the like are preferable, methyl isobutyl ketone, ethyl acetate, cyclohexanone, and propylene glycol monomethyl ether acetate are more preferable, and methyl isobutyl ketone and ethyl acetate are still more preferable. Methyl isobutyl ketone, ethyl acetate, and the like have relatively high saturation solubility for the polycyclic polyphenolic resin and a relatively low boiling point, and it is thus possible to reduce the load in the case of industrially distilling off the solvent and in the step of removing the solvent by drying. These solvents can be each used alone, or can also be used as a mixture of two or more kinds.

The acidic aqueous solution used in the purification method is appropriately selected from aqueous solutions in which organic compounds or inorganic compounds are dissolved in water, generally known as acidic aqueous solutions. Examples of the acidic aqueous solution include, but are not limited to, aqueous solutions of mineral acid in which mineral acids such as hydrochloric acid, sulfuric acid, nitric acid, and phosphoric acid are dissolved in water, or aqueous solutions of organic acid in which organic acids such as acetic acid, propionic acid, oxalic acid, malonic acid, succinic acid, fumaric acid, maleic acid, tartaric acid, citric acid, methanesulfonic acid, phenolsulfonic acid, p-toluenesulfonic acid, and trifluoroacetic acid are dissolved in water. These acidic aqueous solutions can be each used alone, and can be also used as a combination of two or more kinds. Among these acidic aqueous solutions, aqueous solutions of one or more mineral acids selected from the group consisting of hydrochloric acid, sulfuric acid, nitric acid and phosphoric acid, or aqueous solutions of one or more organic acids selected from the group consisting of acetic acid, propionic acid, oxalic acid, malonic acid, succinic acid, fumaric acid, maleic acid, tartaric acid, citric acid, methanesulfonic acid, phenolsulfonic acid, p-toluenesulfonic acid and trifluoroacetic acid are preferable, aqueous solutions of sulfuric acid, nitric acid, and carboxylic acids such as acetic acid, oxalic acid, tartaric acid and citric acid are more preferable, aqueous solutions of sulfuric acid, oxalic acid, tartaric acid and citric acid are still more preferable, and an aqueous solution of oxalic acid is even more preferable. It is considered that polyvalent carboxylic acids such as oxalic acid, tartaric acid and citric acid coordinate with metal ions and provide a chelating effect, and thus tend to be capable of more effectively removing metals. Also, as for water used herein, it is preferable to use water, the metal content of which is small, such as ion exchanged water, according to the purpose of the purification method according to the present embodiment.

The pH of the acidic aqueous solution used in the purification method is not particularly limited, but it is preferable to regulate the acidity of the aqueous solution in consideration of an influence on the resin. Normally, the pH range is about 0 to 5, and is preferably about pH 0 to 3.

The use amount of the acidic aqueous solution used in the purification method is not particularly limited, but it is preferable to regulate the amount from the viewpoint of reducing the number of extraction operations for removing metals and from the viewpoint of ensuring operability in consideration of the overall amount of fluid. From the above viewpoints, the amount of the acidic aqueous solution used is preferably 10 to 200% by mass, more preferably 20 to 100% by mass, based on 100% by mass of the solution (S).

In the purification method, by bringing the acidic aqueous solution as described above into contact with the solution (S), metal components can be extracted from the resin in the solution (S).

In the purification method, the solution (S) may further contain an organic solvent that inadvertently mixes with water. When the solution (S) contains an organic solvent that inadvertently mixes with water, there is a tendency that the amount of the resin charged can be increased, also the fluid separability is improved, and purification can be performed at a high reaction vessel efficiency. The method for adding the organic solvent that inadvertently mixes with water is not particularly limited. For example, any of a method involving adding it to the organic solvent-containing solution in advance, a method involving adding it to water or the acidic aqueous solution in advance, and a method involving adding it after bringing the organic solvent-containing solution into contact with water or the acidic aqueous solution may be employed. Among these, the method involving adding it to the organic solvent-containing solution in advance is preferable in terms of the workability of operations and the ease of managing the amount to be charged.

The organic solvent that inadvertently mixes with water used in the purification method is not particularly limited, but is preferably an organic solvent that is safely applicable to semiconductor production processes. The amount of the organic solvent used that inadvertently mixes with water is not particularly limited as long as the solution phase and the aqueous phase separate, but is preferably 0.1 to 100 times, more preferably 0.1 to 50 times, and still more preferably 0.1 to 20 times the total mass of the resin to be used.

Specific examples of the organic solvent used in the purification method that inadvertently mixes with water include, but are not limited to, ethers such as tetrahydrofuran and 1,3-dioxolane; alcohols such as methanol, ethanol, and isopropanol; ketones such as acetone and N-methylpyrrolidone; aliphatic hydrocarbons such as glycol ethers such as ethylene glycol monoethyl ether, ethylene glycol monobutyl ether, propylene glycol monomethyl ether (PGME), and propylene glycol monoethyl ether. Among these, N-methylpyrrolidone, propylene glycol monomethyl ether and the like are preferable, and N-methylpyrrolidone and propylene glycol monomethyl ether are more preferable. These solvents can be each used alone, or can also be used as a mixture of two or more kinds.

The temperature when extraction treatment is performed is usually in the range of 20 to 90° C., and preferably 30 to 80° C. The extraction operation is performed, for example, by thoroughly mixing by stirring or the like and then leaving the obtained mixed solution to stand still. Thereby, metal components contained in the solution (S) are transferred to the aqueous phase. Also, by this operation, the acidity of the solution is lowered, and the degradation of the resin can be suppressed.

By being left to stand still, the mixed solution is separated into a solution phase containing the resin and the solvents and an aqueous phase, and thus the solution phase is recovered by decantation and the like. The time for leaving the mixed solution to stand still is not particularly limited, but it is preferable to regulate the time for leaving the mixed solution to stand still from the viewpoint of attaining good separation of the solution phase containing the solvents and the aqueous phase. Normally, the time for leaving the mixed solution to stand still is 1 minute or longer, preferably 10 minutes or longer, and more preferably 30 minutes or longer. While the extraction treatment may be performed once, it is effective to repeat mixing, leaving-to-stand-still, and separating operations multiple times.

It is preferable that the purification method includes the step of extracting impurities in the resin by further bringing the solution phase containing the resin into contact with water after the first extraction step (the second extraction step). Specifically, for example, it is preferable that after the above extraction treatment is performed using an acidic aqueous solution, the solution phase that is extracted and recovered from the aqueous solution and that contains the resin and the solvents is further subjected to extraction treatment with water. The extraction treatment with water is not particularly limited, and can be performed, for example, by thoroughly mixing the solution phase and water by stirring or the like and then leaving the obtained mixed solution to stand still. The mixed solution after being left to stand still is separated into a solution phase containing the resin and the solvents and an aqueous phase, and thus the solution phase can be recovered by decantation and the like.

Water used herein is preferably water, the metal content of which is small, such as ion exchanged water, according to the purpose of the present embodiment. While the extraction treatment may be performed once, it is effective to repeat mixing, leaving-to-stand-still, and separating operations multiple times. In addition, the proportions of both used in the extraction treatment, and temperature, time and other conditions are not particularly limited, and may be the same as those of the previous contact treatment with the acidic aqueous solution.

Water that is possibly present in the thus-obtained solution containing the resin and the solvents can be easily removed by performing vacuum distillation operation or the like. Also, if required, the concentration of the resin can be regulated to be any concentration by adding a solvent to the solution.

The method for purifying the polycyclic polyphenolic resin according to the present embodiment can also be performed by passing a solution obtained by dissolving the resin in a solvent through a filter.

According to the method for purifying the substance according to the present embodiment, the content of various metal components in the resin can be effectively and significantly reduced. The amounts of these metal components can be measured by the method described in Examples below.

Herein, the term “passed through” of the present embodiment means that the above-described solution is passed from the outside of the filter through the inside of the filter and is allowed to move out of the filter again. For example, an aspect in which the solution is simply brought into contact with the surface of the filter and an aspect in which the solution is brought into contact on the surface while being allowed to move outside an ion-exchange resin (that is, an aspect in which the solution is simply brought into contact) are excluded.

### [Filter Purification Step (Liquid Passing Step)]

In the step of passing a liquid through a filter according to the present embodiment, a filter commercially available for liquid filtration can usually be used as the filter used for removing the metal component in the solution containing the resin and the solvent. The filtration accuracy of the filter is not particularly limited, but the nominal pore size of the filter is preferably 0.2 μm or less, more preferably less than 0.2 μm, still more preferably 0.1 μm or less, even more preferably less than 0.1 μm, and still further preferably 0.05 μm or less. The lower limit of the nominal pore size of the filter is not particularly limited, but is usually 0.005 μm. As used herein, the term “nominal pore size” refers to the pore size nominally used to indicate the separation performance of the filter, which is determined, for example, by any method specified by the filter manufacturer, such as a bubble point test, a mercury intrusion test or a standard particle trapping test. When using a commercially available product, the nominal pore size is a value described in the manufacturer's catalog data. The nominal pore size of 0.2 μm or less makes it possible to effectively reduce the contents of the metal components after passing the solution through the filter once. In the present embodiment, the step of passing a liquid through a filter may be performed twice or more to reduce the more content of each metal component in the solution.

Forms of the filter to be used can include a hollow fiber membrane filter, a membrane filter, a pleated membrane filter, and a filter filled with a filter medium such as a non-woven fabric, cellulose or diatomaceous earth. Among the above, the filter is preferably one or more selected from the group consisting of a hollow fiber membrane filter, a membrane filter and a pleated membrane filter. Further, it is particularly preferable to use a hollow fiber membrane filter, in particular due to its high precision filtration accuracy and its higher filtration area than other forms.

Examples of a material for the filter can include a polyolefin such as polyethylene and polypropylene; a polyethylene-based resin having a functional group having an ion exchange capacity provided by graft polymerization; a polar group-containing resin such as polyamide, polyester and polyacrylonitrile; and a fluorine-containing resin such as fluorinated polyethylene (PTFE). Among the above, the filter is preferably made of one or more filter media selected from the group consisting of a polyamide, a polyolefin resin and a fluororesin. Further, a polyamide medium is particularly preferable from the viewpoint of the reduction effect of heavy metals such as chromium. From the viewpoint of avoiding metal elution from the filter medium, it is preferable to use a filter other than the sintered metal material.

Examples of the polyamide-based filter can include (hereinafter described under the trade name), but are not limited to: Polyfix nylon series manufactured by KITZ MICROFILTER CORPORATION; Ultipleat P-Nylon 66 and Ultipor N66 manufactured by Nihon Pall Ltd.; and LifeASSURE PSN series and LifeASSURE EF series manufactured by 3M Company.

Examples of polyolefin-based filter can include, but are not limited to: Ultipleat PE Clean and Ion Clean manufactured by Nihon Pall Ltd.; Protego series, Microgard Plus HC10 and Optimizer D manufactured by Entegris Japan Co., Ltd.

Examples of the polyester-based filter can include, but are not limited to: Geraflow DFE manufactured by Central Filter Mfg. Co., Ltd.; and a pleated type PMC manufactured by Nihon Filter Co., Ltd.

Examples of the polyacrylonitrile-based filter can include, but are not limited to: Ultrafilters AIP-0013D, ACP-0013D and ACP-0053D manufactured by Advantec Toyo Kaisha, Ltd.

Examples of the fluororesin-based filter can include, but are not limited to: Emflon HTPFR manufactured by Nihon Pall Ltd.; and LifeASSURE FA series manufactured by 3M Company.

These filters can be used alone or can be used in combination of two or more thereof.

The filter may also contain an ion exchanger such as a cation-exchange resin, or a cation charge controlling agent and the like that causes a zeta potential in an organic solvent solution to be filtered.

Examples of the filter containing an ion exchanger can include, but are not limited to: Protego series manufactured by Entegris Japan Co., Ltd.; and KURANGRAFT manufactured by Kurashiki Textile Manufacturing Co., Ltd. Examples of the filter containing a material having a positive zeta potential such as a cationic polyamidepolyamine-epichlorohydrin resin include (hereinafter described under the trade name), but are not limited to: Zeta Plus 40QSH and Zeta Plus 020GN and LifeASSURE EF series manufactured by 3M company.

The method for isolating the resin from the obtained solution containing the resin and the solvents is not particularly limited, and publicly known methods can be performed, such as reduced-pressure removal, separation by reprecipitation, and a combination thereof. Publicly known treatments such as concentration operation, filtration operation, centrifugation operation, and drying operation can be performed if required.

The polycyclic polyphenolic resin in the present embodiment may further have a modified portion derived from a crosslinking compound. That is, the polycyclic polyphenolic resin in the present embodiment having the structure described above may have a modified portion obtained by reaction with the crosslinking compound. Such a (modified) polycyclic polyphenolic resin is also excellent in heat resistance and etching resistance, and can be used as a coating agent for semiconductors, a material for resists, and a semiconductor underlayer film forming material.

Examples of the crosslinking compound include, but are not limited to, aldehydes, ketones, carboxylic acids, carboxylic acid halides, a halogen containing compound, an amino compound, an imino compound, an isocyanate compound, and an unsaturated hydrocarbon group containing compound. These can be used alone or in combination as appropriate.

In the present embodiment, the crosslinking compound is preferably an aldehyde or a ketone. More specifically, it is preferably a polycyclic polyphenolic resin obtained by subjecting the polycyclic polyphenolic resin according to the present embodiment having the structure described above to a polycondensation reaction with an aldehyde or a ketone in the presence of an acid catalyst. For example, a novolac type polycyclic polyphenolic resin can be obtained by subjecting an aldehyde or a ketone corresponding to a desired structure to a further polycondensation reaction under normal pressure and optionally pressurized conditions under an acid catalyst.

Examples of the aldehyde include, but are not particularly limited to, methylbenzaldehyde, dimethylbenzaldehyde, trimethylbenzaldehyde, ethylbenzaldehyde, propylbenzaldehyde, butylbenzaldehyde, pentabenzaldehyde, butylmethylbenzaldehyde, hydroxybenzaldehyde, dihydroxybenzaldehyde, and fluoromethylbenzaldehyde. These aldehydes can be used alone as one kind or can be used in combination of two or more kinds. Among them, methylbenzaldehyde, dimethylbenzaldehyde, trimethylbenzaldehyde, ethylbenzaldehyde, propylbenzaldehyde, butylbenzaldehyde, pentabenzaldehyde, butylmethylbenzaldehyde, or the like is preferably used from the viewpoint of imparting high heat resistance.

Examples of the ketone include, but are not particularly limited to, acetylmethylbenzene, acetyldimethylbenzene, acetyltrimethylbenzene, acetylethylbenzene, acetylpropylbenzene, acetylbutylbenzene, acetylpentabenzene, acetylbutylmethylbenzene, acetylhydroxybenzene, acetyldihydroxybenzene, and acetylfluoromethylbenzene. These ketones can be used alone as one kind or can be used in combination of two or more kinds. Among them, acetylmethylbenzene, acetyldimethylbenzene, acetyltrimethylbenzene, acetylethylbenzene, acetylpropylbenzene, acetylbutylbenzene, acetylpentabenzene, or acetylbutylmethylbenzene is preferably used from the viewpoint of imparting high heat resistance.

The acid catalyst used in the above reaction can be appropriately selected for use from publicly known acid catalysts and is not particularly limited. Inorganic acids and organic acids are widely known as such acid catalysts. Specific examples of the above acid catalyst include, but are not particularly limited to, inorganic acids such as hydrochloric acid, sulfuric acid, phosphoric acid, hydrobromic acid, and hydrofluoric acid; organic acids such as oxalic acid, malonic acid, succinic acid, adipic acid, sebacic acid, citric acid, fumaric acid, maleic acid, formic acid, p-toluenesulfonic acid, methanesulfonic acid, trifluoroacetic acid, dichloroacetic acid, trichloroacetic acid, trifluoromethanesulfonic acid, benzenesulfonic acid, naphthalenesulfonic acid, and naphthalenedisulfonic acid; Lewis acids such as zinc chloride, aluminum chloride, iron chloride, and boron trifluoride; and solid acids such as tungstosilicic acid, tungstophosphoric acid, silicomolybdic acid, and phosphomolybdic acid. Among them, organic acids and solid acids are preferable from the viewpoint of production, and hydrochloric acid or sulfuric acid is preferably used from the viewpoint of production such as easy availability and handleability. The acid catalysts can be used alone as one kind or can be used in combination of two or more kinds. Further, the amount of the acid catalyst used can be appropriately set according to, the kind of the raw materials used and the catalyst used and moreover the reaction conditions and is not particularly limited, but is preferably 0.01 to 100 parts by mass based on 100 parts by mass of the reaction raw materials.

Upon the above reaction, a reaction solvent may be used. The reaction solvent is not particularly limited as long as the reaction of the aldehyde or the ketone used with the polycyclic polyphenolic resin proceeds, and can be appropriately selected and used from publicly known solvents. Examples thereof include water, methanol, ethanol, propanol, butanol, tetrahydrofuran, dioxane, ethylene glycol dimethyl ether, ethylene glycol diethyl ether, and a mixed solvent thereof. The solvents can be used alone as one kind or can be used in combination of two or more kinds. Also, the amount of these solvents used can be appropriately set according to the kind of the raw materials used and the acid catalyst used and moreover the reaction conditions. The amount of the above solvent used is not particularly limited, but is preferably in the range of 0 to 2000 parts by mass based on 100 parts by mass of the reaction raw materials. Furthermore, the reaction temperature in the above reaction can be appropriately selected according to the reactivity of the reaction raw materials. The above reaction temperature is not particularly limited, but is usually preferably within the range of 10 to 200° C. The reaction method can be appropriately selected and used from publicly known approaches and is not particularly limited, and there are a method of charging the polycyclic polyphenolic resin according to the present embodiment, the aldehyde or the ketone, and the acid catalyst in one portion, and a method of dropping the aldehyde or the ketone in the presence of the acid catalyst. After the polycondensation reaction terminates, isolation of the obtained compound can be performed according to a conventional method, and is not particularly limited. For example, by adopting a commonly used approach in which the temperature of the reaction vessel is elevated to 130 to 230° C. in order to remove unreacted raw materials, acid catalyst, etc. present in the system, and volatile portions are removed at about 1 to 50 mmHg, the compound which is the target compound can be obtained.

The polycyclic polyphenolic resin according to the present embodiment can be used as a composition assuming the various applications. That is, the composition of the present embodiment contains the polycyclic polyphenolic resin according to the present embodiment. The composition of the present embodiment preferably further contains a solvent from the viewpoint of facilitating film formation by the application of a wet process, or the like.

Specific examples of the solvent include, but not particularly limited to: ketone-based solvents such as acetone, methyl ethyl ketone, methyl isobutyl ketone, and cyclohexanone; cellosolve-based solvents such as propylene glycol monomethyl ether and propylene glycol monomethyl ether acetate; ester-based solvents such as ethyl lactate, methyl acetate, ethyl acetate, butyl acetate, isoamyl acetate, ethyl lactate, methyl methoxypropionate, and methyl hydroxyisobutyrate; alcohol-based solvents such as methanol, ethanol, isopropanol, and 1-ethoxy-2-propanol; and aromatic hydrocarbons such as toluene, xylene, and anisole. These solvents can be used alone as one kind or can be used in combination of two or more kinds.

Among the above solvents, propylene glycol monomethyl ether, propylene glycol monomethyl ether acetate, cyclohexanone, cyclopentanone, ethyl lactate, and methyl hydroxyisobutyrate is particularly preferable from the viewpoint of safety.

The content of the solvent is not particularly limited and is preferably 100 to 10,000 parts by mass based on 100 parts by mass of the polycyclic polyphenolic resin according to the present embodiment, more preferably 200 to 5,000 parts by mass, and still more preferably 200 to 1,000 parts by mass, from the viewpoint of solubility and film formation.

### [Application of Composition for Film Formation]

The composition for film formation of the present embodiment contains the above polycyclic polyphenolic resin, but may have various compositions depending on the specific application thereof, and hereinafter, the composition for film formation may be referred to as a “resist composition”, a “radiation-sensitive composition”, or a “composition for underlayer film formation for lithography” depending on the application or composition thereof.

### [Resist Composition]

A resist composition of the present embodiment comprises the composition for film formation of the present embodiment. That is, the resist composition of the present embodiment contains the polycyclic polyphenolic resin according to the present embodiment as an essential component, and may further contain any of various optional components in consideration of use as a resist material. Specifically, the resist composition of the present embodiment preferably further contains at least one selected from the group consisting of a solvent, an acid generating agent, and an acid diffusion controlling agent.

### (Solvent)

Further, the solvent that the resist composition of the present embodiment may contain is not particularly limited, and any of various known organic solvents can be used. For example, those described in International Publication No. WO 2013/024778 can be used. These solvents can be used alone or can be used in combination of two or more kinds.

The solvent used in the present embodiment is preferably a safe solvent, more preferably at least one selected from propylene glycol monomethyl ether acetate (PGMEA), propylene glycol monomethyl ether (PGME), cyclohexanone (CHN), cyclopentanone (CPN), 2-heptanone, anisole, butyl acetate, ethyl propionate, and ethyl lactate, and still more preferably at least one selected from PGMEA, PGME, and CHN.

The amount of the solid component (component other than the solvent in the resist composition of the present embodiment) and the amount of the solvent in the present embodiment is not particularly limited, but preferably the solid component is 1 to 80% by mass and the solvent is 20 to 99% by mass, more preferably the solid component is 1 to 50% by mass and the solvent is 50 to 99% by mass, still more preferably the solid component is 2 to 40% by mass and the solvent is 60 to 98% by mass, and particularly preferably the solid component is 2 to 10% by mass and the solvent is 90 to 98% by mass, based on 100% by mass of the total mass of the amount of the solid component and the solvent.

### (Acid Generating Agent (C))

The resist composition of the present embodiment preferably contains one or more acid generating agents (C) generating an acid directly or indirectly by irradiation of any radiation selected from visible light, ultraviolet, excimer laser, electron beam, extreme ultraviolet (EUV), X-ray, and ion beam. The acid generating agent (C) is not particularly limited, and, for example, an acid generating agent described in International Publication No. WO 2013/024778 can be used. The acid generating agent (C) can be used alone or can be used in combination of two or more kinds.

The amount of the acid generating agent (C) used is preferably 0.001 to 49% by mass of the total weight of the solid components, more preferably 1 to 40% by mass, still more preferably 3 to 30% by mass, and particularly preferably 10 to 25% by mass. By using the acid generating agent (C) within the above range, a pattern profile with high sensitivity and low edge roughness is obtained. In the present embodiment, the acid generation method is not limited as long as an acid is generated in the system. By using excimer laser instead of ultraviolet such as g-ray and i-ray, finer processing is possible, and also by using electron beam, extreme ultraviolet, X-ray or ion beam as a high energy ray, further finer processing is possible.

### (Acid Crosslinking Agent (G))

In the present embodiment, the resist composition preferably contains one or more acid crosslinking agents (G). The acid crosslinking agent (G) is a compound capable of intramolecularly or intermolecularly crosslinking the component (A) in the presence of the acid generated from the acid generating agent (C). Examples of such an acid crosslinking agent (G) can include a compound having one or more groups (hereinafter, referred to as a “crosslinkable group”) capable of crosslinking the component (A).

Examples of such a crosslinkable group can include, but are not particularly limited to, (i) a hydroxyalkyl group such as a hydroxy (C1-C6 alkyl group), a C1-C6 alkoxy (C1-C6 alkyl group), and an acetoxy (C1-C6 alkyl group), or a group derived therefrom; (ii) a carbonyl group such as a formyl group and a carboxy (C1-C6 alkyl group), or a group derived therefrom; (iii) a nitrogenous group-containing group such as a dimethylaminomethyl group, a diethylaminomethyl group, a dimethylolaminomethyl group, a diethylolaminomethyl group, and a morpholinomethyl group; (iv) a glycidyl group-containing group such as a glycidyl ether group, a glycidyl ester group, and a glycidylamino group; (v) a group derived from an aromatic group such as a C1-C6 allyloxy (C1-C6 alkyl group) and a C1-C6 aralkyloxy (C1-C6 alkyl group) such as a benzyloxymethyl group and a benzoyloxymethyl group; and (vi) a polymerizable multiple bond-containing group such as a vinyl group and an isopropenyl group. As the crosslinkable group of the acid crosslinking agent (G) according to the present embodiment, a hydroxyalkyl group and an alkoxyalkyl group or the like are preferable, and an alkoxymethyl group is particularly preferable.

The acid crosslinking agent (G) having the above crosslinkable group is not particularly limited, and, for example, an acid crosslinking agent described in International Publication No. WO 2013/024778 can be used. The acid crosslinking agent (G) can be used alone or can be used in combination of two or more kinds.

In the present embodiment, the amount of the acid crosslinking agent (G) used is preferably 0.5 to 49% by mass of the total weight of the solid components, more preferably 0.5 to 40% by mass, still more preferably 1 to 30% by mass, and particularly preferably 2 to 20% by mass. When the content ratio of the above acid crosslinking agent (G) is 0.5% by mass or more, the inhibiting effect of the solubility of a resist film in an alkaline developing solution is improved, and a decrease in the film remaining rate, and occurrence of swelling and meandering of a pattern can be inhibited, which is preferable. On the other hand, when the content ratio is 50% by mass or less, a decrease in heat resistance as a resist can be inhibited, which is preferable.

### (Acid Diffusion Controlling Agent (E))

In the present embodiment, the resist composition may contain an acid diffusion controlling agent (E) having a function of controlling diffusion of an acid generated from an acid generating agent by radiation irradiation in a resist film to inhibit any unpreferable chemical reaction in an unexposed region or the like. By using such an acid diffusion controlling agent (E), the storage stability of a resist composition is improved. Also, along with the improvement of the resolution, the line width change of a resist pattern due to variation in the post exposure delay time before radiation irradiation and the post exposure delay time after radiation irradiation can be inhibited, and the composition has extremely excellent process stability. Such an acid diffusion controlling agent (E) is not particularly limited, and examples thereof include a radiation degradable basic compound such as a nitrogen atom-containing basic compound, a basic sulfonium compound, and a basic iodonium compound.

The above acid diffusion controlling agent (E) is not particularly limited, and, for example, an acid diffusion controlling agent described in International Publication No. WO 2013/024778 can be used. The acid diffusion controlling agent (E) can be used alone or can be used in combination of two or more kinds.

The content of the acid diffusion controlling agent (E) is preferably 0.001 to 49% by mass of the total weight of the solid component, more preferably 0.01 to 10% by mass, still more preferably 0.01 to 5% by mass, and particularly preferably 0.01 to 3% by mass. Within the above range, a decrease in resolution, and deterioration of the pattern shape and the dimension fidelity or the like can be prevented. Moreover, even though the post exposure delay time from electron beam irradiation to heating after radiation irradiation becomes longer, the shape of the pattern upper layer portion does not deteriorate. When the content is 10% by mass or less, a decrease in sensitivity, and developability of the unexposed portion or the like can be prevented. Also, by using such an acid diffusion controlling agent, the storage stability of a resist composition is improved, also along with improvement of the resolution, the line width change of a resist pattern due to variation in the post exposure delay time before radiation irradiation and the post exposure delay time after radiation irradiation can be inhibited, making the composition extremely excellent in process stability.

### (Further Component (F))

To the resist composition of the present embodiment, if required, as the further component (F), one kind or two or more kinds of various additive agents such as a dissolution promoting agent, a dissolution controlling agent, a sensitizing agent, a surfactant, and an organic carboxylic acid or an oxo acid of phosphorus or derivative thereof can be added.

### (Dissolution Promoting Agent)

A low molecular weight dissolution promoting agent is a component having a function of increasing the solubility of the polycyclic polyphenolic resin according to the present embodiment in a developing solution to moderately increase the dissolution rate of the compound upon developing, when the solubility of the compound is too low. The low molecular weight dissolution promoting agent can be used, if required. Examples of the above dissolution promoting agent can include a phenolic compound having a low molecular weight, such as a bisphenol and a tris(hydroxyphenyl) methane. These dissolution promoting agents can be used alone or can be used in mixture of two or more kinds.

The content of the dissolution promoting agent, which is appropriately adjusted according to the kind of the compound to be used, is preferably 0 to 49% by mass of the total weight of the solid component, more preferably 0 to 5% by mass, still more preferably 0 to 1% by mass, and particularly preferably 0% by mass.

### (Dissolution Controlling Agent)

The dissolution controlling agent is a component having a function of controlling the solubility of the polycyclic polyphenolic resin according to the present embodiment in a developing solution to moderately decrease the dissolution rate upon developing, when the solubility of the polycyclic polyphenolic resin according to the present embodiment is too high. As such a dissolution controlling agent, the one which does not chemically change in steps such as calcination of resist coating, radiation irradiation, and development is preferable.

The dissolution controlling agent is not particularly limited, and examples thereof can include an aromatic hydrocarbon such as phenanthrene, anthracene and acenaphthene; a ketone such as acetophenone, benzophenone and phenyl naphthyl ketone; and a sulfone such as methyl phenyl sulfone, diphenyl sulfone and dinaphthyl sulfone. These dissolution controlling agents can be used alone or can be used in combination of two or more kinds.

The content of the dissolution controlling agent, which is appropriately adjusted according to the kind of the compound to be used, is preferably 0 to 49% by mass of the total weight of the solid component, more preferably 0 to 5% by mass, still more preferably 0 to 1% by mass, and particularly preferably 0% by mass.

### (Sensitizing Agent)

The sensitizing agent is a component having a function of absorbing irradiated radiation energy, transmitting the energy to the acid generating agent (C), and thereby increasing the acid production amount, and improving the apparent sensitivity of a resist. Examples of such a sensitizing agent can include, but are not particularly limited to, a benzophenone, a biacetyl, a pyrene, a phenothiazine and a fluorene. These sensitizing agents can be used alone or can be used in combination of two or more kinds.

The content of the sensitizing agent, which is appropriately adjusted according to the kind of the compound to be used, is preferably 0 to 49% by mass of the total weight of the solid component, more preferably 0 to 5% by mass, still more preferably 0 to 1% by mass, and particularly preferably 0% by mass.

### (Surfactant)

The surfactant is a component having a function of improving coatability and striation of the resist composition of the present embodiment, and developability of a resist or the like. Such a surfactant may be any of anionic, cationic, nonionic, and amphoteric surfactants. A preferable surfactant is a nonionic surfactant. The nonionic surfactant has a good affinity with a solvent used in production of resist compositions and more effects. Examples of the nonionic surfactant include, but are not particularly limited to, a polyoxyethylene higher alkyl ether, a polyoxyethylene higher alkyl phenyl ether, and a higher fatty acid diester of polyethylene glycol. Examples of the commercially available product thereof can include, but are not particularly limited to, hereinafter by trade name, EFTOP (manufactured by Jemco Inc.), MEGAFAC (manufactured by DIC Corporation), Fluorad (manufactured by Sumitomo 3M Limited), AsahiGuard, Surflon (hereinbefore, manufactured by Asahi Glass Co., Ltd.), Pepole (manufactured by Toho Chemical Industry Co., Ltd.), KP (manufactured by Shin-Etsu Chemical Co., Ltd.), and Polyflow (manufactured by Kyoeisha Yushi Kagaku Kogyo Co., Ltd.).

The content of the surfactant, which is appropriately adjusted according to the kind of the compound to be used, is preferably 0 to 49% by mass of the total weight of the solid component, more preferably 0 to 5% by mass, still more preferably 0 to 1% by mass, and particularly preferably 0% by mass.

### (Organic Carboxylic Acid or Oxo Acid of Phosphorus or Derivative Thereof)

For the purpose of prevention of sensitivity deterioration or improvement of a resist pattern shape and post exposure delay stability or the like, and as an additional optional component, the composition of the present embodiment can contain an organic carboxylic acid or an oxo acid of phosphorus or derivative thereof. The organic carboxylic acid or the oxo acid of phosphorus or derivative thereof can be used in combination with the acid diffusion controlling agent, or may be used alone. Suitable examples of the organic carboxylic acid include malonic acid, citric acid, malic acid, succinic acid, benzoic acid and salicylic acid. Examples of the oxo acid of phosphorus or derivative thereof include phosphoric acid or derivative thereof such as ester including phosphoric acid, di-n-butyl phosphate and diphenyl phosphate; phosphonic acid or derivative thereof such as ester including phosphonic acid, dimethyl phosphonate, di-n-butyl phosphonate, phenylphosphonic acid, diphenyl phosphonate and dibenzyl phosphonate; and phosphinic acid and derivative thereof such as ester including phosphinic acid and phenylphosphinic acid. Among these, phosphonic acid is particularly preferable.

The organic carboxylic acid or the oxo acid of phosphorus or derivative thereof can be used alone, or can be used in combination of two or more kinds. The content of the organic carboxylic acid or the oxo acid of phosphorus or derivative thereof, which is appropriately adjusted according to the kind of the compound to be used, is preferably 0 to 49% by mass of the total weight of the solid component, more preferably 0 to 5% by mass, still more preferably 0 to 1% by mass, and particularly preferably 0% by mass.

(Further Additive Agent Other than Above Additive Agents (Dissolution Promoting Agent, Dissolution Controlling Agent, Sensitizing Agent, Surfactant, and Organic Carboxylic Acid or Oxo Acid of Phosphorus or Derivative Thereof))

Furthermore, the resist composition of the present embodiment can contain one kind or two or more kinds of additive agents other than the above dissolution controlling agent, sensitizing agent, surfactant, and organic carboxylic acid or oxo acid of phosphorus or derivative thereof if required. Examples of such an additive agent include a dye, a pigment, and an adhesion aid. For example, when the composition contains the dye or the pigment, a latent image of the exposed portion is visualized and influence of halation upon exposure can be alleviated, which is preferable. In addition, when the composition contains the adhesion aid, adhesiveness to a substrate can be improved, which is preferable. Furthermore, examples of other additive agent can include, but are not particularly limited to, a halation preventing agent, a storage stabilizing agent, a defoaming agent, and a shape improving agent. Specific examples thereof can include 4-hydroxy-4′-methylchalcone.

In the resist composition of the present embodiment, the total content of the optional component (F) is 0 to 99% by mass of the total weight of the solid components, preferably 0 to 49% by mass, more preferably 0 to 10% by mass, still more preferably 0 to 5% by mass, still more preferably 0 to 1% by mass, and particularly preferably 0% by mass.

### [Content Ratio of Each Component in Resist Composition]

In the resist composition of the present embodiment, the content of the polycyclic polyphenolic resin according to the present embodiment (the component (A)) is not particularly limited, but is preferably 50 to 99.4% by mass of the total mass of the solid components (summation of solid components including the polycyclic polyphenolic resin (A), and optionally used components such as acid generating agent (C), acid crosslinking agent (G), acid diffusion controlling agent (E), and further component (F) (also referred to as “optional component (F)”), hereinafter the same applies to the resist composition.), more preferably 55 to 90% by mass, still more preferably 60 to 80% by mass, and particularly preferably 60 to 70% by mass. In the case of the above content, there is a tendency that resolution is further improved and that line edge roughness (LER) is further decreased.

In the resist composition of the present embodiment, the content ratio of the polycyclic polyphenolic resin according to the present embodiment (component (A)), the acid generating agent (C), the acid crosslinking agent (G), the acid diffusion controlling agent (E), and the optional component (F) (the component (A)/the acid generating agent (C)/the acid crosslinking agent (G)/the acid diffusion controlling agent (E)/the optional component (F)) is preferably 50 to 99.4% by mass/0.001 to 49% by mass/0.5 to 49% by mass/0.001 to 49% by mass/0 to 49% by mass based on 100% by mass of the solid content of the resist composition, more preferably 55 to 90% by mass/i to 40% by mass/0.5 to 40% by mass/0.01 to 10% by mass/0 to 5% by mass, still more preferably 60 to 80% by mass/3 to 30% by mass/i to 30% by mass/0.01 to 5% by mass/0 to 1% by mass, and particularly preferably 60 to 70% by mass/10 to 25% by mass/2 to 20% by mass/0.01 to 3% by mass/0% by mass. The content ratio of each component is selected from each range so that the summation thereof is 100% by mass. Through the above content ratio, there is a tendency that performance such as sensitivity, resolution and developability is excellent. The “solid content” refers to components except for the solvent. “100% by mass of the solid content” refer to 100% by mass of the components except for the solvent.

The resist composition of the present embodiment is usually prepared by dissolving each component in a solvent upon use into a homogeneous solution, and then if required, filtering through a filter or the like with a pore diameter of about 0.2 μm, for example.

The resist composition of the present embodiment can contain an additional resin other than the polycyclic polyphenolic resin according to the present embodiment, if required. Examples of the additional resin include, but are not particularly limited to, a novolac resin, a polyvinyl phenol, a polyacrylic acid, a polyvinyl alcohol, a styrene-maleic anhydride resin, and a polymer containing acrylic acid, vinyl alcohol or vinylphenol as a monomeric unit, and derivatives thereof. The content of the additional resin is not particularly limited and is appropriately adjusted according to the kind of the component (A) to be used, and is preferably 30 parts by mass or less based on 100 parts by mass of the component (A), more preferably 10 parts by mass or less, still more preferably 5 parts by mass or less, and particularly preferably 0 parts by mass.

### [Physical Properties and the Like of Resist Composition]

The resist composition of the present embodiment can form an amorphous film by spin coating. Also, the resist composition can be applied to a general semiconductor production process. Any of positive type and negative type resist patterns can be individually prepared depending on the kind of a developing solution to be used.

In the case of a positive type resist pattern, the dissolution rate of the amorphous film formed by spin coating with the resist composition of the present embodiment in a developing solution at 23° C. is preferably 5 angstrom/sec or less, more preferably 0.05 to 5 angstrom/sec, and still more preferably 0.0005 to 5 angstrom/sec. When the dissolution rate is 5 angstrom/sec or less, the above portion is insoluble in a developing solution, and thus the amorphous film can form a resist. When the amorphous film has a dissolution rate of 0.0005 angstrom/sec or more, the resolution may improve. It is presumed that this is because due to the change in the solubility before and after exposure of the component (A), contrast at the interface between the exposed portion being dissolved in a developing solution and the unexposed portion not being dissolved in a developing solution is increased. Also, there are effects of reducing LER and defects.

In the case of a negative type resist pattern, the dissolution rate of the amorphous film formed by spin coating with the resist composition of the present embodiment in a developing solution at 23° C. is preferably 10 angstrom/sec or more. When the dissolution rate is 10 angstrom/sec or more, the amorphous film more easily dissolves in a developing solution, and is more suitable for a resist. When the amorphous film has a dissolution rate of 10 angstrom/sec or more, the resolution may improve. It is presumed that this is because the micro surface portion of the component (A) dissolves, and LER is reduced. Also, there are effects of reducing defects.

The above dissolution rate can be determined by immersing the amorphous film in a developing solution for a predetermined period of time at 23° C. and then measuring the film thickness before and after the immersion by a publicly known method such as visual inspection, ellipsometry, or cross-sectional observation with a scanning electron microscope.

In the case of a positive type resist pattern, the dissolution rate of the portion exposed by radiation such as KrF excimer laser, extreme ultraviolet, electron beam or X-ray, of the amorphous film formed by spin coating with the resist composition of the present embodiment, in a developing solution at 23° C. is preferably 10 angstrom/sec or more. When the dissolution rate is 10 angstrom/sec or more, the amorphous film more easily dissolves in a developing solution, and is more suitable for a resist. In addition, when the amorphous film has a dissolution rate of 10 angstrom/sec or more, the resolution may be improved. It is presumed that this is because the micro surface portion of the component (A) dissolves, and LER is reduced. Also, there are effects of reducing defects.

In the case of a negative type resist pattern, the dissolution rate of the portion exposed by radiation such as KrF excimer laser, extreme ultraviolet, electron beam or X-ray, of the amorphous film formed by spin coating with the resist composition of the present embodiment, in a developing solution at 23° C. is preferably 5 angstrom/sec or less, more preferably 0.05 to 5 angstrom/sec, and still more preferably 0.0005 to 5 angstrom/sec. When the dissolution rate is 5 angstrom/sec or less, the above portion is insoluble in a developing solution, and thus the amorphous film can form a resist. When the amorphous film has a dissolution rate of 0.0005 angstrom/sec or more, the resolution may improve. It is presumed that this is because due to the change in the solubility before and after exposure of the component (A), contrast at the interface between the unexposed portion being dissolved in a developing solution and the exposed portion not being dissolved in a developing solution is increased. Also, there are effects of reducing LER and defects.

### [Radiation-Sensitive Composition]

A radiation-sensitive composition of the present embodiment contains the composition for film formation of the present embodiment, an optically active diazonaphthoquinone compound (B), and a solvent, wherein the content of the solvent is 20 to 99% by mass based on 100% by mass in total of the radiation-sensitive composition; and the content of components except for the solvent is 1 to 80% by mass based on 100% by mass in total of the radiation-sensitive composition. That is, the radiation-sensitive composition of the present embodiment contains the polycyclic polyphenolic resin according to the present embodiment, the optically active diazonaphthoquinone compound (B), and a solvent as essential components, and may further contain any of various optional components in consideration of being radiation-sensitive.

The radiation-sensitive composition of the present embodiment contains the polycyclic polyphenolic resin (component (A)) and is used in combination with the optically active diazonaphthoquinone compound (B) and is useful as a base material for positive type resists that becomes a compound easily soluble in a developing solution by irradiation with g-ray, h-ray, i-ray, KrF excimer laser, ArF excimer laser, extreme ultraviolet, electron beam, or X-ray. Although the properties of the component (A) are not largely altered by g-ray, h-ray, i-ray, KrF excimer laser, ArF excimer laser, extreme ultraviolet, electron beam, or X-ray, the optically active diazonaphthoquinone compound (B) poorly soluble in a developing solution is converted to an easily soluble compound so that a resist pattern can be formed in a development step.

As described above, since the component (A) to be contained in the radiation-sensitive composition of the present embodiment is a compound having a relatively low molecular weight, the obtained resist pattern has very small roughness.

The glass transition temperature of the component (A) to be contained in the radiation-sensitive composition of the present embodiment is preferably 100° C. or higher, more preferably 120° C. or higher, still more preferably 140° C. or higher, and particularly preferably 150° C. or higher. The upper limit of the glass transition temperature of the component (A) is not particularly limited and is, for example, 400° C. When the glass transition temperature of the component (A) falls within the above range, there is a tendency that the resulting radiation-sensitive composition has heat resistance capable of maintaining a pattern shape in a semiconductor lithography process, and improves performance such as high resolution.

The heat of crystallization determined by the differential scanning calorimetry of the glass transition temperature of the component (A) to be contained in the radiation-sensitive composition of the present embodiment is preferably less than 20 J/g. Also, (Crystallization temperature)−(Glass transition temperature) is preferably 70° C. or more, more preferably 80° C. or more, still more preferably 100° C. or more, and particularly preferably 130° C. or more. When the heat of crystallization is less than 20 J/g or when (Crystallization temperature)−(Glass transition temperature) falls within the above range, there is a tendency that the radiation-sensitive composition easily forms an amorphous film by spin coating, can maintain film formability necessary for a resist over a long period, and can improve resolution.

In the present embodiment, the above heat of crystallization, crystallization temperature, and glass transition temperature can be determined by differential scanning calorimetry using “DSC/TA-50WS” manufactured by Shimadzu Corp. For example, about 10 mg of a sample is placed in an unsealed container made of aluminum, and the temperature is raised to the melting point or more at a temperature increase rate of 20° C./min in a nitrogen gas stream (50 mL/min). After quenching, again the temperature is raised to the melting point or more at a temperature increase rate of 20° C./min in a nitrogen gas stream (30 mL/min). After further quenching, again the temperature is raised to 400° C. at a temperature increase rate of 20° C./min in a nitrogen gas stream (30 mL/min). The temperature at the middle point (where the specific heat is changed into the half) of steps in the baseline shifted in a step-like pattern is defined as the glass transition temperature (Tg). The temperature of the subsequently appearing exothermic peak is defined as the crystallization temperature. The heat is determined from the area of a region surrounded by the exothermic peak and the baseline and defined as the heat of crystallization.

The component (A) to be contained in the radiation-sensitive composition of the present embodiment is preferably low sublimable at 100 or lower, preferably 120° C. or lower, more preferably 130° C. or lower, still more preferably 140° C. or lower, and particularly preferably 150° C. or lower at normal pressure. The low sublimability means that in thermogravimetry, weight reduction when the resist base material is kept at a predetermined temperature for 10 minutes is 10% or less, preferably 5% or less, more preferably 3% or less, still more preferably 1% or less, and particularly preferably 0.1% or less. The low sublimability can prevent an exposure apparatus from being contaminated by outgassing upon exposure. In addition, a good pattern shape with low roughness can be obtained.

The component (A) to be contained in the radiation-sensitive composition of the present embodiment dissolves at preferably 1% by mass or more, more preferably 5% by mass or more, and still more preferably 10% by mass or more at 23° C. in a solvent that is selected from propylene glycol monomethyl ether acetate (PGMEA), propylene glycol monomethyl ether (PGME), cyclohexanone (CHN), cyclopentanone (CPN), 2-heptanone, anisole, butyl acetate, ethyl propionate, and ethyl lactate and exhibits the highest ability to dissolve the component (A). Further preferably, the component (A) dissolves at 20% by mass or more at 23° C. in a solvent that is selected from PGMEA, PGME, and CHN and exhibits the highest ability to dissolve the component (A). Particularly preferably, the component (A) dissolves at 20% by mass or more at 23° C. in PGMEA. When the above conditions are met, the radiation-sensitive composition can be used in a semiconductor production process at a full production scale.

### (Optically Active Diazonaphthoquinone Compound (B))

The optically active diazonaphthoquinone compound (B) to be contained in the radiation-sensitive composition of the present embodiment is a diazonaphthoquinone substance including a polymer or non-polymer optically active diazonaphthoquinone compound and is not particularly limited as long as it is generally used as a photosensitive component (sensitizing agent) in positive type resist compositions. One kind or two or more kinds can be optionally selected and used.

Such a sensitizing agent is preferably a compound obtained by reacting naphthoquinonediazide sulfonic acid chloride, benzoquinonediazide sulfonic acid chloride, or the like with a low molecular weight compound or a high molecular weight compound having a functional group condensable with these acid chlorides. Here, examples of the above functional group condensable with the acid chlorides include, but are not particularly limited to, a hydroxy group and an amino group. Particularly, a hydroxy group is suitable. Examples of the compound containing a hydroxy group condensable with the acid chlorides can include, but are not particularly limited to, hydroquinone; resorcin; hydroxybenzophenones such as 2,4-dihydroxybenzophenone, 2,3,4-trihydroxybenzophenone, 2,4,6-trihydroxybenzophenone, 2,4,4′-trihydroxybenzophenone, 2,3,4,4′-tetrahydroxybenzophenone, 2,2′,4,4′-tetrahydroxybenzophenone, and 2,2′,3,4,6′-pentahydroxybenzophenone; hydroxyphenylalkanes such as bis(2,4-dihydroxyphenyl)methane, bis(2,3,4-trihydroxyphenyl)methane, and bis(2,4-dihydroxyphenyl)propane; and hydroxytriphenylmethanes such as 4,4′,3″,4″-tetrahydroxy-3,5,3′,5′-tetramethyltriphenylmethane and 4,4′,2″,3″,4″-pentahydroxy-3,5,3′,5′-tetramethyltriphenylmethane.

Also, preferable examples of the acid chloride such as naphthoquinonediazide sulfonic acid chloride or benzoquinonediazide sulfonic acid chloride include 1,2-naphthoquinonediazide-5-sulfonyl chloride and 1,2-naphthoquinonediazide-4-sulfonyl chloride.

The radiation-sensitive composition of the present embodiment is preferably prepared by, for example, dissolving each component in a solvent upon use into a homogeneous solution, and then if required, filtering through a filter or the like with a pore diameter of about 0.2 μm, for example.

### (Solvent)

Examples of the solvent that can be used in the radiation-sensitive composition of the present embodiment include, but are not particularly limited to, propylene glycol monomethyl ether acetate, propylene glycol monomethyl ether, cyclohexanone, cyclopentanone, 2-heptanone, anisole, butyl acetate, ethyl propionate, and ethyl lactate. Among them, propylene glycol monomethyl ether acetate, propylene glycol monomethyl ether, or cyclohexanone is preferable. The solvent may be used alone as one kind or may be used in combination of two or more kinds.

The content of the solvent is 20 to 99% by mass based on 100% by mass in total of the radiation-sensitive composition, preferably 50 to 99% by mass, more preferably 60 to 98% by mass, and particularly preferably 90 to 98% by mass.

The content of components except for the solvent (solid components) is 1 to 80% by mass based on 100% by mass in total of the radiation-sensitive composition, preferably 1 to 50% by mass, more preferably 2 to 40% by mass, and particularly preferably 2 to 10% by mass.

### [Properties of Radiation-Sensitive Composition]

The radiation-sensitive composition of the present embodiment can form an amorphous film by spin coating. Also, the radiation-sensitive composition of the present embodiment can be applied to a general semiconductor production process. Any of positive type and negative type resist patterns can be individually prepared depending on the kind of a developing solution to be used.

In the case of a positive type resist pattern, the dissolution rate of the amorphous film formed by spin coating with the radiation-sensitive composition of the present embodiment in a developing solution at 23° C. is preferably 5 angstrom/sec or less, more preferably 0.05 to 5 angstrom/sec, and still more preferably 0.0005 to 5 angstrom/sec. When the dissolution rate is 5 angstrom/sec or less, the above portion is insoluble in a developing solution, and thus the amorphous film can form a resist. When the amorphous film has a dissolution rate of 0.0005 angstrom/sec or more, the resolution may improve. It is presumed that this is because due to the change in the solubility before and after exposure of the component (A), contrast at the interface between the exposed portion being dissolved in a developing solution and the unexposed portion not being dissolved in a developing solution is increased. Also, there are effects of reducing LER and defects.

In the case of a negative type resist pattern, the dissolution rate of the amorphous film formed by spin coating with the radiation-sensitive composition of the present embodiment in a developing solution at 23° C. is preferably 10 angstrom/sec or more. When the dissolution rate is 10 angstrom/sec or more, the amorphous film more easily dissolves in a developing solution, and is more suitable for a resist. In addition, when the amorphous film has a dissolution rate of 10 angstrom/sec or more, the resolution may be improved. It is presumed that this is because the micro surface portion of the component (A) dissolves, and LER is reduced. Also, there are effects of reducing defects.

The above dissolution rate can be determined by immersing the amorphous film in a developing solution for a predetermined period of time at 23° C. and then measuring the film thickness before and after the immersion by a publicly known method such as visual inspection, ellipsometry, or QCM method.

In the case of a positive type resist pattern, the dissolution rate of the exposed portion after irradiation with radiation such as KrF excimer laser, extreme ultraviolet, electron beam or X-ray, or after heating at 20 to 500° C., of the amorphous film formed by spin coating with the radiation-sensitive composition of the present embodiment, in a developing solution at 23° C. is preferably 10 angstrom/sec or more, more preferably 10 to 10000 angstrom/sec, and still more preferably 100 to 1000 angstrom/sec. When the dissolution rate is 10 angstrom/sec or more, the amorphous film more easily dissolves in a developing solution, and is more suitable for a resist. When the amorphous film has a dissolution rate of 10000 angstrom/sec or less, the resolution may improve. It is presumed that this is because the micro surface portion of the component (A) dissolves, and LER is reduced. Also, there are effects of reducing defects.

In the case of a negative type resist pattern, the dissolution rate of the exposed portion after irradiation with radiation such as KrF excimer laser, extreme ultraviolet, electron beam or X-ray, or after heating at 20 to 500° C., of the amorphous film formed by spin coating with the radiation-sensitive composition of the present embodiment, in a developing solution at 23° C. is preferably 5 angstrom/sec or less, more preferably 0.05 to 5 angstrom/sec, and still more preferably 0.0005 to 5 angstrom/sec. When the dissolution rate is 5 angstrom/sec or less, the above portion is insoluble in a developing solution, and thus the amorphous film can form a resist. When the amorphous film has a dissolution rate of 0.0005 angstrom/sec or more, the resolution may improve. It is presumed that this is because due to the change in the solubility before and after exposure of the component (A), contrast at the interface between the unexposed portion being dissolved in a developing solution and the exposed portion not being dissolved in a developing solution is increased. Also, there are effects of reducing LER and defects.

### (Content Ratio of Each Component in Radiation-Sensitive Composition)

In the radiation-sensitive composition of the present embodiment, the content of the component (A) is preferably 1 to 99% by mass based on the total weight of the solid components (summation of the component (A), the optically active diazonaphthoquinone compound (B), optionally used solid components such as further component (D), hereinafter the same applies to the radiation-sensitive composition), more preferably 5 to 95% by mass, still more preferably 10 to 90% by mass, and particularly preferably 25 to 75% by mass. When the content of the component (A) falls within the above range, the radiation-sensitive composition of the present embodiment can produce a pattern with high sensitivity and low roughness.

In the radiation-sensitive composition of the present embodiment, the content of the optically active diazonaphthoquinone compound (B) is preferably 1 to 99% by mass, more preferably 5 to 95% by mass, still more preferably 10 to 90% by mass, and particularly preferably 25 to 75% by mass, based on the total weight of the solid components. When the content of the optically active diazonaphthoquinone compound (B) falls within the above range, the radiation-sensitive composition of the present embodiment can produce a pattern with high sensitivity and low roughness.

### (Further Component (D))

To the radiation-sensitive composition of the present embodiment, if required, as a component other than the solvent, the component (A) and the optically active diazonaphthoquinone compound (B), one kind or two or more kinds of various additive agents such as the above acid generating agent, acid crosslinking agent, acid diffusion controlling agent, dissolution promoting agent, dissolution controlling agent, sensitizing agent, surfactant, and organic carboxylic acid or oxo acid of phosphorus or derivative thereof can be added. In the radiation-sensitive composition of the present embodiment, the further component (D) may be referred to as an optional component (D).

The content ratio of the component (A), the optically active diazonaphthoquinone compound (B), and the optional component (D) ((A)/(B)/(D)) is preferably 1 to 99% by mass/99 to 1% by mass/0 to 98% by mass based on 100% by mass of the solid content of the radiation-sensitive composition, more preferably 5 to 95% by mass/95 to 5% by mass/0 to 49% by mass, still more preferably 10 to 90% by mass/90 to 10% by mass/0 to 10% by mass, particularly preferably 20 to 80% by mass/80 to 20% by mass/0 to 5% by mass, and most preferably 25 to 75% by mass/75 to 25% by mass/0% by mass.

The content ratio of each component is selected from each range so that the summation thereof is 100% by mass. When the content ratio of each component falls within the above range, the radiation-sensitive composition of the present embodiment is excellent in performance such as sensitivity and resolution, in addition to roughness.

The radiation-sensitive composition of the present embodiment may contain an additional resin other than the polycyclic polyphenolic resin according to the present embodiment. Examples of such an additional resin include a novolac resin, a polyvinyl phenol, a polyacrylic acid, a polyvinyl alcohol, a styrene-maleic anhydride resin, and a polymer containing acrylic acid, vinyl alcohol or vinylphenol as a monomeric unit, and derivatives thereof. The content of additional resins, which is appropriately adjusted according to the kind of the component (A) to be used, is preferably 30 parts by mass or less based on 100 parts by mass of the component (A), more preferably 10 parts by mass or less, still more preferably 5 parts by mass or less, and particularly preferably 0 parts by mass.

### [Method for Producing Amorphous Film]

The method for producing an amorphous film of the present embodiment comprises the step of forming an amorphous film on a substrate using the above radiation-sensitive composition.

### [Resist Pattern Formation Method]

In the present embodiment, the resist pattern can be formed by using the resist composition of the present embodiment or by using the radiation-sensitive composition of the present embodiment.

### [Resist Pattern Formation Method Using Resist Composition]

A resist pattern formation method using the resist composition of the present embodiment includes the steps of: forming a resist film on a substrate using the above resist composition of the present embodiment; exposing at least a portion of the formed resist film; and developing the exposed resist film, thereby forming a resist pattern. The resist pattern according to the present embodiment can also be formed as an upper layer resist in a multilayer process.

### [Resist Pattern Formation Method Using Radiation-Sensitive Composition]

A resist pattern formation method using the radiation-sensitive composition of the present embodiment includes the steps of: forming a resist film on a substrate using the above radiation-sensitive composition; exposing at least a portion of the formed resist film; and developing the exposed resist film, thereby forming a resist pattern. Specifically, the same operation as in the following resist pattern formation method using the resist composition can be performed.

Hereinafter, the conditions for carrying out the resist pattern formation method which can be common between the case of using the resist composition of the present embodiment and the case of using the radiation-sensitive composition of the present embodiment will be described.

Examples of the resist pattern formation method include, but are not particularly limited to, the following method. A resist film is formed by coating a conventionally publicly known substrate with the above resist composition of the present embodiment using a coating means such as spin coating, flow casting coating, and roll coating. Examples of the conventionally publicly known substrate can include, but are not particularly limited to, a substrate for electronic components, and the one having a predetermined wiring pattern formed thereon, or the like. More specific examples thereof include, but are not particularly limited to, a silicon wafer, a substrate made of a metal such as copper, chromium, iron and aluminum, and a glass substrate. Examples of the wiring pattern material include, but are not particularly limited to, copper, aluminum, nickel and gold. Also if required, the substrate may be a substrate having an inorganic and/or organic film provided thereon. Examples of the inorganic film include, but are not particularly limited to, an inorganic antireflection film (inorganic BARC). Examples of the organic film include, but are not particularly limited to, an organic antireflection film (organic BARC) The substrate may be subjected to surface treatment with hexamethylene disilazane or the like.

Next, the coated substrate is heated if required. The heating conditions vary according to the compounding composition of the resist composition, or the like, but are preferably 20 to 250° C., and more preferably 20 to 150° C. By heating, the adhesiveness of a resist to a substrate may be improved, which is preferable. Then, the resist film is exposed to a desired pattern by any radiation selected from the group consisting of visible light, ultraviolet, excimer laser, electron beam, extreme ultraviolet (EUV), X-ray, and ion beam. The exposure conditions or the like are appropriately selected according to the compounding composition of the resist composition, or the like. In the present embodiment, in order to stably form a fine pattern with a high degree of accuracy in exposure, the resist film is preferably heated after radiation irradiation.

Next, by developing the exposed resist film in a developing solution, a predetermined resist pattern is formed. As the above developing solution, it is preferable to select a solvent having a solubility parameter (SP value) close to that of the component (A) to be used. A polar solvent such as a ketone-based solvent, an ester-based solvent, an alcohol-based solvent, an amide-based solvent and an ether-based solvent; and a hydrocarbon-based solvent, or an alkaline aqueous solution can be used. Examples of the solvent and the alkaline aqueous solution include, but are not limited to, those described in International Publication No. WO 2013/024778.

A plurality of above solvents may be mixed, or the solvent may be used by mixing the solvent with a solvent other than those described above or water within the range having performance. Here, from the viewpoint of further enhancing the desired effect of the present embodiment, the water content ratio as the whole developing solution is less than 70% by mass, and is preferably less than 50% by mass, more preferably less than 30% by mass, and still more preferably less than 10% by mass. Particularly preferably, the developing solution is substantially moisture free. That is, the content of the organic solvent in the developing solution is preferably 30% by mass or more and 100% by mass or less based on the total amount of the developing solution, preferably 50% by mass or more and 100% by mass or less, more preferably 70% by mass or more and 100% by mass or less, still more preferably 90% by mass or more and 100% by mass or less, and particularly preferably 95% by mass or more and 100% by mass or less.

Particularly, as the developing solution, a developing solution containing at least one kind of solvent selected from a ketone-based solvent, an ester-based solvent, an alcohol-based solvent, an amide-based solvent, and an ether-based solvent is preferable because it improves resist performance such as resolution and roughness of the resist pattern.

To the developing solution, a surfactant can be added in an appropriate amount, if required. The surfactant is not particularly limited, but an ionic or nonionic, fluorine-based and/or silicon-based surfactant or the like can be used, for example. Examples of the fluorine-based and/or silicon-based surfactant may include, for example, the surfactants described in Japanese Patent Laid-Open Nos. 62-36663, 61-226746, 61-226745, 62-170950, 63-34540, 7-230165, 8-62834, 9-54432, and 9-5988, and U.S. Pat. Nos. 5,405,720, 5,360,692, 5,529,881, 5,296,330, 5,436,098, 5,576,143, 5,294,511, and 5,824,451. The surfactant is preferably a nonionic surfactant. The nonionic surfactant is not particularly limited, but it is still more preferable to use a fluorine-based surfactant or a silicon-based surfactant.

The amount of the surfactant used is usually 0.001 to 5% by mass based on the total amount of the developing solution, preferably 0.005 to 2% by mass, and still more preferably 0.01 to 0.5% by mass.

For the development method, without particular limitations, for example, a method for dipping a substrate in a bath filled with a developing solution for a fixed time (dipping method), a method for raising a developing solution on a substrate surface by the effect of a surface tension and keeping it still for a fixed time, thereby conducting the development (puddle method), a method for spraying a developing solution on a substrate surface (spraying method), and a method for continuously ejecting a developing solution on a substrate rotating at a constant speed while scanning a developing solution ejecting nozzle at a constant rate (dynamic dispense method), or the like may be applied. The time for conducting the pattern development is not particularly limited, but is preferably 10 seconds to 90 seconds.

In addition, after the step of conducting the development, a step of stopping the development by the replacement with another solvent may be carried out.

After the development, it is preferable that a step of rinsing the resist film with a rinsing solution containing an organic solvent is included.

The rinsing solution used in the rinsing step after development is not particularly limited as long as the rinsing solution does not dissolve the resist pattern cured by crosslinking. A solution containing a general organic solvent or water may be used as the rinsing solution. As the foregoing rinsing solution, a rinsing solution containing at least one kind of organic solvent selected from a hydrocarbon-based solvent, a ketone-based solvent, an ester-based solvent, an alcohol-based solvent, an amide-based solvent, and an ether-based solvent is preferably used. More preferably, after development, a step of rinsing the film by using a rinsing solution containing at least one kind of organic solvent selected from the group consisting of a ketone-based solvent, an ester-based solvent, an alcohol-based solvent and an amide-based solvent is conducted. Even more preferably, after development, a step of rinsing the film by using a rinsing solution containing an alcohol-based solvent or an ester-based solvent is conducted. Even more preferably, after the development, a step of rinsing the film by using a rinsing solution containing a monohydric alcohol is conducted. Particularly preferably, after the development, a step of rinsing the film by using a rinsing solution containing a monohydric alcohol having 5 or more carbon atoms is conducted. The time for rinsing the pattern is not particularly limited, but is preferably 10 seconds to 90 seconds.

Herein, examples of the monohydric alcohol used in the rinsing step after development include a linear, branched or cyclic monohydric alcohol, and examples thereof include, but are not particularly limited to, those described in International Publication No. WO 2013/024778. As a particularly preferable monohydric alcohol having 5 or more carbon atoms, 1-hexanol, 2-hexanol, 4-methyl-2-pentanol, 1-pentanol, 3-methyl-1-butanol or the like can be used.

A plurality of these components may be mixed, or the component may be used by mixing the component with an organic solvent other than those described above.

The water content ratio in the rinsing solution is preferably 10% by mass or less, more preferably 5% by mass or less, and particularly preferably 3% by mass or less. By setting the water content ratio to 10% by mass or less, better development characteristics can be obtained.

The rinsing solution may also be used after adding an appropriate amount of a surfactant to the rinsing solution.

In the rinsing step, the wafer after development is rinsed using the above organic solvent-containing rinsing solution. The method of rinsing treatment is not particularly limited. However, for example, a method for continuously ejecting a rinsing solution on a substrate rotating at a constant speed (spin coating method), a method for dipping a substrate in a bath filled with a rinsing solution for a fixed time (dipping method), a method for spraying a rinsing solution on a substrate surface (spraying method), or the like can be applied. Among them, it is preferable to conduct the rinsing treatment by the spin coating method and after the rinsing, spin the substrate at a rotational speed of 2,000 rpm to 4,000 rpm, to remove the rinsing solution from the substrate surface.

After forming the resist pattern, a pattern wiring substrate is obtained by etching. Etching can be performed by a publicly known method such as dry etching using plasma gas, and wet etching with an alkaline solution, a cupric chloride solution, a ferric chloride solution or the like.

After forming the resist pattern, plating can also be conducted. Examples of the above plating method include copper plating, solder plating, nickel plating, and gold plating.

The remaining resist pattern after etching can be peeled by an organic solvent. Examples of the above organic solvent include, but are not particularly limited to, PGMEA (propylene glycol monomethyl ether acetate), PGME (propylene glycol monomethyl ether), and EL (ethyl lactate). Examples of the above stripping method include, but are not particularly limited to, a dipping method and a spraying method. In addition, a wiring substrate having a resist pattern formed thereon may be a multilayer wiring substrate, and may have a small diameter through hole.

In the present embodiment, the wiring substrate obtained can also be formed by a method for forming a resist pattern, then depositing a metal in vacuum, and subsequently dissolving the resist pattern in a solution, that is, a liftoff method.

### [Underlayer Film Forming Material for Lithography]

The composition for underlayer film formation for lithography of the present embodiment comprises a composition for film formation. That is, the composition for underlayer film formation for lithography of the present embodiment contains the polycyclic polyphenolic resin according to the present embodiment as an essential component, and may further contain any of various optional components in consideration of use as an underlayer film forming material for lithography. Specifically, the composition for underlayer film formation for lithography of the present embodiment preferably further contains at least one selected from the group consisting of a solvent, an acid generating agent, and a crosslinking agent.

The content of the polycyclic polyphenolic resin according to the present embodiment in the composition for underlayer film formation for lithography is preferably 1 to 100% by mass, more preferably 10 to 100% by mass, still more preferably 50 to 100% by mass, particularly preferably 100% by mass, from the viewpoint of coatability and quality stability.

When the composition for underlayer film formation for lithography of the present embodiment comprises a solvent, the content of the polycyclic polyphenolic resin according to the present embodiment is not particularly limited, but is preferably 1 to 33 parts by mass based on 100 parts by mass in total including the solvent, more preferably 2 to 25 parts by mass, and still more preferably 3 to 20 parts by mass.

The underlayer film forming composition for lithography of the present embodiment is applicable to a wet process and is excellent in heat resistance and etching resistance. Furthermore, the underlayer film forming composition for lithography of the present embodiment contains the polycyclic polyphenolic resin according to the present embodiment and can therefore form an underlayer film that is prevented from deteriorating upon baking at a high temperature and is also excellent in etching resistance against oxygen plasma etching or the like. Moreover, the underlayer film forming composition for lithography of the present embodiment is also excellent in adhesiveness to a resist layer and can therefore produce an excellent resist pattern. The underlayer film forming composition for lithography of the present embodiment may contain an already known underlayer film forming material for lithography or the like, within the range not deteriorating the desired effect of the present embodiment.

### (Solvent)

A publicly known solvent can be appropriately used as the solvent used in the composition for underlayer film formation for lithography of the present embodiment as long as at least the above component (A) dissolves.

Specific examples of the solvent include, but are not particularly limited to, solvents described in International Publication No. WO 2013/024779. These solvents can be used alone as one kind, or can be used in combination of two or more kinds.

Among the above solvents, cyclohexanone, propylene glycol monomethyl ether, propylene glycol monomethyl ether acetate, ethyl lactate, methyl hydroxyisobutyrate, or anisole is particularly preferable from the viewpoint of safety.

The content of the solvent is not particularly limited and is preferably 100 to 10,000 parts by mass based on 100 parts by mass of the polycyclic polyphenolic resin according to the present embodiment, more preferably 200 to 5,000 parts by mass, and still more preferably 200 to 1,000 parts by mass, from the viewpoint of solubility and film formation.

### (Crosslinking Agent)

The composition for underlayer film formation for lithography of the present embodiment may contain a crosslinking agent, if required, from the viewpoint of, for example, suppressing intermixing. The crosslinking agent that may be used in the present embodiment is not particularly limited, but a crosslinking agent described in, for example, International Publication No. WO 2013/024779 or International Publication No. WO 2018/016614 can be used. In the present embodiment, the crosslinking agent can be used alone or can be used in combination of two or more kinds.

Specific examples of the crosslinking agent that may be used in the present embodiment include, but are not particularly limited to, phenol compounds (excluding the polycyclic polyphenolic resin according to the present embodiment), epoxy compounds, cyanate compounds, amino compounds, benzoxazine compounds, acrylate compounds, melamine compounds, guanamine compounds, glycoluril compounds, urea compounds, isocyanate compounds, and azide compounds. These crosslinking agents can be used alone as one kind, or can be used in combination of two or more kinds. Among these, a benzoxazine compound, an epoxy compound, or a cyanate compound is preferable, and a benzoxazine compound is more preferable from the viewpoint of improvement in etching resistance.

As the phenol compound, a known phenol compound can be used and is not particularly limited, but an aralkyl-based phenolic resin is preferable in terms of heat resistance and solubility.

As the epoxy compound, a known epoxy compound can be used and is not particularly limited, but is preferably an epoxy resin that is in a solid state at normal temperature, such as an epoxy resin obtained from a phenol aralkyl resin or a biphenyl aralkyl resin in terms of heat resistance and solubility.

The above cyanate compound is not particularly limited as long as the compound has two or more cyanate groups in one molecule, and a publicly known compound can be used. In the present embodiment, preferable examples of the cyanate compound include cyanate compounds having a structure where hydroxy groups of a compound having two or more hydroxy groups in one molecule are replaced with cyanate groups. Also, the cyanate compound is preferably a cyanate compound that has an aromatic group, and those having a structure where a cyanate group is directly bonded to an aromatic group can be suitably used. Examples of such a cyanate compound include, but are not particularly limited to, cyanate compounds having a structure where hydroxy groups of bisphenol A, bisphenol F, bisphenol M, bisphenol P, bisphenol E, a phenol novolac resin, a cresol novolac resin, a dicyclopentadiene novolac resin, tetramethylbisphenol F, a bisphenol A novolac resin, brominated bisphenol A, a brominated phenol novolac resin, trifunctional phenol, tetrafunctional phenol, naphthalene-based phenol, biphenyl-based phenol, a phenol aralkyl resin, a biphenyl aralkyl resin, a naphthol aralkyl resin, a dicyclopentadiene aralkyl resin, alicyclic phenol, phosphorus-containing phenol, or the like are replaced with cyanate groups. Also, the above cyanate compound may be in any form of a monomer, an oligomer and a resin.

As the amino compound, a known amino compound can be used and is not particularly limited, but 4,4′-diaminodiphenylmethane, 4,4′-diaminodiphenylpropane, or 4,4′-diaminodiphenyl ether is preferable from the viewpoint of heat resistance and availability of raw materials.

As the benzoxazine compound, a known benzoxazine compound can be used and is not particularly limited, but P-d-type benzoxazine obtained from difunctional diamines and monofunctional phenols is preferable from the viewpoint of heat resistance.

As the melamine compound, a known melamine compound can be used and is not particularly limited, but a compound in which 1 to 6 methylol groups of hexamethylol melamine, hexamethoxymethyl melamine, or hexamethylol melamine are methoxymethylated or a mixture thereof is preferable from the viewpoint of availability of raw materials.

As the guanamine compound, a known guanamine compound can be used and is not particularly limited, but tetramethylolguanamine, tetramethoxymethylguanamine, a compound in which 1 to 4 methylol groups of tetramethylolguanamine are methoxymethylated, or a mixture thereof is preferable from the viewpoint of heat resistance.

As the glycol uryl compound, a known glycol uryl compound can be used and is not particularly limited, but tetramethylolglycol uryl and tetramethoxyglycol uryl are preferable from the viewpoint of heat resistance and etching resistance.

As the urea compound, a known urea compound can be used and is not particularly limited, but tetramethylurea and tetramethoxymethylurea are preferable from the viewpoint of heat resistance.

In the present embodiment, a crosslinking agent having at least one allyl group may be used from the viewpoint of improvement in crosslinkability. Among them, an allylphenol such as 2,2-bis(3-allyl-4-hydroxyphenyl)propane, 1,1,1,3,3,3-hexafluoro-2,2-bis(3-allyl-4-hydroxyphenyl)propane, bis(3-allyl-4-hydroxyphenyl)sulfone, bis(3-allyl-4-hydroxyphenyl) sulfide, or bis(3-allyl-4-hydroxyphenyl) ether is preferable.

In the composition for underlayer film formation for lithography of the present embodiment, the content of the crosslinking agent is not particularly limited, but is preferably 5 to 50 parts by mass, and more preferably 10 to 40 parts by mass based on 100 parts by mass of the polycyclic polyphenolic resin according to the present embodiment. By setting the content of the crosslinking agent to the above preferable range, occurrence of a mixing event with a resist layer tends to be prevented. Also, an antireflection effect is enhanced, and film formability after crosslinking tends to be enhanced.

### (Crosslinking Promoting Agent)

In the composition for underlayer film formation for lithography of the present embodiment, if required, a crosslinking promoting agent for accelerating crosslinking and curing reaction can be used.

The above crosslinking promoting agent is not particularly limited as long as it accelerates crosslinking or curing reaction, and examples thereof include amines, imidazoles, organic phosphines, and Lewis acids. These crosslinking promoting agents can be used alone as one kind or can be used in combination of two or more kinds. Among these, an imidazole or an organic phosphine is preferable, and an imidazole is more preferable from the viewpoint of decrease in crosslinking temperature.

As the crosslinking promoting agent, a known crosslinking promoting agent can be used, and examples thereof include those described in International Publication No. WO 2018/016614. From the viewpoint of heat resistance and acceleration of curing, 2-methylimidazole, 2-phenylimidazole, and 2-ethyl-4-methylimidazole are particularly preferable.

The content of the crosslinking promoting agent is usually preferably 0.1 to 10 parts by mass based on 100 parts by mass of the total mass of the composition, and is more preferably 0.1 to 5 parts by mass, and still more preferably 0.1 to 3 parts by mass, from the viewpoint of easy control and cost efficiency.

### (Radical Polymerization Initiator)

The composition for underlayer film formation for lithography of the present embodiment can contain, if required, a radical polymerization initiator. The radical polymerization initiator may be a photopolymerization initiator that initiates radical polymerization by light, or may be a thermal polymerization initiator that initiates radical polymerization by heat. The radical polymerization initiator can be at least one selected from the group consisting of a ketone-based photopolymerization initiator, an organic peroxide-based polymerization initiator and an azo-based polymerization initiator.

Such a radical polymerization initiator is not particularly limited, and a radical polymerization initiator conventionally used can be appropriately adopted. For example, examples thereof include those described in International Publication No. WO 2018/016614. Among these, dicumyl peroxide, 2,5-dimethyl-2,5-bis(t-butylperoxy)hexane, and t-butylcumyl peroxide are particularly preferable from the viewpoint of availability of raw materials and storage stability.

As the radical polymerization initiator used for the present embodiment, one kind thereof may be used alone, or two or more kinds may be used in combination. Alternatively, the radical polymerization initiator according to the present embodiment may be used in further combination with an additional publicly known polymerization initiator.

### (Acid Generating Agent)

The composition for underlayer film formation for lithography of the present embodiment may contain an acid generating agent, if required, from the viewpoint of, for example, further accelerating crosslinking reaction by heat. An acid generating agent that generates an acid by thermal decomposition, an acid generating agent that generates an acid by light irradiation, and the like are known, any of which can be used.

The acid generating agent is not particularly limited, and, for example, an acid generating agent described in International Publication No. WO2013/024779 can be used. In the present embodiment, the acid generating agent can be used alone or can be used in combination of two or more kinds.

In the composition for underlayer film formation for lithography of the present embodiment, the content of the acid generating agent is not particularly limited, but is preferably 0.1 to 50 parts by mass, and more preferably 0.5 to 40 parts by mass based on 100 parts by mass of the polycyclic polyphenolic resin according to the present embodiment. By setting the content of the acid generating agent to the above preferable range, crosslinking reaction tends to be enhanced by an increased amount of an acid generated. Also, occurrence of a mixing event with a resist layer tends to be prevented.

### (Basic Compound)

The composition for underlayer film formation for lithography of the present embodiment may further contain a basic compound from the viewpoint of, for example, improving storage stability.

The basic compound plays a role as a quencher against acids in order to prevent crosslinking reaction from proceeding due to a trace amount of an acid generated by the acid generating agent. Examples of such a basic compound include, but are not particularly limited to, primary, secondary or tertiary aliphatic amines, amine blends, aromatic amines, heterocyclic amines, nitrogen-containing compounds having a carboxy group, nitrogen-containing compounds having a sulfonyl group, nitrogen-containing compounds having a hydroxy group, nitrogen-containing compounds having a hydroxyphenyl group, alcoholic nitrogen-containing compounds, amide derivatives, and imide derivatives.

The basic compound used in the present embodiment is not particularly limited, and, for example, a basic compound described in International Publication No. WO2013/024779 can be used. In the present embodiment, the basic compound can be used alone or can be used in combination of two or more kinds.

In the composition for underlayer film formation for lithography of the present embodiment, the content of the basic compound is not particularly limited, but is preferably 0.001 to 2 parts by mass, and more preferably 0.01 to 1 parts by mass based on 100 parts by mass of the polycyclic polyphenolic resin according to the present embodiment. By setting the content of the basic compound to the above preferable range, storage stability tends to be enhanced without excessively deteriorating crosslinking reaction.

### (Further Additive Agent)

The composition for underlayer film formation for lithography of the present embodiment may also contain an additional resin and/or compound for the purpose of conferring thermosetting properties or controlling absorbance. Examples of such an additional resin and/or compound include, but are not particularly limited to, a naphthol resin, a xylene resin, a naphthol-modified resin, a phenol-modified resin of a naphthalene resin; a polyhydroxystyrene, a dicyclopentadiene resin, a resin containing (meth)acrylate, dimethacrylate, trimethacrylate, tetramethacrylate, a naphthalene ring such as vinylnaphthalene or polyacenaphthylene, a biphenyl ring such as phenanthrenequinone or fluorene, or a heterocyclic ring having a heteroatom such as thiophene or indene, and a resin not containing an aromatic ring; and a resin or compound containing an alicyclic structure, such as a rosin-based resin, a cyclodextrin, an adamantine(poly)ol, a tricyclodecane(poly)ol, and a derivative thereof. The composition for underlayer film formation for lithography of the present embodiment may further contain a publicly known additive agent. Examples of the above publicly known additive agent include, but are not limited to, ultraviolet absorbers, surfactants, colorants, and nonionic surfactants.

### [Underlayer Film for Lithography Formation Method]

The method for forming an underlayer film for lithography according to the present embodiment includes the step of forming an underlayer film on a substrate using the composition for underlayer film formation for lithography of the present embodiment.

### [Resist Pattern Formation Method Using Composition for Underlayer Film Formation for Lithography]

A resist pattern formation method using the composition for underlayer film formation for lithography of the present embodiment has the steps of: forming an underlayer film on a substrate using the composition for underlayer film formation for lithography of the present embodiment (step (A-1)); forming at least one photoresist layer on the underlayer film (step (A-2)); and irradiating a predetermined region of the photoresist layer with radiation for development, thereby forming a resist pattern (step (A-3)).

### [Circuit Pattern Formation Method Using Composition for Underlayer Film Formation for Lithography]

A circuit pattern formation method using the composition for underlayer film formation for lithography of the present embodiment has the steps of: forming an underlayer film on a substrate using the composition for underlayer film formation for lithography of the present embodiment (step (B-1)); forming an intermediate layer film on the underlayer film using a resist intermediate layer film material containing a silicon atom (step (B-2)); forming at least one photoresist layer on the intermediate layer film (step (B-3)); after the step (B-3), irradiating a predetermined region of the photoresist layer with radiation for development, thereby forming a resist pattern (step (B-4)); after the step (B-4), etching the intermediate layer film with the resist pattern as a mask, thereby forming an intermediate layer film pattern (step (B-5)); etching the underlayer film with the obtained intermediate layer film pattern as an etching mask, thereby forming an underlayer film pattern (step (B-6)); and etching the substrate with the obtained underlayer film pattern as an etching mask, thereby forming a pattern on the substrate (step (B-7)).

The underlayer film for lithography of the present embodiment is not particularly limited by its formation method as long as it is formed from the composition for underlayer film formation for lithography of the present embodiment. A publicly known approach can be applied thereto. The underlayer film can be formed by, for example, applying the composition for underlayer film formation for lithography of the present embodiment onto a substrate by a publicly known coating method or printing method such as spin coating or screen printing, and then removing an organic solvent by volatilization or the like.

It is preferable to perform baking in the formation of the underlayer film, for preventing occurrence of a mixing event with an upper layer resist while accelerating crosslinking reaction. In this case, the baking temperature is not particularly limited and is preferably in the range of 80 to 450° C., and more preferably 200 to 400° C. The baking time is not particularly limited and is preferably in the range of 10 to 300 seconds. The thickness of the underlayer film can be appropriately selected according to required performance and is not particularly limited, but is usually preferably about 30 to 20,000 nm, and more preferably 50 to 15,000 nm.

After preparing the underlayer film, it is preferable to prepare a silicon-containing resist layer or a usual single-layer resist made of hydrocarbon thereon in the case of a two-layer process, and to prepare a silicon-containing intermediate layer thereon and further a silicon-free single-layer resist layer thereon in the case of a three-layer process. In this case, a publicly known photoresist material can be used for forming this resist layer.

After preparing the underlayer film on the substrate, a silicon-containing resist layer or a usual single-layer resist made of hydrocarbon thereon can be prepared on the underlayer film in the case of a two-layer process. In the case of a three-layer process, a silicon-containing intermediate layer can be prepared on the underlayer film, and a silicon-free single-layer resist layer can be further prepared on the silicon-containing intermediate layer. In these cases, a publicly known photoresist material can be appropriately selected and used for forming the resist layer, without particular limitations.

For the silicon-containing resist material for a two-layer process, a silicon atom-containing polymer such as a polysilsesquioxane derivative or a vinylsilane derivative is used as a base polymer, and a positive type photoresist material further containing an organic solvent, an acid generating agent, and if required, a basic compound or the like is preferably used, from the viewpoint of oxygen gas etching resistance. Here, a publicly known polymer that is used in this kind of resist material can be used as the silicon atom-containing polymer.

A polysilsesquioxane-based intermediate layer is preferably used as the silicon-containing intermediate layer for a three-layer process. By imparting effects as an antireflection film to the intermediate layer, there is a tendency that reflection can be effectively suppressed. For example, use of a material containing a large amount of an aromatic group and having high substrate etching resistance as the underlayer film in a process for exposure at 193 nm tends to increase a k value and enhance substrate reflection. However, the intermediate layer suppresses the reflection so that the substrate reflection can be 0.5% or less. The intermediate layer having such an antireflection effect is not limited, and polysilsesquioxane that crosslinks by an acid or heat in which a light absorbing group having a phenyl group or a silicon-silicon bond is introduced is preferably used for exposure at 193 nm.

Alternatively, an intermediate layer formed by chemical vapour deposition (CVD) may be used. The intermediate layer highly effective as an antireflection film prepared by CVD is not limited, and, for example, a SiON film is known. In general, the formation of an intermediate layer by a wet process such as spin coating or screen printing is more convenient and more advantageous in cost than CVD. The upper layer resist for a three-layer process may be positive type or negative type, and the same as a single-layer resist usually used can be used.

The underlayer film according to the present embodiment can also be used as an antireflection film for usual single-layer resists or an underlying material for suppression of pattern collapse. The underlayer film of the present embodiment is excellent in etching resistance for an underlying process and can be expected to also function as a hard mask for an underlying process.

In the case of forming a resist layer from the above photoresist material, a wet process such as spin coating or screen printing is preferably used, as in the case of forming the above underlayer film. After coating with the resist material by spin coating or the like, prebaking is usually performed. This prebaking is preferably performed at 80 to 180° C. in the range of 10 to 300 seconds. Then, exposure, post-exposure baking (PEB), and development can be performed according to a conventional method to obtain a resist pattern. The thickness of the resist film is not particularly limited, and in general, is preferably 30 to 500 nm and more preferably 50 to 400 nm.

The exposure light can be appropriately selected and used according to the photoresist material to be used. General examples thereof can include a high energy ray having a wavelength of 300 nm or less, specifically, excimer laser of 248 nm, 193 nm, or 157 nm, soft x-ray of 3 to 20 nm, electron beam, and X-ray.

In a resist pattern formed by the above method, pattern collapse is suppressed by the underlayer film according to the present embodiment. Therefore, use of the underlayer film according to the present embodiment can produce a finer pattern and can reduce an exposure amount necessary for obtaining the resist pattern.

Next, etching is performed with the obtained resist pattern as a mask. Gas etching is preferably used as the etching of the underlayer film in a two-layer process. The gas etching is suitably etching using oxygen gas. In addition to oxygen gas, an inert gas such as He or Ar, or CO, CO₂, NH₃, SO₂, N₂, NO₂, or H₂ gas may be added. Alternatively, the gas etching may be performed with CO, CO₂, NH₃, N₂, NO₂, or H₂ gas without the use of oxygen gas. Particularly, the latter gas is preferably used for side wall protection in order to prevent the undercut of pattern side walls.

On the other hand, gas etching is also preferably used as the etching of the intermediate layer in a three-layer process. The same gas etching as described in the above two-layer process is applicable. In particular, it is preferable to process the intermediate layer in a three-layer process by using chlorofluorocarbon-based gas and using the resist pattern as a mask. Then, as mentioned above, for example, the underlayer film can be processed by oxygen gas etching with the intermediate layer pattern as a mask.

Herein, in the case of forming an inorganic hard mask intermediate layer film as the intermediate layer, a silicon oxide film, a silicon nitride film, or a silicon oxynitride film (SiON film) is formed by CVD, atomic layer deposition (ALD), or the like. A method for forming the nitride film is not limited, and, for example, a method described in Japanese Patent Laid-Open No. 2002-334869 (Patent Literature 4) or International Publication No. WO2004/066377 (Patent Literature 5) can be used. Although a photoresist film can be formed directly on such an intermediate layer film, an organic antireflection film (BARC) may be formed on the intermediate layer film by spin coating and a photoresist film may be formed thereon.

A polysilsesquioxane-based intermediate layer is preferably used as the intermediate layer. By imparting effects as an antireflection film to the resist intermediate layer film, there is a tendency that reflection can be effectively suppressed. A specific material for the polysilsesquioxane-based intermediate layer is not limited, and, for example, a material described in Japanese Patent Laid-Open No. 2007-226170 (Patent Literature 6) or Japanese Patent Laid-Open No. 2007-226204 (Patent Literature 7) can be used.

The subsequent etching of the substrate can also be performed by a conventional method. For example, the substrate made of SiO₂ or SiN can be etched mainly using chlorofluorocarbon-based gas, and the substrate made of p-Si, Al, or W can be etched mainly using chlorine- or bromine-based gas. In the case of etching the substrate with chlorofluorocarbon-based gas, the silicon-containing resist of the two-layer resist process or the silicon-containing intermediate layer of the three-layer process is stripped at the same time with substrate processing. On the other hand, in the case of etching the substrate with chlorine- or bromine-based gas, the silicon-containing resist layer or the silicon-containing intermediate layer is separately stripped and in general, stripped by dry etching using chlorofluorocarbon-based gas after substrate processing.

A feature of the underlayer film according to the present embodiment is that it is excellent in etching resistance of these substrates. The substrate can be appropriately selected from publicly known ones and used and is not particularly limited. Examples thereof include Si, α-Si, p-Si, SiO₂, SiN, SiON, W, TiN, and Al. The substrate may be a laminate having a film to be processed (substrate to be processed) on a base material (support). Examples of such a film to be processed include various low-k films such as Si, SiO₂, SiON, SiN, p-Si, α-Si, W, W—Si, Al, Cu, and Al—Si, and stopper films thereof. A material different from that for the base material (support) is usually used. The thickness of the substrate to be processed or the film to be processed is not particularly limited, and usually, it is preferably approximately 50 to 1,000,000 nm and more preferably 75 to 500,000 nm.

### [Resist Permanent Film]

The composition for film formation of the present embodiment can also be used to prepare a resist permanent film. The resist permanent film prepared by coating with the composition for film formation of the present embodiment on a base material or the like is suitable as a permanent film that also remains in a final product, if required, after formation of a resist pattern. Specific examples of the permanent film include, but are not particularly limited to, in relation to semiconductor devices, solder resists, package materials, underfill materials, package adhesive layers for circuit elements and the like, and adhesive layers between integrated circuit elements and circuit substrates, and in relation to thin displays, thin film transistor protecting films, liquid crystal color filter protecting films, black matrixes, and spacers. Particularly, the permanent film made of the composition for film formation of the present embodiment is excellent in heat resistance and humidity resistance and furthermore, also has the excellent advantage that contamination by sublimable components is reduced. Particularly, for a display material, a material that achieves all of high sensitivity, high heat resistance, and hygroscopic reliability with reduced deterioration in image quality due to significant contamination can be obtained.

In the case of using the composition for film formation of the present embodiment for resist permanent films, a curing agent as well as, if required, various additive agents such as an additional resin, a surfactant, a dye, a filler, a crosslinking agent, and a dissolution promoting agent can be further added and dissolved in an organic solvent to prepare a composition for resist permanent films.

The composition for film formation according to the present embodiment is used for resist permanent films, the composition for a resist permanent film can be prepared by adding each of the above components and mixing them using a stirrer or the like. When the composition for film formation of the present embodiment contains a filler or a pigment, the composition for a resist permanent film can be prepared by dispersion or mixing using a dispersion apparatus such as a dissolver, a homogenizer, and a three-roll mill.

### [Composition for Optical Component Formation]

The composition for film formation of the present embodiment can also be used for forming optical components. That is, the composition for optical component formation of the present embodiment contains the composition for film formation of the present embodiment. In other words, the composition for optical component formation of the present embodiment contains the polycyclic polyphenolic resin according to the present embodiment as an essential component. Herein, the “optical component” refers to a component in the form of a film or a sheet as well as a plastic lens (a prism lens, a lenticular lens, a microlens, a Fresnel lens, a viewing angle control lens, a contrast improving lens, etc.), a phase difference film, a film for electromagnetic wave shielding, a prism, an optical fiber, a solder resist for flexible printed wiring, a plating resist, an interlayer insulating film for multilayer printed circuit boards, or a photosensitive optical waveguide. The polycyclic polyphenolic resin according to the present embodiment are useful for forming these optical components. The composition for forming an optical component of the present embodiment may further contain various optional components in consideration of being used as an optical component forming material. Specifically, the composition for optical component formation of the present embodiment preferably further contains at least one selected from the group consisting of a solvent, an acid generating agent, and a crosslinking agent. Specific examples that can be used as the solvent, the acid generating agent, and the crosslinking agent may be the same as those of the components that may be contained in the composition for underlayer film formation for lithography according to the present embodiment described above, and the blending ratio thereof may be appropriately set in consideration of specific application.

### EXAMPLES

Hereinafter, the present embodiment will be described in more detail based on Examples, and Comparative Examples, but the present embodiment is not limited thereto.

The analysis and evaluation method of the polycyclic polyphenolic resin according to the present embodiment is as follows.

¹H-NMR measurement was performed under the following conditions by using “Advance 60011 spectrometer” manufactured by Bruker Corp.

Frequency: 400 MHz

Solvent: d6-DMSO

Internal standard: TMS

Measurement temperature: 23° C.

### <Molecular Weight>

The molecular weight of the polycyclic polyphenolic resin was measured by LC-MS analysis using Acquity UPLC/MALDI-Synapt HDMS manufactured by Waters Corporation.

### <Polystyrene Equivalent Molecular Weight>

The weight-average molecular weight (Mw) and number-average molecular weight (Mn) were determined by gel permeation chromatography (GPC) analysis, and the dispersibility (Mw/Mn) in terms of polystyrene was determined.

Apparatus: Shodex GPC-101 model (manufactured by Showa Denko K.K.)

Column: KF-80M x 3

Eluent: 1 mL/min THF

Temperature: 40° C.

### <Measurement of Thermal Decomposition Temperature>

EXSTAR 6000 TG/DTA apparatus manufactured by SII NanoTechnology Inc. was used. About 5 mg of a sample was placed in an unsealed container made of aluminum, and the temperature was raised to 700° C. at a temperature increase rate of 10° C./min in a nitrogen gas stream (30 mL/min). The temperature at which a heat loss of 5% by weight was observed was defined as the thermal decomposition temperature (Tg), and the heat resistance was evaluated according to the following criteria.

Evaluation A: The thermal decomposition temperature was 450° C. or higher

Evaluation B: The thermal decomposition temperature was 300° C. or higher

Evaluation C: The thermal decomposition temperature was lower than 300° C.

### <Measurement of Film Thickness>

The film thickness of the resin film made using polycyclic polyphenolic resin was measured with an interference thickness meter “OPTM-A1” (manufactured by Otsuka Electronics Co., Ltd.).

### (Synthesis Example 1) Synthesis of R-DHN

To a container (internal capacity: 500 mL) equipped with a stirrer, a condenser tube, and a burette, 16.8 g (105 mmol) of 2,6-dihydroxynaphthalene (reagent manufactured by Kanto Chemical Co., Inc.) and 10.1 g (20 mmol) of monobutylcopper phthalate were added, and 30 mL of 1-butanol was added as a solvent. The reaction solution was stirred at 110° C. for 6 hours and reacted. After cooling, the precipitate was filtered and the resulting crude was dissolved in 100 mL of ethyl acetate. Next, 5 mL of hydrochloric acid was added, and the mixture was stirred at room temperature, and neutralized with sodium hydrogen carbonate. The ethyl acetate solution was concentrated and 200 mL of methanol was added to precipitate the reaction product. After cooling to room temperature, the precipitates were separated by filtration. The obtained solid matter was dried to obtain 27.3 g of the objective resin (R-DHN) having a structure represented by the following formula.

The polystyrene equivalent molecular weight of the obtained resin was measured by the method described above, and as a result, the obtained resin had Mn: 3578, Mw: 4793, and Mw/Mn: 1.34.

The following peaks were found by NMR measurement performed on the obtained resin under the above measurement conditions, and the resin was confirmed to have a chemical structure of the following formula.

δ (ppm) 9.7-9.8 (2H, O—H), 7.0-7.9 (4H, Ph-H)

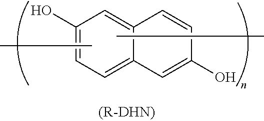

### (Synthesis Example 1-2) Synthesis of R-2,7DHN

To a container (internal capacity: 500 mL) equipped with a stirrer, a condenser tube, and a burette, 16.8 g (105 mmol) of 2,7-dihydroxynaphthalene (reagent manufactured by Kanto Chemical Co., Inc.) and 15.2 g (30 mmol) of monobutylcopper phthalate were added, and 40 mL of 1-butanol was added as a solvent. The reaction solution was stirred at 110° C. for 6 hours and reacted. After cooling, the precipitate was filtered and the resulting crude was dissolved in 100 mL of ethyl acetate. Next, 5 mL of hydrochloric acid was added, and the mixture was stirred at room temperature, and neutralized with sodium hydrogen carbonate. The ethyl acetate solution was concentrated and 200 mL of methanol was added to precipitate the reaction product. After cooling to room temperature, the precipitates were separated by filtration. The obtained solid matter was dried to obtain 24.7 g of the objective resin (R-2,7DHN) having a structure represented by the following formula.

The polystyrene equivalent molecular weight of the obtained resin was measured by the method described above, and as a result, the obtained resin had Mn: 2832, Mw: 3476, and Mw/Mn: 1.23.

The following peaks were found by NMR measurement performed on the obtained resin under the above measurement conditions, and the resin was confirmed to have a chemical structure of the following formula.

δ (ppm) 9.7-9.8 (2H, O—H), 7.0-7.9 (4H, Ph-H)

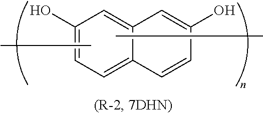

### (Synthesis Example 1-3) Synthesis of R-2,3DHN

In the same manner as in Synthesis Example 1-2 except that 2,7-dihydroxynaphthalene (reagent manufactured by Kanto Chemical Co., Inc.) in Synthesis Example 1-2 was changed to 2,3-dihydroxynaphthalene (reagent manufactured by Kanto Chemical Co., Inc.), 29.2 g of the objective resin (R-2,3DHN) having a structure represented by the following formula was obtained.

The polystyrene equivalent molecular weight of the obtained resin was measured by the method described above, and as a result, the obtained resin had Mn: 3124, Mw: 4433, and Mw/Mn: 1.42.

The following peaks were found by NMR measurement performed on the obtained resin under the above measurement conditions, and the resin was confirmed to have a chemical structure of the following formula.

δ (ppm) 9.5-9.6 (2H, O—H), 7.0-7.9 (4H, Ph-H)

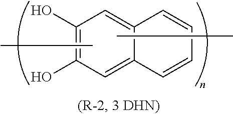

### (Synthesis Example 1-4) Synthesis of R-1,5DHN

In the same manner as in Synthesis Example 1-2 except that 2,7-dihydroxynaphthalene (reagent manufactured by Kanto Chemical Co., Inc.) in Synthesis Example 1-2 was changed to 1,5-dihydroxynaphthalene (reagent manufactured by Kanto Chemical Co., Inc.), 25.8 g of the objective resin (R-1,5DHN) having a structure represented by the following formula was obtained.

The polystyrene equivalent molecular weight of the obtained resin was measured by the method described above, and as a result, the obtained resin had Mn: 2988, Mw: 3773, and Mw/Mn: 1.26.

The following peaks were found by NMR measurement performed on the obtained resin under the above measurement conditions, and the resin was confirmed to have a chemical structure of the following formula.

δ (ppm) 9.8-9.9 (2H, O—H), 7.1-8.0 (4H, Ph-H)

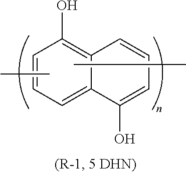

### (Synthesis Example 1-5) Synthesis of R-1,6DHN

In the same manner as in Synthesis Example 1-2 except that 2,7-dihydroxynaphthalene (reagent manufactured by Kanto Chemical Co., Inc.) in Synthesis Example 1-2 was changed to 1,6-dihydroxynaphthalene (reagent manufactured by Kanto Chemical Co., Inc.), 23.2 g of the objective resin (R-1,6DHN) having a structure represented by the following formula was obtained.

The polystyrene equivalent molecular weight of the obtained resin was measured by the method described above, and as a result, the obtained resin had Mn: 2687, Mw: 3693, and Mw/Mn: 1.37.

The following peaks were found by NMR measurement performed on the obtained resin under the above measurement conditions, and the resin was confirmed to have a chemical structure of the following formula.

δ (ppm) 9.8-9.9 (2H, O—H), 6.8-7.9 (4H, Ph-H)

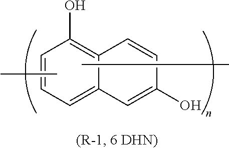

### (Synthesis Example 1-6) Synthesis of R-FLBNDHN

To a container (internal capacity: 500 mL) equipped with a stirrer, a condenser tube, and a burette, 47.3 g (105 mmol) of 6,6′-(9H-fluorene-9,9-diyl)bis(2-naphthol) (manufactured by Kanto Chemical Co., Inc.), 16.8 g (105 mmol) of 2,6-dihydroxynaphthalene (manufactured by Kanto Chemical Co., Inc.) and 10.1 g (20 mmol) of monobutylcopper phthalate were added, and 120 mL of 4-butyrolactone was added as a solvent. The reaction solution was stirred at 120° C. for 8 hours and reacted. After cooling, the precipitate was filtered and the resulting crude was dissolved in 150 mL of ethyl acetate. Next, 5 mL of hydrochloric acid was added, and the mixture was stirred at room temperature, and neutralized with sodium hydrogen carbonate. The ethyl acetate solution was concentrated and 300 mL of distilled water was added to precipitate the reaction product. After cooling to room temperature, the precipitates were separated by filtration. The obtained solid matter was dried to obtain 51.6 g of the objective resin (R-FLBNDHN) having a structure represented by the following formula.

The polystyrene equivalent molecular weight of the obtained resin was measured by the method described above, and as a result, the obtained resin had Mn: 4128, Mw: 5493, and Mw/Mn: 1.33.

The following peaks were found by NMR measurement performed on the obtained resin under the above measurement conditions, and the resin was confirmed to have a chemical structure of the following formula.

δ (ppm) 9.7-9.9 (2H, O—H), 9.1-9.3 (2H, O—H), 7.1-8.0 (22H, Ph-H)

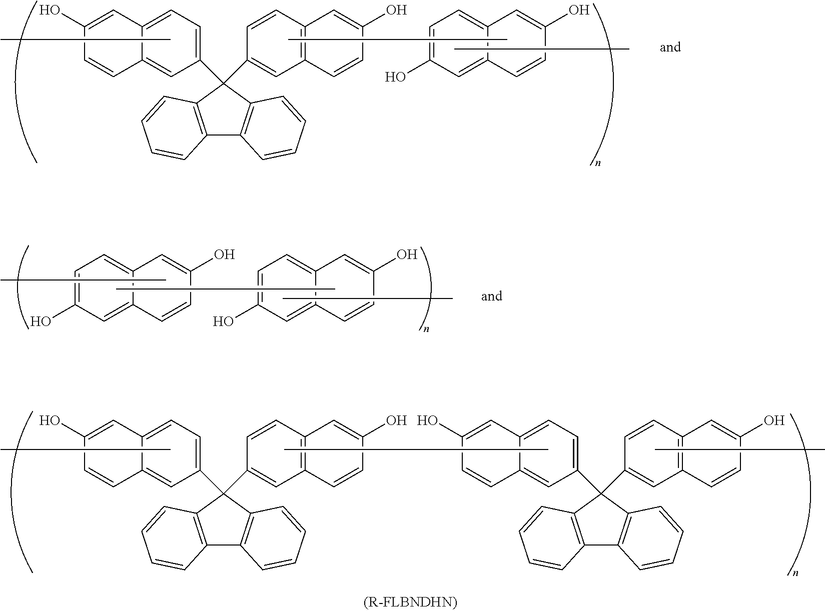

That is, R-FLBNDHN was a mixture containing a homopolymer of 6,6′-(9H-fluorene-9,9-diyl)bis(2-naphthol), a homopolymer of 2,6-dihydroxynaphthalene, and a copolymer of 6,6′-(9H-fluorene-9,9-diyl)bis(2-naphthol) and 2,6-dihydroxynaphthalene.

### (Synthesis Example 2) Synthesis of R—BiF

To a container (internal capacity: 500 mL) equipped with a stirrer, a condenser tube, and a burette, 19.2 g (105 mmol) of 4,4-biphenol (reagent manufactured by Kanto Chemical Co., Inc.) and 10.1 g (20 mmol) of monobutylcopper phthalate were added, and 80 mL of 4-butyrolactone was added as a solvent. The reaction solution was stirred at 120° C. for 6 hours and reacted. After cooling, the precipitate was filtered and the resulting crude was dissolved in 100 mL of ethyl acetate. Next, 5 mL of hydrochloric acid was added, and the mixture was stirred at room temperature, and neutralized with sodium hydrogen carbonate. The ethyl acetate solution was concentrated and 200 mL of methanol was added to precipitate the reaction product. After cooling to room temperature, the precipitates were separated by filtration. The obtained solid matter was dried to obtain 21.2 g of the objective resin (R—BiF) having a structure represented by the following formula.

The polystyrene equivalent molecular weight of the obtained resin was measured by the method described above, and as a result, the obtained resin had Mn: 4128, Mw: 5493, and Mw/Mn: 1.33.

The following peaks were found by NMR measurement performed on the obtained resin under the above measurement conditions, and the resin was confirmed to have a chemical structure of the following formula.

δ (ppm) 9.1-9.3 (2H, O—H), 7.1-8.2 (6H, Ph-H)

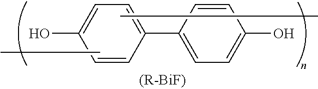

### (Synthesis Example 3) Synthesis of BisN-1

To a container (internal capacity: 500 mL) equipped with a stirrer, a condenser tube, and a burette, 20.0 g (200 mmol) of 1,4-dihydroxybenzene (reagent manufactured by Kanto Chemical Co., Inc.), 18.2 g (100 mmol) of 4-biphenylaldehyde (manufactured by Mitsubishi Gas Chemical Company), and 100 mL of 1,4-dioxane were added, and 5 mL of 95% sulfuric acid was added. The reaction solution was stirred at 100° C. for 6 hours and reacted. Next, the reaction liquid was neutralized with 24% aqueous sodium hydroxide solution. The reaction product was precipitated by the addition of 50 g of pure water. After cooling to room temperature, the precipitates were separated by filtration. The solid matter obtained was dried and then separated and purified by column chromatography to obtain 20.6 g of the objective compound (BisN-1) represented by the following formula.

The following peaks were found by 400 MHz-1H-NMR, and the compound was confirmed to have a chemical structure of the following formula.

¹H-NMR: (d-DMSO, internal standard TMS)

δ (ppm) 9.4 (2H, O—H), 7.2-8.1 (13H, Ph-H), 6.5 (1H, C—H)

LC-MS analysis confirmed that the molecular weight was 366.1 corresponding to the following chemical structure.

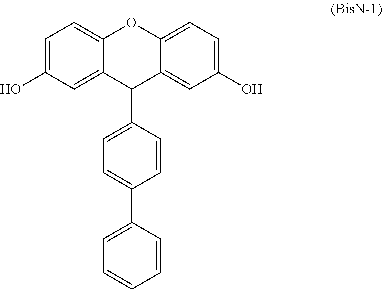 [SMILES: Oc1ccc2c(c1)C(c1ccc(-c3ccccc3)cc1)c1cc(O)ccc1O2]

### (Synthesis Example 3-1) Synthesis of RBisN-1

To a container (internal capacity: 500 mL) equipped with a stirrer, a condenser tube, and a burette, 38.0 g (105 mmol) of BisN-1 and 10.1 g (20 mmol) of monobutylcopper phthalate were added, and 100 mL of 1-butanol was added as a solvent. The reaction solution was stirred at 100° C. for 6 hours and reacted. After cooling, the precipitate was filtered and the resulting crude was dissolved in 100 mL of ethyl acetate. Next, 5 mL of hydrochloric acid was added, and the mixture was stirred at room temperature, and neutralized with sodium hydrogen carbonate. The ethyl acetate solution was concentrated and 200 mL of methanol was added to precipitate the reaction product. After cooling to room temperature, the precipitates were separated by filtration. The obtained solid matter was dried to obtain 28.2 g of the objective resin (RBisN-1) having a structure represented by the following formula.

The polystyrene equivalent molecular weight of the obtained resin was measured by the method described above, and as a result, the obtained resin had Mn: 3762, Mw: 4905, and Mw/Mn: 1.30.

The following peaks were found by NMR measurement performed on the obtained resin under the above measurement conditions, and the resin was confirmed to have a chemical structure of the following formula.

δ (ppm) 9.3-9.6 (2H, O—H), 7.2-8.7 (17H, Ph-H), 6.8 (1H, C—H)

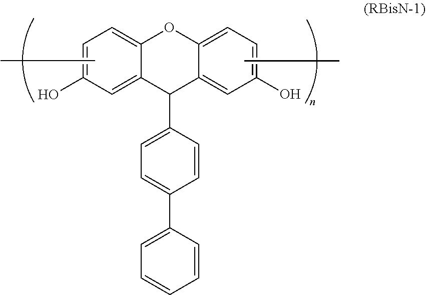

### (Synthesis Example 4) Synthesis of BisN-2

To a container (internal capacity: 500 mL) equipped with a stirrer, a condenser tube, and a burette, 32.0 g (20 mmol) of 2,6-naphthalenediol (reagent manufactured by Sigma-Aldrich), 18.2 g (100 mmol) of 4-biphenylaldehyde (manufactured by Mitsubishi Gas Chemical Co., Inc.), and 200 mL of 1,4-dioxane were added, and 10 mL of 95% sulfuric acid was added. The reaction solution was stirred at 100° C. for 6 hours and reacted. Next, the reaction liquid was neutralized with 24% aqueous sodium hydroxide solution. The reaction product was precipitated by the addition of 100 g of pure water. After cooling to room temperature, the precipitates were separated by filtration. The solid matter obtained was dried and then separated and purified by column chromatography to obtain 25.5 g of the objective compound (BisN-2) represented by the following formula.

The following peaks were found by 400 MHz-1H-NMR, and the compound was confirmed to have a chemical structure of the following formula. From the doublets of proton signals at positions 3 and 4, it was confirmed that the substitution position of 2,6-dihydroxynaphthol was position 1.

¹H-NMR: (d-DMSO, internal standard TMS)

δ (ppm) 9.7 (2H, O—H), 7.2-8.5 (19H, Ph-H), 6.6 (1H, C—H)

LC-MS analysis confirmed that the molecular weight was 466.5 corresponding to the following chemical structure.

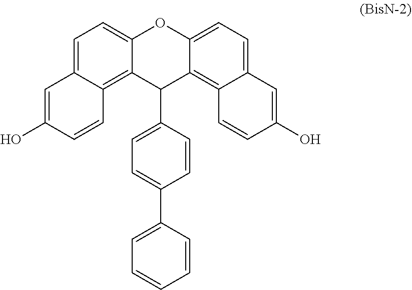 [SMILES: Oc1ccc2c3c(ccc2c1)Oc1ccc2cc(O)ccc2c1C3c1ccc(-c2ccccc2)cc1]

### (Synthesis Example 4-1) Synthesis of RBisN-2

To a container (internal capacity: 500 mL) equipped with a stirrer, a condenser tube, and a burette, 50 g (105 mmol) of BisN-2 and 10.1 g (20 mmol) of monobutylcopper phthalate were added, and 100 mL of 1-butanol was added as a solvent. The reaction solution was stirred at 100° C. for 6 hours and reacted. After cooling, the precipitate was filtered and the resulting crude was dissolved in 100 mL of ethyl acetate. Next, 5 mL of hydrochloric acid was added, and the mixture was stirred at room temperature, and neutralized with sodium hydrogen carbonate. The ethyl acetate solution was concentrated and 200 mL of methanol was added to precipitate the reaction product. After cooling to room temperature, the precipitates were separated by filtration. The obtained solid matter was dried to obtain 38.2 g of the objective resin (RBisN-2) having a structure represented by the following formula.

The polystyrene equivalent molecular weight of the obtained resin was measured by the method described above, and as a result, the obtained resin had Mn: 4232, Mw: 5502, and Mw/Mn: 1.30.

The following peaks were found by NMR measurement performed on the obtained resin under the above measurement conditions, and the resin was confirmed to have a chemical structure of the following formula.

δ (ppm) 9.3-9.7 (2H, O—H), 7.2-8.5 (17H, Ph-H), 6.7-6.9 (1H, C—H)

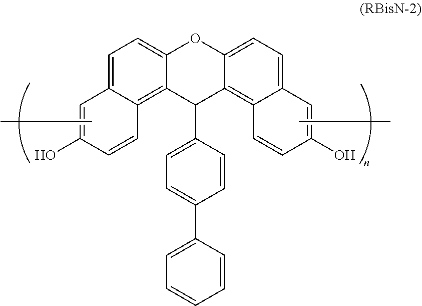

### (Synthesis Example 4-2) Synthesis of RBisN-3

To a container (internal capacity: 500 mL) equipped with a stirrer, a condenser equipped with an internal pressure control valve, and a burette, and a gas injection nozzle capable of injecting gas while bubbling the gas into the bottom surface, 50 g (105 mmol) of BisN-2 and 1.8 g (10 mmol) of copper acetate were added, and 100 mL of 1-butanol was added as a solvent, and then a gas diluted with N2 gas to have an oxygen concentration of 5% was injected in a bubbling state at a rate of 500 mL/min while being stirred by a stirrer, and the reaction solution was stirred at 100° C. for 6 hours and reacted while controlling the internal pressure to be 0.2 MPa. After cooling, the precipitate was collected by filtration, and the resulting crude was dissolved in 100 mL of ethyl acetate. Next, 5 mL of hydrochloric acid was added, and the mixture was stirred at room temperature, and neutralized with sodium hydrogen carbonate. The ethyl acetate solution was concentrated and 200 mL of methanol was added to precipitate the reaction product. After cooling to room temperature, the precipitates were separated by filtration. The obtained solid matter was dried to obtain 36.5 g of the objective resin (RBisN-3) having a structure represented by the following formula.

The polystyrene equivalent molecular weight of the obtained resin was measured by the method described above, and as a result, the obtained resin had Mn: 8795, Mw: 10444, and Mw/Mn: 1.19.

The following peaks were found by NMR measurement performed on the obtained resin under the above measurement conditions, and the resin was confirmed to have a chemical structure of the following formula.

δ (ppm) 9.3-9.7 (2H, O—H), 7.2-8.5 (17H, Ph-H), 6.7-6.9 (1H, C—H)

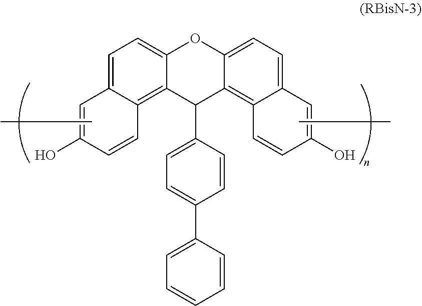

### (Synthesis Example 4-3) Synthesis of RBisN-4

To a container (internal capacity: 500 mL) equipped with a stirrer, a condenser equipped with an internal pressure control valve, and a burette, and a gas injection nozzle capable of injecting gas while bubbling the gas into the bottom surface, 50 g (105 mmol) of BisN-2 and 1.1 g (2 mmol) of monobutylcopper phthalate were added, and 100 mL of 1-butanol was added as a solvent, and then a gas diluted with N2 gas to have an oxygen concentration of 5% was injected in a bubbling state at a rate of 50 mL/min while being stirred by a stirrer, and the reaction solution was stirred at 100° C. for 6 hours and reacted while controlling the internal pressure control valve so that the internal pressure was 0.5 MPa. After cooling, the precipitate was collected by filtration, and the resulting crude was dissolved in 100 mL of ethyl acetate. Next, 5 mL of hydrochloric acid was added, and the mixture was stirred at room temperature, and neutralized with sodium hydrogen carbonate. The ethyl acetate solution was concentrated and 200 mL of methanol was added to precipitate the reaction product. After cooling to room temperature, the precipitates were separated by filtration. The obtained solid matter was dried to obtain 37.1 g of the objective resin (RBisN-4) having a structure represented by the following formula.

The polystyrene equivalent molecular weight of the obtained resin was measured by the method described above, and as a result, the obtained resin had Mn: 9354, Mw: 11298, and Mw/Mn: 1.21.

The following peaks were found by NMR measurement performed on the obtained resin under the above measurement conditions, and the resin was confirmed to have a chemical structure of the following formula.

δ (ppm) 9.3-9.7 (2H, O—H), 7.2-8.5 (17H, Ph-H), 6.7-6.9 (1H, C—H)

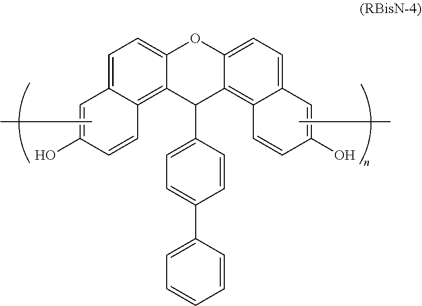

### (Synthesis Example 4A) Synthesis of BisN-5

The same procedure as in Synthesis Example 4 was performed except that 18.2 g (100 mmol) of 4-biphenylaldehyde (manufactured by Mitsubishi Gas Chemical Co., Inc.) of Synthesis Example 4 was changed to 9.1 g (100 mmol) of 4-tolualdehyde (manufactured by Mitsubishi Gas Chemical Co., Inc.), whereby 23.2 g of the objective compound (BisN-3) represented by the following formula was obtained.

The following peaks were found by 400 MHz-1H-NMR, and the compound was confirmed to have a chemical structure of the following formula. From the doublets of proton signals at positions 3 and 4, it was confirmed that the substitution position of 2,6-dihydroxynaphthol was position 1.

¹H-NMR: (d-DMSO, internal standard TMS)

δ (ppm) 9.7 (2H, O—H), 7.2-8.4 (14H, Ph-H), 6.6 (1H, C—H), 1.9 (3H, C—H3)

LC-MS analysis confirmed that the molecular weight was 404.1 corresponding to the following chemical structure.

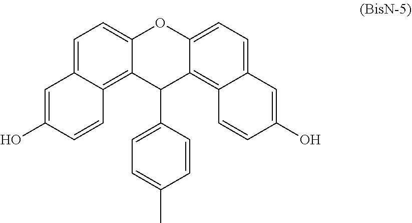 [SMILES: Cc1ccc(C2c3c(ccc4cc(O)ccc34)Oc3ccc4cc(O)ccc4c32)cc1]

### (Synthesis Example 4A-1) Synthesis of RBisN-5

In the same manner as in Synthesis Example 4-1 except that BisN-2 of Synthesis Example 4-1 was changed to BisN-5 obtained in Synthesis Example 4A, 32.1 g of the objective resin (RBisN-5) having a structure represented by the following formula was obtained.

The polystyrene equivalent molecular weight of the obtained resin was measured by the method described above, and as a result, the obtained resin had Mn: 3452, Mw: 4802, and Mw/Mn: 1.39.

The following peaks were found by NMR measurement performed on the obtained resin under the above measurement conditions, and the resin was confirmed to have a chemical structure of the following formula.

δ (ppm) 9.3-9.7 (2H, O—H), 7.2-8.5 (12H, Ph-H), 6.7-6.9 (1H, C—H), 1.9 (3H, C—H3)

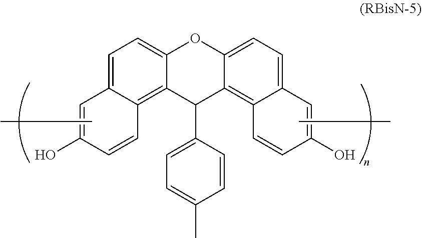

### (Synthesis Example 4B) Synthesis of BisN-6

The same procedure as in Synthesis Example 4 was performed except that 18.2 g (100 mmol) of 4-biphenylaldehyde (manufactured by Mitsubishi Gas Chemical Co., Inc.) of Synthesis Example 4 was changed to 18.8 g (100 mmol) of 4-cyclohexylbenzaldehyde (manufactured by Mitsubishi Gas Chemical Co., Inc.), 33.5 g of the objective compound (BisN-6) represented by the following formula was obtained.

The following peaks were found by 400 MHz-1H-NMR, and the compound was confirmed to have a chemical structure of the following formula. From the doublets of proton signals at positions 3 and 4, it was confirmed that the substitution position of 2,6-dihydroxynaphthol was position 1.

¹H-NMR: (d-DMSO, internal standard TMS)

δ (ppm) 9.7 (2H, O—H), 7.2-8.4 (14H, Ph-H), 6.6 (1H, C—H), 2.5-2.6 (6H, C6-H5)

LC-MS analysis confirmed that the molecular weight was 472.2 corresponding to the following chemical structure.

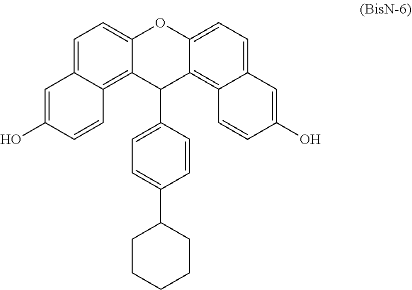 [SMILES: Oc1ccc2c3c(ccc2c1)Oc1ccc2cc(O)ccc2c1C3c1ccc(C2CCCCC2)cc1]

### (Synthesis Example 4B-1) Synthesis of RBisN-6

In the same manner as in Synthesis Example 4-1 except that BisN-2 of Synthesis Example 4-1 was changed to BisN-6 obtained in Synthesis Example 4B, 40.4 g of the objective resin (RBisN-6) having a structure represented by the following formula was obtained.

The polystyrene equivalent molecular weight of the obtained resin was measured by the method described above, and as a result, the obtained resin had Mn: 3672, Mw: 5080, and Mw/Mn: 1.38.

The following peaks were found by NMR measurement performed on the obtained resin under the above measurement conditions, and the resin was confirmed to have a chemical structure of the following formula.

δ (ppm) 9.3-9.7 (2H, O—H), 7.2-8.5 (12H, Ph-H), 6.7 (1H, C—H), 2.5-2.7 (6H, C6-H5)

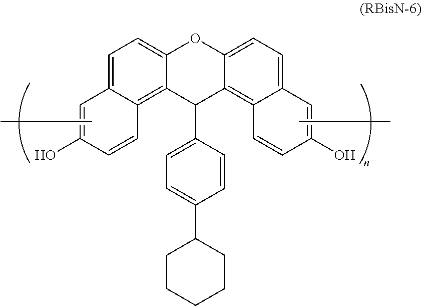

### (Synthesis Example 4C) Synthesis of BisN-7

The same procedure as in Synthesis Example 4 was performed except that 18.2 g (100 mmol) of 4-biphenylaldehyde (manufactured by Mitsubishi Gas Chemical Co., Inc.) of Synthesis Example 4 was changed to g (100 mmol) of 2-naphthaldehyde (manufactured by Kanto Chemical Co., Ltd.) to synthesize the aromatic hydroxy compound of Synthesis Example 4C. In the same manner as in Synthesis Example 4-1 except that the aromatic hydroxy compound was used, 33.5 g of the objective resin (RBisN-7) represented by the following formula was obtained.

The polystyrene equivalent molecular weight of the obtained resin was measured by the method described above, and as a result, the obtained resin had Mn: 4174, Mw: 5280, and Mw/Mn: 1.26.

The following peaks were found by 400 MHz-1H-NMR, and the compound was confirmed to have a chemical structure of the following formula. From the doublets of proton signals at positions 3 and 4, it was confirmed that the substitution position of 2,6-dihydroxynaphthol was position 1.

¹H-NMR: (d-DMSO, internal standard TMS)

δ (ppm) 9.6 (2H, O—H), 7.0-8.5 (19H, Ph-H), 6.6 (1H, C—H), 2.5H, Ph-H), 6.7 (1H, C—H)

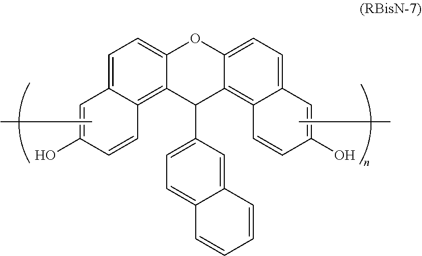

### (Synthesis Example 5) Synthesis of BiF-1

A container (internal capacity: 1 L) equipped with a stirrer, a condenser tube, and a burette was prepared. To this container, 150 g (800 mmol) of 4,4-biphenol (a reagent manufactured by Tokyo Chemical Industry Co., Ltd.), 75 g (410 mmol) of 4-biphenylaldehyde (manufactured by Mitsubishi Gas Chemical Co., Inc.), and 300 mL of propylene glycol monomethyl ether were added, and 19.5 g (105 mmol) of p-toluenesulfonic acid (a reagent manufactured by Kanto Chemical Co., Inc.) was added to prepare a reaction liquid. This reaction liquid was stirred at 90° C. for 3 hours and reacted. Next, the reaction liquid was neutralized with 24% aqueous sodium hydroxide solution. The reaction product was precipitated by the addition of 100 g of distilled water. After cooling to 5° C., the precipitates were separated by filtration. The solid matter obtained by filtration was dried and then separated and purified by column chromatography to obtain 25.8 g of the objective compound (BiF-1) represented by the following formula.

The following peaks were found by 400 MHz-1H-NMR, and the compound was confirmed to have a chemical structure of the following formula.

¹H-NMR: (d-DMSO, internal standard TMS)

δ (ppm) 9.4 (4H, O—H), 6.8-7.8 (22H, Ph-H), 6.2 (1H, C—H)

LC-MS analysis confirmed that the molecular weight was 536.2 corresponding to the following chemical structure.

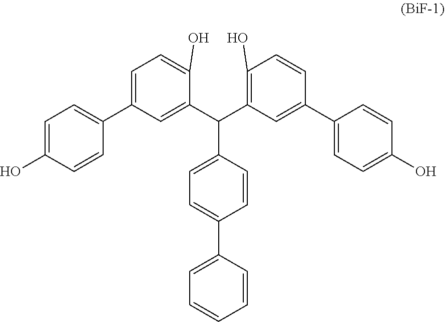 [SMILES: Oc1ccc(-c2ccc(O)c(C(c3ccc(-c4ccccc4)cc3)c3cc(-c4ccc(O)cc4)ccc3O)c2)cc1]

### (Synthesis Example 5-1) Synthesis of RBiF-1

To a container (internal capacity: 500 mL) equipped with a stirrer, a condenser tube, and a burette, 55.0 g (105 mmol) of BiF-1 and 10.1 g (20 mmol) of monobutylcopper phthalate were added, and 100 mL of 1-butanol was added as a solvent. The reaction solution was stirred at 100° C. for 6 hours and reacted. After cooling, the precipitate was filtered and the resulting crude was dissolved in 100 mL of ethyl acetate. Next, 5 mL of hydrochloric acid was added, and the mixture was stirred at room temperature, and neutralized with sodium hydrogen carbonate. The ethyl acetate solution was concentrated and 200 mL of methanol was added to precipitate the reaction product. After cooling to room temperature, the precipitates were separated by filtration. The obtained solid matter was dried to obtain 34.3 g of the objective resin (RBiF-1) having a structure represented by the following formula.

The polystyrene equivalent molecular weight of the obtained resin was measured by the method described above, and as a result, the obtained resin had Mn: 4532, Mw: 5698, and Mw/Mn: 1.26.

The following peaks were found by NMR measurement performed on the obtained resin under the above measurement conditions, and the resin was confirmed to have a chemical structure of the following formula.

δ (ppm) 9.4-9.7 (4H, O—H), 6.8-8.1 (20H, Ph-H), 6.3-6.5 (1H, C—H)

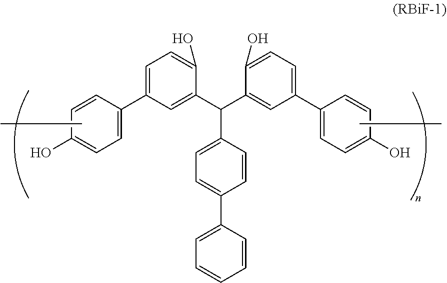

### (Synthesis Example 5-2) Synthesis of RBiF-2

To a container (internal capacity: 500 mL) equipped with a stirrer, a condenser equipped with an internal pressure control valve, and a burette, and a gas injection nozzle capable of injecting gas while bubbling the gas into the bottom surface, 55.0 g (105 mmol) of BiF-1 and 1.01 g (2 mmol) of monobutylcopper phthalate were added, and 100 mL of 1-butanol was added as a solvent, and then a gas diluted with N2 gas to have an oxygen concentration of 5% was injected in a bubbling state at a rate of 500 mL/min while being stirred by a stirrer, and the reaction solution was stirred at 100° C. for 6 hours and reacted. After cooling, the precipitate was collected by filtration, and the resulting crude was dissolved in 100 mL of ethyl acetate. Next, 5 mL of hydrochloric acid was added, and the mixture was stirred at room temperature, and neutralized with sodium hydrogen carbonate. The ethyl acetate solution was concentrated and 200 mL of methanol was added to precipitate the reaction product. After cooling to room temperature, the precipitates were separated by filtration. The obtained solid matter was dried to obtain 35.3 g of the objective resin (RBiF-2) having a structure represented by the following formula.

The polystyrene equivalent molecular weight of the obtained resin was measured by the method described above, and as a result, the obtained resin had Mn: 9249, Mw: 11286, and Mw/Mn: 1.26.

The following peaks were found by NMR measurement performed on the obtained resin under the above measurement conditions, and the resin was confirmed to have a chemical structure of the following formula.

δ (ppm) 9.4-9.7 (4H, O—H), 6.8-8.1 (20H, Ph-H), 6.3-6.5 (1H, C—H)

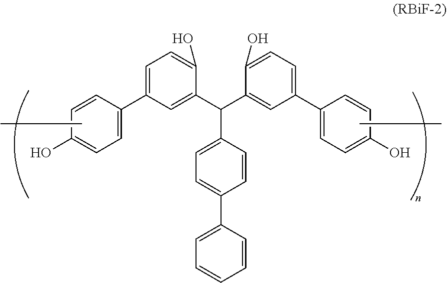

### (Synthesis Example 5A) Synthesis of BiF-3

In the same manner as in Synthesis Example 5, except that 75 g (410 mmol) of 4-biphenylaldehyde (manufactured by Mitsubishi Gas Chemical Co., Inc.) of Synthesis Example 5 was changed to 4-tolualdehyde (manufactured by Mitsubishi Gas Chemical Co., Inc.), 26.3 g of the objective compound (BiF-3) represented by the following formula was obtained.

The following peaks were found by 400 MHz-1H-NMR, and the compound was confirmed to have a chemical structure of the following formula.

¹H-NMR: (d-DMSO, internal standard TMS)

δ (ppm) 9.4 (4H, O—H), 6.8-7.8 (18H, Ph-H), 6.2 (1H, C—H), 1.8 (3H, C—H3)

LC-MS analysis confirmed that the molecular weight was 474.5 corresponding to the following chemical structure.

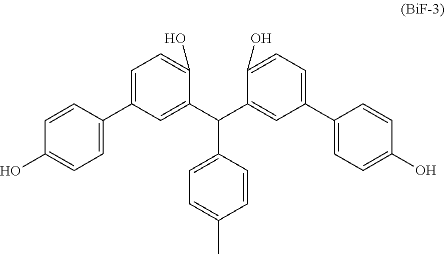 [SMILES: Cc1ccc(C(c2cc(-c3ccc(O)cc3)ccc2O)c2cc(-c3ccc(O)cc3)ccc2O)cc1]

### (Synthesis Example 5A-1) Synthesis of RBiF-3

In the same manner as in Synthesis Example 5-1 except that BiF-1 of Synthesis Example 5-1 was changed to BiF-3 obtained in Synthesis Example 5A, 31.2 g of the objective resin (RBiF-3) having a structure represented by the following formula was obtained.

The polystyrene equivalent molecular weight of the obtained resin was measured by the method described above, and as a result, the obtained resin had Mn: 4232, Mw: 5288, and Mw/Mn: 1.25.

The following peaks were found by NMR measurement performed on the obtained resin under the above measurement conditions, and the resin was confirmed to have a chemical structure of the following formula.

δ (ppm) 9.4-9.7 (4H, O—H), 6.8-8.1 (16H, Ph-H), 6.3-6.5 (1H, C—H), 1.8-1.9 (3H, C—H3)

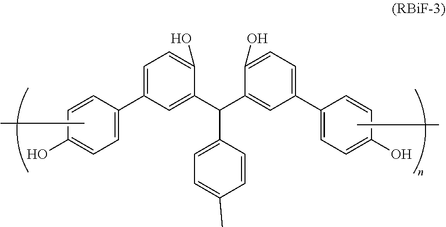

### (Synthesis Example 5B) Synthesis of BiF-4

In the same manner as in Synthesis Example 5, except that 75 g (410 mmol) of 4-biphenylaldehyde (manufactured by Mitsubishi Gas Chemical Co., Inc.) of Synthesis Example 5 was changed to 4-cyclohexylbenzaldehyde (manufactured by Mitsubishi Gas Chemical Co., Inc.), 32.1 g of the objective compound (BiF-4) represented by the following formula was obtained.

The following peaks were found by 400 MHz-1H-NMR, and the compound was confirmed to have a chemical structure of the following formula.

¹H-NMR: (d-DMSO, internal standard TMS)

δ (ppm) 9.4 (4H, O—H), 6.8-7.8 (18H, Ph-H), 6.2 (1H, C—H), 2.4-2.6 (10H, C6H10)

LC-MS analysis confirmed that the molecular weight was 542.7 corresponding to the following chemical structure.

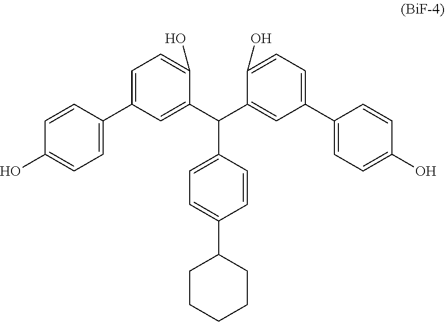 [SMILES: Oc1ccc(-c2ccc(O)c(C(c3ccc(C4CCCCC4)cc3)c3cc(-c4ccc(O)cc4)ccc3O)c2)cc1]

### (Synthesis Example 5B-1) Synthesis of RBiF-4

In the same manner as in Synthesis Example 5-1 except that BiF-1 of Synthesis Example 5-1 was changed to BiF-4 obtained in Synthesis Example 5B, 29.5 g of the objective resin (RBiF-4) having a structure represented by the following formula was obtained.

The polystyrene equivalent molecular weight of the obtained resin was measured by the method described above, and as a result, the obtained resin had Mn: 4431, Mw: 5568, and Mw/Mn: 1.26.

The following peaks were found by NMR measurement performed on the obtained resin under the above measurement conditions, and the resin was confirmed to have a chemical structure of the following formula.

δ (ppm) 9.4-9.7 (4H, O—H), 6.8-8.1 (16H, Ph-H), 6.3-6.5 (1H, C—H), 2.4-2.9 (10H, C6H10)

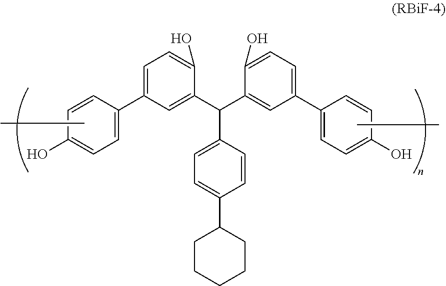

### (Synthesis Example 5C) Synthesis of BiF-5

In the same manner as in Synthesis Example 5, except that 75 g (410 mmol) of 4-biphenylaldehyde (manufactured by Mitsubishi Gas Chemical Co., Inc.) of Synthesis Example 5 was changed to 2-naphthaldehyde (manufactured by Mitsubishi Gas Chemical Co., Inc.), 33.5 g of the objective compound (BiF-5) represented by the following formula was obtained.

The following peaks were found by 400 MHz-1H-NMR, and the compound was confirmed to have a chemical structure of the following formula.

¹H-NMR: (d-DMSO, internal standard TMS)

δ (ppm) 9.4 (4H, O—H), 6.8-7.8 (21H, Ph-H), 6.2 (1H, C—H)

LC-MS analysis confirmed that the molecular weight was 510.6 corresponding to the following chemical structure.

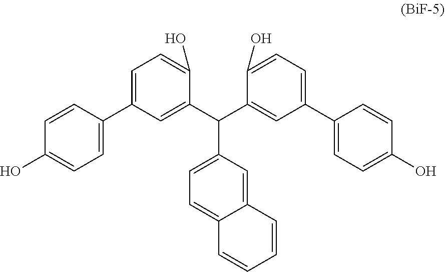 [SMILES: Oc1ccc(-c2ccc(O)c(C(c3ccc4ccccc4c3)c3cc(-c4ccc(O)cc4)ccc3O)c2)cc1]

### (Synthesis Example 5C-1) Synthesis of RBiF-5

In the same manner as in Synthesis Example 5-1 except that BiF-1 of Synthesis Example 5-1 was changed to BiF-5 obtained in Synthesis Example 5C, 29.5 g of the objective resin (RBiF-4) having a structure represented by the following formula was obtained.

The polystyrene equivalent molecular weight of the obtained resin was measured by the method described above, and as a result, the obtained resin had Mn: 4133, Mw: 5462, and Mw/Mn: 1.32.

The following peaks were found by NMR measurement performed on the obtained resin under the above measurement conditions, and the resin was confirmed to have a chemical structure of the following formula.

δ (ppm) 9.4-9.7 (4H, O—H), 6.8-8.1 (19H, Ph-H), 6.3-6.5 (1H, C—H)

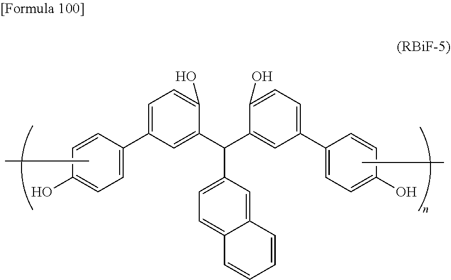

### (Synthesis Example 6) Synthesis of DB-1

### (a) Production of Calcium Dibenzochrysene Sulfonate

Into a four-necked flask (capacity: 1 L) equipped with a mechanical stirrer, 20 g of dibenzo[g, p]chrysene (0.06 mol, HPLC purity: 99.8%) and 200 g (1.94 mol) of 95% sulfuric acid (manufactured by Wako Pure Chemical Industries, Ltd.) was added. The reaction was carried out with stirring at an internal temperature of 80° C. for 2 hours while keeping the temperature in a hot water bath. As a result, the content became a uniform gray viscous liquid.

While cooling the flask containing the contents obtained above in an ice bath, 400 g of distilled water was added. At the time of the addition, the addition was performed while maintaining an internal temperature of 40° C. or lower while measuring the temperature so that the internal temperature does not exceed 40° C. due to heat generation. Next, 154.4 g (2.08 mol) of powdered calcium hydroxide (manufactured by Wako Pure Chemical Industries, Ltd.) was added to the flask to which the distilled water was added. At the time of the addition, the addition was performed while maintaining an internal temperature of 45° C. or lower while measuring the temperature so that the internal temperature does not exceed 45° C. due to heat generation. By this addition, calcium sulfate was precipitated as a white solid, and the content became a slurry. Moreover, the liquid property was alkaline.

The slurry thus obtained was subjected to suction filtration using a stainless buchner funnel and No. 2 filter paper, and the resulting filtrate (pale yellow liquid) was collected. Further, the solid content residue (mainly calcium sulfate) was washed with 350 g of distilled water, and the washing liquid was also collected and concentrated under reduced pressure using a rotary evaporator together with the above filtrate. As a result, 36.5 g of calcium dibenzochrysene sulfonate, which is a pale yellow powdery solid, was obtained (yield 82.7%). The calcium dibenzochrysene sulfonate is considered to be a mixture in which 98% is a 4-substituted dibenzochrysene sulfonate and the balance is a 3-substituted dibenzochrysene sulfonate from the result of LC/MS analysis of hydroxydibenzochrysene described later.

### (b) Production of Hydroxydibenzochrysene

Into a cylindrical container made of nickel having a volume of 100 mL, 14.0 g (0.212 mol) of 85% potassium hydroxide granules (manufactured by Wako Pure Chemical Industries, Ltd.) was put, and hot-melted on a hot plate (400° C.). Subsequently, 4.0 g (0.0055 mol) of the calcium dibenzochrysene sulfonate obtained above (mixture 8) was added. At the time of this addition, the calcium dibenzochrysene sulfonate was charged into the above nickel cylindrical container over 30 minutes, and the reaction was promoted by stirring with a stainless steel spoon at the time of charging. Further, stirring was continued for 30 minutes after the addition of the calcium dibenzochrysene sulfonate was completed. As a result, a reddish-brown viscous liquid was obtained.

The reddish-brown viscous liquid obtained above (the contents of the nickel cylindrical container) was poured into a stainless steel cup having a volume of 200 mL while hot and allowed to cool and solidify. Subsequently, 40 g of distilled water was added to the stainless steel cup to dissolve the solid matter in water to obtain a reddish-brown, slightly cloudy liquid.

Next, the reddish-brown liquid was transferred to a glass beaker having a volume of 200 mL, and while stirring using a magnetic stirrer, 35% hydrochloric acid (Wako Pure Chemical Industries, Ltd.) was added to obtain contents containing brown solid. At the time of this addition, the addition was continued until the pH of the contents reached pH 3 while measuring the pH with a pH meter. The above brown solid was confirmed to be precipitated at the time of neutralization.

Then, 30 g of ethyl acetate (Wako Pure Chemical Industries, Ltd.) was added to the contents obtained so far and stirred to dissolve the brown solid. Then, the obtained liquid was allowed to stand to be separated into an organic phase and an aqueous phase, and then the organic phase was separated. The separated organic layer was filtered through a glass funnel and No. 2 filter paper to remove insoluble matter, and then concentrated under reduced pressure using a rotary evaporator to obtain 1.6 g of a brown powdery solid (yield: 73.9%). As a result of subjecting the brown powdery solid obtained by the above operation to LC/MS analysis, the brown powdery solid was 4-substituted hydroxydibenzochrysene having a purity of 98%.

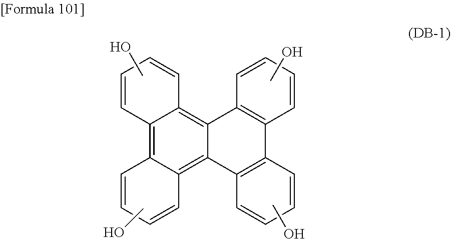

### (Synthesis Example 6-1) Synthesis of RDB-1

To a container (internal capacity: 500 mL) equipped with a stirrer, a condenser tube, and a burette, 80.0 g of DB-1 and 10.1 g (20 mmol) of monobutylcopper phthalate were added, and 100 mL of 1-butanol was added as a solvent. The reaction solution was stirred at 100° C. for 6 hours and reacted. After cooling, the precipitate was filtered and the resulting crude was dissolved in 100 mL of ethyl acetate. Next, 5 mL of hydrochloric acid was added, and the mixture was stirred at room temperature, and neutralized with sodium hydrogen carbonate. The ethyl acetate solution was concentrated and 300 mL of heptane was added to precipitate the reaction product. After cooling to room temperature, the precipitates were separated by filtration. The obtained solid matter was dried to obtain 64.5 g of the objective resin (RDB-1) having a structure represented by the group represented by the following formula.

The polystyrene equivalent molecular weight of the obtained resin was measured by the method described above, and as a result, the obtained resin had Mn: 2512, Mw: 3298, and Mw/Mn: 1.31.

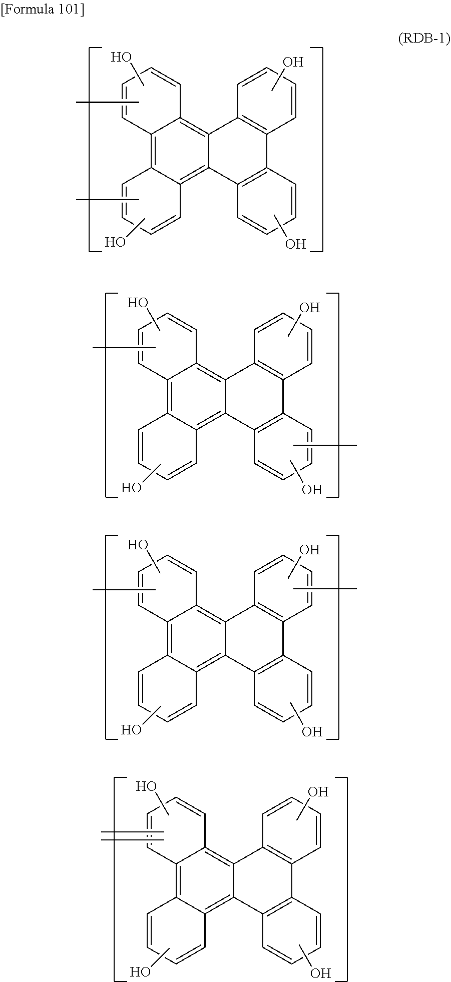

### (Synthesis Example 6-2) Synthesis of R-NFA01

Into a 500 mL four-necked flask under nitrogen, 4,4′-methylenebis(2-(hydroxymethyl)-6-methylphenol) (18.0 g; 0.0624 mol, manufactured by ASAHI YUKIZAI CORPORATION), 2,6 dihydroxynaphthalene (100.0 g; 0.624 mol, manufactured by Tokyo Chemical Industry Co., Ltd.), and hydrochloric acid (6.32 g; 0.0624 mol, manufactured by Tokyo Chemical Industry Co., Ltd.) were added, and 200 g of 1-methoxy-2-propanol (hereinafter referred to as “PGME”.) was added, stirred, heated to 60° C. to dissolve, and polymerization was started. After 3 hours, the mixture was allowed to cool to 25° C. and then reprecipitated in 1600 g of water.

The obtained precipitate was filtered and dried in a vacuum drier at 60° C. for 16 hours to obtain 65.4 g of the objective oligomer having a structural unit represented by the following formula (NFA01). The obtained oligomer had a weight-average molecular weight of 1730 and a dispersibility of 2.60 as measured in terms of polystyrene by GPC.

Next, to a container (internal capacity: 500 mL) equipped with a stirrer, a condenser tube, and a burette, 40.0 g of the oligomer (NFA01) obtained as described above and 10.1 g (20 mmol) of monobutylcopper phthalate were added, and 100 mL of 1-butanol was added as a solvent. The reaction solution was stirred at 100° C. for 6 hours and reacted. After cooling, the precipitate was filtered and the resulting crude was dissolved in 100 mL of ethyl acetate. Next, 5 mL of hydrochloric acid was added, and the mixture was stirred at room temperature, and neutralized with sodium hydrogen carbonate. The ethyl acetate solution was concentrated and 300 mL of heptane was added to precipitate the reaction product. After cooling to room temperature, the precipitates were separated by filtration. The obtained solid matter was dried to obtain 24.5 g of the objective resin (R-NFA01) having a structure represented by the group represented by the following formula.

The polystyrene equivalent molecular weight of the obtained resin was measured by the method described above, and as a result, the obtained resin had Mn: 4512, Mw: 6298, and Mw/Mn: 1.40.

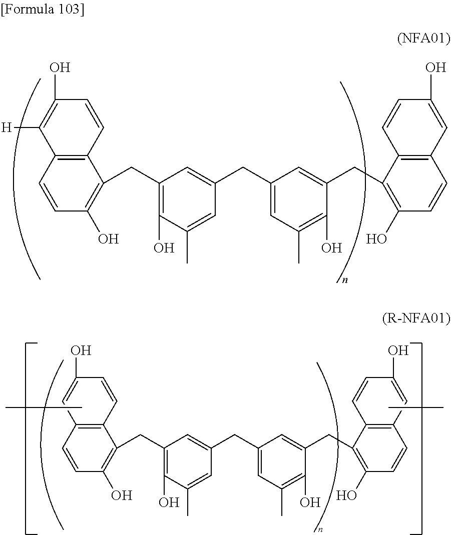

### (Synthesis Example 1-A1) Synthesis of R-DHN-A1

Except that instead of 2,6-dihydroxynaphthalene, 15.1 g (105 mmol) of 2-hydroxynaphthalene (reagents manufactured by Kanto Chemical Co., Inc.) was used in the method for synthesizing R-DHN in Synthesis Example 1, 21.5 g of the objective resin (R-DHN-A1) having a structure represented by the following formula was obtained by the same method as in Synthesis Example 1.

The polystyrene equivalent molecular weight of the obtained resin was measured by the method described above, and as a result, the obtained resin had Mn: 4567, Mw: 5612, and Mw/Mn: 1.23.

The following peaks were found by NMR measurement performed on the obtained resin under the above measurement conditions, and the resin was confirmed to have a chemical structure of the following formula.

δ (ppm) 9.7-9.8 (2H, O—H), 7.0-7.9 (4H, Ph-H)

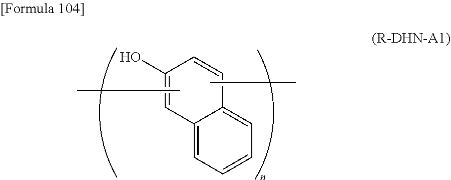

### (Synthesis Example 1-A2) Synthesis of R-DHN-A2

Except that instead of 2,6-dihydroxynaphthalene, 15.1 g (105 mmol) of 1-hydroxynaphthalene (reagents manufactured by Kanto Chemical Co., Inc.) was used in the method for synthesizing R-DHN in Synthesis Example 1, 21.5 g of the objective resin (R-DHN-A2) having a structure represented by the following formula was obtained by the same method as in Synthesis Example 1.

The polystyrene equivalent molecular weight of the obtained resin was measured by the method described above, and as a result, the obtained resin had Mn: 6137, Mw: 7622, and Mw/Mn: 1.24.

The following peaks were found by NMR measurement performed on the obtained resin under the above measurement conditions, and the resin was confirmed to have a chemical structure of the following formula.

δ (ppm) 9.7-9.8 (2H, O—H), 7.0-7.9 (4H, Ph-H)

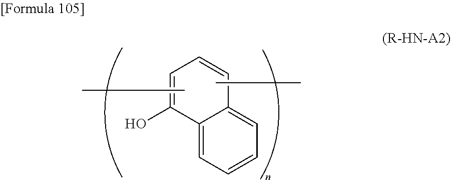

### (Synthesis Example 1-B1) Synthesis of R-DHN-B1

Except that 2,3-dihydroxynaphthalene (reagent manufactured by Kanto Chemical Co., Inc.) in an amount of 5.6 g (35 mmol), 2,6-dihydroxynaphthalene (reagent manufactured by Kanto Chemical Co., Inc.) in an amount of 5.6 g (35 mmol), and 1,5-dihydroxynaphthalene (reagent manufactured by Kanto Chemical Co., Inc.) in an amount of 5.6 g (35 mmol) were used instead of 2,6-dihydroxynaphthalene in the method for synthesizing R-DHN in Synthesis Example 1, 20.4 g of the objective resin (R-DHN-B1) having a structure represented by the following formula was obtained in the same manner as in Synthesis Example 1.

The polystyrene equivalent molecular weight of the obtained resin was measured by the method described above, and as a result, the obtained resin had Mn: 7179, Mw: 9541, and Mw/Mn: 1.34. Further, the obtained resin was subjected to C13-NMR measurement, and it was confirmed that the composition ratio was a:b:c=1:1:1.

The following peaks were found by NMR measurement performed on the obtained resin under the above measurement conditions, and the resin was confirmed to have a chemical structure of the following formula.

δ (ppm) 9.7-9.8 (2H, O—H), 7.0-7.9 (4H, Ph-H)

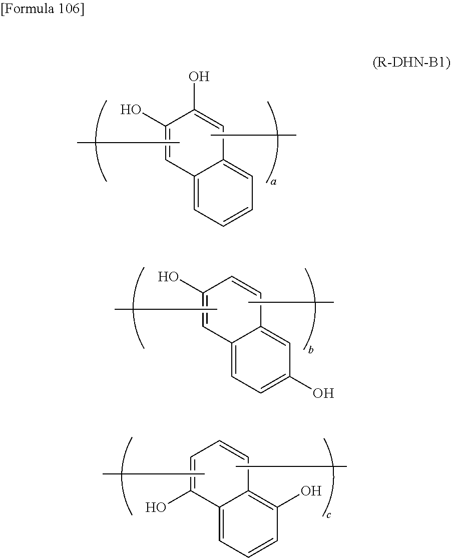

### (Synthesis Example 1-B2) Synthesis of R-DHN-B2

Except that 2,3-dihydroxynaphthalene (reagent manufactured by Kanto Chemical Co., Inc.) was used instead of 2,6-dihydroxynaphthalene in an amount of 5.6 g (35 mmol), 2,6-dihydroxynaphthalene (reagent manufactured by Kanto Chemical Co., Inc.) in an amount of 5.6 g (35 mmol), and 2-dihydroxynaphthalene (reagent manufactured by Kanto Chemical Co., Inc.) in an amount of 5.1 g (35 mmol) in the method for synthesizing R-DHN in Synthesis Example 1, 18.8 g of the objective resin (R-DHN-B2) having a structure represented by the following formula was obtained in the same manner as in Synthesis Example 1.

The polystyrene equivalent molecular weight of the obtained resin was measured by the method described above, and as a result, the obtained resin had Mn: 6912, Mw: 8533, and Mw/Mn: 1.23.

Further, the obtained resin was subjected to C13-NMR measurement, and it was confirmed that the composition ratio was a:b:c=1:1:1.

The following peaks were found by NMR measurement performed on the obtained resin under the above measurement conditions, and the resin was confirmed to have a chemical structure of the following formula.

δ (ppm) 9.7-9.8 (2H, O—H), 7.0-7.9 (4H, Ph-H)

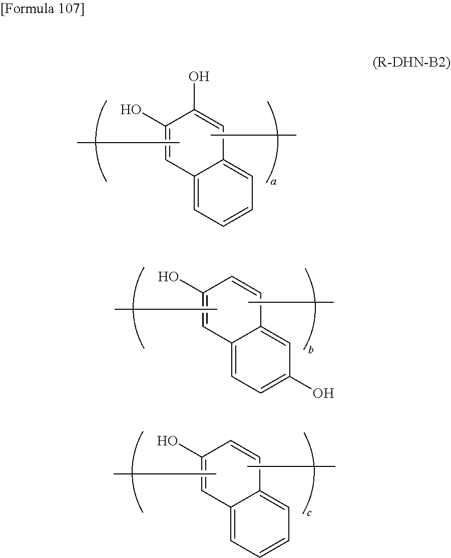

### Comparative Synthesis Example 1

A four necked flask (internal capacity: 10 L) equipped with a Dimroth condenser tube, a thermometer and a stirring blade, and having a detachable bottom was prepared. To this four necked flask, 1.09 kg (7 mol) of 1,5-dimethylnaphthalene (manufactured by Mitsubishi Gas Chemical Co., Inc.), 2.1 kg (28 mol as formaldehyde) of 40% by mass of an aqueous formalin solution (manufactured by Mitsubishi Gas Chemical Co., Inc.), and 0.97 mL of 98% by mass of sulfuric acid (manufactured by Kanto Chemical Co., Inc.) were added in a nitrogen stream, and the mixture was reacted for 7 hours while refluxed at 100° C. at normal pressure. Subsequently, 1.8 kg of ethylbenzene (special grade reagent manufactured by Wako Pure Chemical Industries, Ltd.) was added as a diluting solvent to the reaction liquid, and the mixture was left to stand still, followed by removal of an aqueous phase as a lower phase. Neutralization and washing with water were further performed, and ethylbenzene and unreacted 1,5-dimethylnaphthalene were distilled off under reduced pressure to obtain 1.25 kg of a dimethylnaphthalene formaldehyde resin as a light brown solid.

Subsequently, a four necked flask (internal capacity: 0.5 L) equipped with a Dimroth condenser tube, a thermometer, and a stirring blade was prepared. To this four necked flask, 100 g (0.51 mol) of the dimethylnaphthalene formaldehyde resin obtained as described above, and 0.05 g of p-toluenesulfonic acid were added in a nitrogen stream, and the temperature was raised to 190° C. at which the mixture was then heated for 2 hours, followed by stirring. Subsequently, 52.0 g (0.36 mol) of 1-naphthol was added thereto, and the temperature was further raised to 220° C. at which the mixture was reacted for 2 hours. After dilution with a solvent, neutralization and washing with water were performed, and the solvent was distilled off under reduced pressure to obtain 126.1 g of a modified resin (CR-1) as a black-brown solid.

### Comparative Synthesis Example 2

To a container (internal capacity: 100 ml) equipped with a stirrer, a condenser tube, and a burette, 10 g (21 mmol) of BisN-2, 0.7 g (42 mmol) of paraformaldehyde, 50 mL of glacial acetic acid, and 50 mL of PGME were added, and 8 mL of 95% sulfuric acid was added thereto. The reaction solution was stirred at 100° C. for 6 hours and reacted. Next, the reaction solution was concentrated and 1000 mL of methanol was added to precipitate the reaction product. After cooling to room temperature, the precipitates were separated by filtration. The obtained solid material was filtered and dried to obtain 7.2 g of the objective resin (NBisN-2) having a structure represented by the following formula.

The polystyrene equivalent molecular weight of the obtained resin was measured by the method described above, and as a result, the obtained resin had Mn: 778, Mw: 1793, and Mw/Mn: 2.30.

The following peaks were found by NMR measurement performed on the obtained resin under the above measurement conditions, and the resin was confirmed to have a chemical structure of the following formula.

δ (ppm) 9.7 (2H, O—H), 7.2-8.5 (17H, Ph-H), 6.6 (1H, C—H), 4.1 (2H, —CH2)

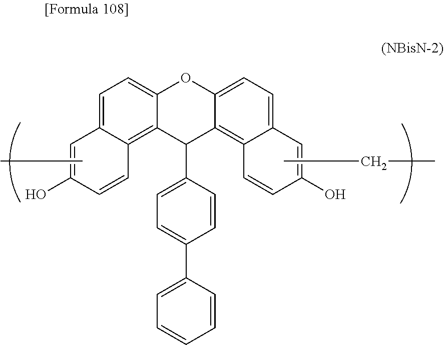

### Examples 1 to 6, Reference Example 1, and Comparative Examples 1 and 2

Table 1 shows the results of evaluating the heat resistance by the evaluation methods shown below using the resins obtained in Synthesis Examples 1 to 6-2 and Comparative Synthesis Examples 1 and 2.

TABLE 1

| | | | Heat resistance | |
|---|---|---|---|---|
| | Resin | | evaluation | |
| Example 1 | Synthesis | R-DHN | A | 460° C. |
| | Example 1 | | | |
| Example 1-2 | Synthesis Example | R-2,7DHN | A | 450° C. |
| | 1-2 | | | |
| Example 1-3 | Synthesis Example | R-2,3DHN | A | 455° C. |
| | 1-3 | | | |
| Example 1-4 | Synthesis Example | R-1,5DHN | A | 455° C. |
| | 1-4 | | | |
| Example 1-5 | Synthesis Example | R-1,6DHN | A | 450° C. |
| | 1-5 | | | |
| Example 1-6 | Synthesis Example | R-FLBNDHN | A | 460° C. |
| | 1-6 | | | |
| Example 1-7 | Synthesis Example | R-DHN-A1 | A | 460° C. |
| | 1-A1 | | | |
| Example 1-8 | Synthesis Example | R-DHN-A2 | A | 460° C. |
| | 1-A2 | | | |
| Example 1-9 | Synthesis Example | R-DHN-B1 | A | 455° C. |
| | 1-B1 | | | |
| Example 1-10 | Synthesis Example | R-DHN-B2 | A | 450° C. |
| | 1-B2 | | | |
| Example 2 | Synthesis | R-BiF | A | 490° C. |
| | Example 2 | | | |
| Example 3 | Synthesis Example | RBisN-1 | A | 490° C. |
| | 3-1 | | | |
| Example 4-1 | Synthesis Example | RBisN-2 | A | 490° C. |
| | 4-1 | | | |
| Example 4-2 | Synthesis Example | RBisN-3 | A | 490° C. |
| | 4-2 | | | |
| Example 4-3 | Synthesis Example | RBisN-4 | A | 490° C. |
| | 4-3 | | | |
| Example 4-4 | Synthesis Example | RBisN-5 | A | 490° C. |
| | 4A-1 | | | |
| Example 4-5 | Synthesis Example | RBisN-6 | A | 490° C. |
| | 4B-1 | | | |
| Example 4-6 | Synthesis Example | RBisN-7 | A | 500° C. |
| | 4C-1 | | | |
| Example 5-1 | Synthesis Example | RBiF-1 | A | 480° C. |
| | 5-1 | | | |
| Example 5-2 | Synthesis Example | RBiF-2 | A | 490° C. |
| | 5-2 | | | |
| Example 5-3 | Synthesis Example | RBiF-3 | A | 490° C. |
| | 5A-1 | | | |
| Example 5-4 | Synthesis Example | RBiF-4 | A | 480° C. |
| | 5B-1 | | | |
| Example 5-5 | Synthesis Example | RBiF-5 | A | 500° C. |
| | 5C-1 | | | |
| Example 6 | Synthesis Example | RDB-1 | A | 480° C. |
| | 6-1 | | | |
| Reference | Synthesis Example | R-NFA01 | A | 450° C. |
| Example 1 | 6-2 | | | |
| Comparative | Comparative | CR-1 | C | 260° C. |
| Example 1 | Synthesis | | | |
| | Example 1 | | | |
| Comparative | Comparative | NBisN-2 | B | 310° C. |
| Example 2 | Synthesis | | | |
| | Example 2 | | | |

As is evident from Table 1, it was able to be confirmed that the resins used in Examples 1 to 6 have good heat resistance whereas the resins used in Comparative Examples 1 to 2 is inferior in heat resistance. In particular, it was able to be confirmed that the resins used in Examples 2 to 6 exhibited remarkably good heat resistance.

### Examples 7 to 12 and Comparative Example 3

### (Heat Resistance and Resist Performance)

By using the resins obtained in Synthesis Example 1 to 6-1 and Comparative Example 1, the test for heat resistance and evaluation of resist performance below were carried out, and the results thereof are shown in Table 2.

### (Preparation of Resist Composition)

A resist composition was prepared according to the recipe shown in Table 2 using each resin synthesized as described above. For the components of the resist compositions in Table 2, the following acid generating agent (C), acid diffusion controlling agent (E), and solvent were used.

Acid Generating Agent (C)

P-1: triphenylbenzenesulfonium trifluoromethanesulfonate (Midori Kagaku Co., Ltd.)

Acid Diffusion Controlling Agent (E)

Q-1: trioctylamine (Tokyo Kasei Kogyo Co., Ltd.) Solvent

S-1: propylene glycol monomethyl ether (Tokyo Kasei Kogyo Co., Ltd.)

### (Method for Evaluating Resist Performance of Resist Composition)

A clean silicon wafer was spin coated with the homogeneous resist composition, and then prebaked (PB) before exposure in an oven of 110° C. to form a resist film with a thickness of 60 nm. The obtained resist film was irradiated with electron beams of 1:1 line and space setting with a 50 nm interval using an electron beam lithography system (ELS-7500 manufactured by ELIONIX INC.). After the irradiation, the resist film was heated at each predetermined temperature for 90 seconds, and immersed in 2.38% by mass tetramethylammonium hydroxide (TMAH) alkaline developing solution for 60 seconds for development. Subsequently, the resist film was washed with ultrapure water for 30 seconds, and dried to form a positive type resist pattern. Concerning the formed resist pattern, the line and space were observed by a scanning electron microscope (S-4800 manufactured by Hitachi High-Technologies Corporation) to evaluate the reactivity by electron beam irradiation of the resist composition.

TABLE 2

| | | Resist composition | | | | |
|---|---|---|---|---|---|---|
| | | Resin | P-1 | Q-1 | S-1 | Resist performance |
| | Resin | [g] | [g] | [g] | [g] | evaluation |
| Example 7 | R-DHN | 1.0 | 0.3 | 0.03 | 50.0 | Good |
| Example 8 | R-BiF | 1.0 | 0.3 | 0.03 | 50.0 | Good |
| Example 9 | RBisN-1 | 1.0 | 0.3 | 0.03 | 50.0 | Good |
| Example 10 | RBisN-2 | 1.0 | 0.3 | 0.03 | 50.0 | Good |
| Example 11 | RBiF-1 | 1.0 | 0.3 | 0.03 | 50.0 | Good |
| Example 12 | RDB-1 | 1.0 | 0.3 | 0.03 | 50.0 | Good |
| Comparative | CR-1 | 1.0 | 0.3 | 0.03 | 50.0 | Poor |
| Example 3 | | | | | | |

In the resist pattern evaluation, a good resist pattern was obtained by irradiation with electron beams of 1:1 line and space setting with a 50 nm interval in each of Examples 7 to 12. As for the line edge roughness, a pattern having asperities of less than 50 nm was evaluated to be good. On the other hand, it was not possible to obtain a good resist pattern in Comparative Example 3.

When the resin satisfying the requirements of the present embodiment is used as described above, the resin can have the high heat resistance and can impart a good shape to a resist pattern, as compared with the resin (CR-1) of Comparative Example 3 which does not satisfy the requirements. As long as the above requirements of the present embodiment are met, compounds other than the resins described in Examples also exhibit the same effects.

### Examples 13 to 18 and Comparative Example 4

### (Preparation of Radiation-Sensitive Composition)

The components set forth in Table 3 were formulated and formed into homogeneous solutions, and the obtained homogeneous solutions were filtered through a Teflon® membrane filter with a pore diameter of 0.1 μm to prepare radiation-sensitive compositions. Each of the prepared radiation-sensitive compositions was evaluated as described below.

TABLE 3

| | Composition | | |
|---|---|---|---|
| | Component | Optically active | |
| | (A) | compound (B) | Solvent |
| | [g] | [g] | [g] |
| Example 13 | R-DHN | B-1 | S-1 |
| | 0.5 | 1.5 | 30.0 |
| Example 14 | R-BiF | B-1 | S-1 |
| | 0.5 | 1.5 | 30.0 |
| Example 15 | RBisN-1 | B-1 | S-1 |
| | 0.5 | 1.5 | 30.0 |
| Example 16 | RBisN-2 | B-1 | S-1 |
| | 0.5 | 1.5 | 30.0 |
| Example 17 | RBisF-1 | B-1 | S-1 |
| | 0.5 | 1.5 | 30.0 |
| Example 18 | RDB-1 | B-1 | S-1 |
| | 0.5 | 1.5 | 30.0 |
| Comparative | PHS-1 | B-1 | S-1 |
| Example 4 | 0.5 | 1.5 | 30.0 |

The following resist base material (component (A)) was used in Comparative Example 4.

PHS-1: polyhydroxystyrene Mw=8000 (Sigma-Aldrich)

The following optically active compound (B) was used.

B-1: naphthoquinonediazide-based sensitizing agent having the following chemical structural formula (G) (4NT-300, Toyo Gosei Co., Ltd.)

The following solvent was used.

S-1: propylene glycol monomethyl ether (Tokyo Kasei Kogyo Co., Ltd.)

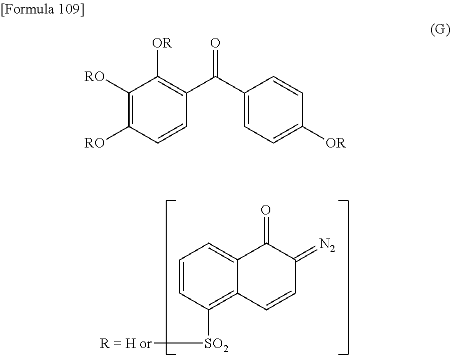

### (Evaluation of Resist Performance of Radiation-Sensitive Composition)

A clean silicon wafer was spin coated with the radiation-sensitive composition obtained as described above, and then prebaked (PB) before exposure in an oven of 110° C. to form a resist film with a thickness of 200 nm. The resist film was exposed to ultraviolet using an ultraviolet exposure apparatus (mask aligner MA-10 manufactured by Mikasa Co., Ltd.). The ultraviolet lamp used was a super high pressure mercury lamp (relative intensity ratio: g-ray:h-ray:i-ray:j-ray=100:80:90:60). After irradiation, the resist film was heated at 110° C. for 90 seconds, and immersed in a 2.38% by mass TMAH alkaline developing solution for 60 seconds for development. Subsequently, the resist film was washed with ultrapure water for 30 seconds, and dried to form a 5 μm positive type resist pattern.

The obtained line and space were observed in the formed resist pattern by a scanning electron microscope (S-4800 manufactured by Hitachi High-Technologies Corporation). As for the line edge roughness, a pattern having asperities of less than 50 nm was evaluated to be good.

In the case of using the radiation-sensitive composition according to each of Examples 13 to 18, a good resist pattern with a resolution of 5 μm was able to be obtained. The roughness of the pattern was also small and good.

On the other hand, in the case of using the radiation-sensitive composition according to Comparative Example 4, a good resist pattern with a resolution of 5 μm was able to be obtained. However, the roughness of the pattern was large and poor.

As described above, it was found that each of the radiation-sensitive compositions according to Examples 13 to 18 can form a resist pattern that has small roughness and a good shape, as compared with the radiation-sensitive composition according to Comparative Example 4. As long as the above requirements of the present embodiment are met, radiation-sensitive compositions other than those described in Examples also exhibit the same effects.

Each of the resins obtained in Synthesis Examples 1 to 6-1 has a relatively low molecular weight and a low viscosity. As such, it was evaluated that the embedding properties and film surface flatness of underlayer film forming materials for lithography containing these compounds or resins can be relatively advantageously enhanced. Furthermore, each of these compounds or resins has a thermal decomposition temperature of 150° C. or higher (evaluation A) and has high heat resistance, so that it was evaluated that they can be used even under high temperature baking conditions. In order to confirm these points, the following evaluation was performed assuming the application to the underlayer film.

### Examples 19 to 24 and Comparative Examples 5 to 6

### (Preparation of Composition for Underlayer Film Formation for Lithography)

Compositions for underlayer film formation for lithography were prepared according to the composition shown in Table 4. Next, a silicon substrate was spin coated with each of these compositions for underlayer film formation for lithography, and then baked at 240° C. for 60 seconds and further at 400° C. for 120 seconds to prepare each underlayer film having a film thickness of 200 nm. The following acid generating agent, crosslinking agent, and organic solvent were used.

Acid generating agent: di-tertiary butyl diphenyliodonium nonafluoromethanesulfonate (DTDPI) manufactured by Midori Kagaku Co., Ltd.

Crosslinking agent: NIKALAC MX270 (NIKALAC) (Sanwa Chemical Co., Ltd.)

Organic solvent: propylene glycol monomethyl ether acetate (PGMEA)

Novolac: PSM4357 manufactured by Gunei Chemical Industry Co., Ltd.

Next, etching test was conducted under conditions shown below to evaluate etching resistance. The evaluation results are shown in Table 4.

### [Etching Test]

Etching apparatus: RIE-10NR manufactured by Samco International, Inc.

Output: 50 W

Pressure: 20 Pa

Time: 2 min

Etching gas

Ar gas flow rate:CF₄ gas flow rate:O₂ gas flow rate=50:5:5 (sccm)

### (Evaluation of Etching Resistance)

The evaluation of etching resistance was conducted by the following procedures. First, an underlayer film of novolac was prepared under the same conditions as described above except that novolac (PSM4357 manufactured by Gunei Chemical Industry Co., Ltd.) was used. This underlayer film of novolac was subjected to the above etching test, and the etching rate was measured.

Next, underlayer films of Examples 19 to 24 and Comparative Examples 5 to 6 were prepared under the same conditions as the novolac underlayer films and subjected to the etching test described above in the same way as above, and the etching rate was measured. The etching resistance was evaluated according to the following evaluation criteria on the basis of the etching rate of the underlayer film of novolac.

### [Evaluation Criteria]

A: The etching rate was less than −20% as compared with the underlayer film of novolac.

B: The etching rate was −20% to 0% as compared with the underlayer film of novolac.

C: The etching rate was more than +0% as compared with the underlayer film of novolac.

TABLE 4

| | | | Acid | Cross- | |
|---|---|---|---|---|---|
| | Resin | | generating | linking | |
| | (parts | Solvent | agent | agent | Etching |
| | by | (parts by | (parts by | (parts by | resist- |
| | mass) | mass) | mass) | mass) | ance |
| Example | R-DHN | Cyclohexanone | DTDPI | NIKALAC | A |
| 19 | (10) | (90) | (0.5) | (0.5) | |
| Example | R-BiF | PGMEA | DTDPI | NIKALAC | A |
| 20 | (10) | (90) | (0.5) | (0.5) | |
| Example | RBisN-1 | PGMEA | DTDPI | NIKALAC | A |
| 21 | (10) | (90) | (0.5) | (0.5) | |
| Example | RBisN-2 | PGMEA | DTDPI | NIKALAC | A |
| 22 | (10) | (90) | (0.5) | (0.5) | |
| Example | RBiF-1 | PGMEA | DTDPI | NIKALAC | A |
| 23 | (10) | (90) | (0.5) | (0.5) | |
| Example | RDB-1 | PGMEA | DTDPI | NIKALAC | A |
| 24 | (10) | (90) | (0.5) | (0.5) | |
| Com- | CR-1 | PGMEA | DTDPI | NIKALAC | C |
| parative | (10) | (90) | (0.5) | (0.5) | |
| Example | | | | | |
| 5 | | | | | |
| Com- | NBisN-2 | PGMEA | DTDPI | NIKALAC | B |
| parative | (10) | (90) | (0.5) | (0.5) | |
| Example | | | | | |
| 6 | | | | | |

It was found that an excellent etching rate is exerted in Examples 19 to 24 as compared with the underlayer film of novolac and the resin of Comparative Example 5 to 6. On the other hand, it was found that an etching rate is poor in the resin of Comparative Example 5 or Comparative Example 6 as compared with the underlayer film of novolac.

### Examples 25 to 30 and Comparative Example 7

Next, a SiO₂ substrate having a film thickness of 80 nm and a line and space pattern of 60 nm was coated with each of the compositions for underlayer film formation for lithography used in Examples 19 to 24 and Comparative Example 5, and baked at 240° C. for 60 seconds to form a 90 nm underlayer film.

### (Evaluation of Embedding Properties)

The embedding properties were evaluated by the following procedures. The cross section of the film obtained under the above conditions was cut out and observed under an electron microscope to evaluate the embedding properties. The evaluation results are shown in Table 5.

### [Evaluation Criteria]

A: The underlayer film was embedded without defects in the asperities of the SiO₂ substrate having a line and space pattern of 60 nm.

C: The asperities of the SiO₂ substrate having a line and space pattern of 60 nm had defects which hindered the embedding of the underlayer film.

TABLE 5

| | Underlayer film forming | Resin | |
|---|---|---|---|
| | composition for | (parts by | Embedding |
| | lithography | mass) | properties |
| Example 25 | Example 19 | R-DHN | A |
| Example 26 | Example 20 | R-BiF | A |
| Example 27 | Example 21 | RBisN-1 | A |
| Example 28 | Example 22 | RBisN-2 | A |
| Example 29 | Example 23 | RBiF-1 | A |
| Example 30 | Example 24 | RDB-1 | A |
| Comparative | Comparative | CR-1 | C |
| Example 7 | Example 5 | | |

It was found that embedding properties are good in Examples 25 to 30. On the other hand, it was found that defects are seen in the asperities of the SiO₂ substrate and embedding properties are poor in Comparative Example 7.

### Examples 31 to 36

Next, a SiO₂ substrate having a film thickness of 300 nm was coated with each composition for underlayer film formation for lithography used in Examples 19 to 24, and baked at 240° C. for 60 seconds and further at 400° C. for 120 seconds to form an underlayer film having a film thickness of 85 nm. This underlayer film was coated with a resist solution for ArF and baked at 130° C. for 60 seconds to form a photoresist layer having a film thickness of 140 nm.

The ArF resist solution used was prepared by containing 5 parts by mass of a compound of the formula (16) given below, 1 part by mass of triphenylsulfonium nonafluoromethanesulfonate, 2 parts by mass of tributylamine, and 92 parts by mass of PGMEA.

The compound of the following formula (16) was prepared as follows. That is, 4.15 g of 2-methyl-2-methacryloyloxyadamantane, 3.00 g of methacryloyloxy-γ-butyrolactone, 2.08 g of 3-hydroxy-1-adamantyl methacrylate, and 0.38 g of azobisisobutyronitrile were dissolved in 80 mL of tetrahydrofuran to prepare a reaction solution. This reaction solution was polymerized for 22 hours with the reaction temperature kept at 63° C. in a nitrogen atmosphere. Then, the reaction solution was added dropwise into 400 mL of n-hexane. The product resin thus obtained was solidified and purified, and the resulting white powder was filtered and dried overnight at 40° C. under reduced pressure to obtain a compound represented by the following formula (16).

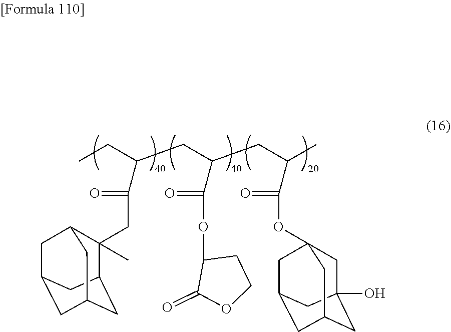

wherein 40, 40, and 20 represent the ratio of each constituent unit and do not represent a block copolymer.

Subsequently, the photoresist layer was exposed using an electron beam lithography system (manufactured by ELIONIX INC.; ELS-7500, 50 keV), baked (PEB) at 115° C. for 90 seconds, and developed for 60 seconds in a 2.38% by mass tetramethylammonium hydroxide (TMAH) aqueous solution to obtain a positive type resist pattern.

### Comparative Example 8

The same operations as in Example 31 were performed except that no underlayer film was formed so that a photoresist layer was formed directly on a SiO₂ substrate to obtain a positive type resist pattern.

### [Evaluation]

Concerning each of Examples 31 to 36 and Comparative Example 8, the shapes of the obtained 45 nm L/S (1:1) and 80 nm L/S (1:1) resist patterns were observed under an electron microscope manufactured by Hitachi, Ltd. (S-4800). The shapes of the resist patterns after development were evaluated as goodness when having good rectangularity without pattern collapse, and as poorness if this was not the case. The smallest line width having good rectangularity without pattern collapse as a result of this observation was used as an index for resolution evaluation. The smallest electron beam energy quantity capable of lithographing good pattern shapes was used as an index for sensitivity evaluation. The results are shown in Table 6.

TABLE 6

| | Underlayer film | | | |
|---|---|---|---|---|
| | forming | | | Resist pattern |
| | composition for | Resolution | Sensitivity | shape after |
| | lithography | (nmL/S) | (μC/cm²) | development |
| Example 31 | Example 19 | 55 | 15 | Good |
| Example 32 | Example 20 | 55 | 10 | Good |
| Example 33 | Example 21 | 50 | 15 | Good |
| Example 34 | Example 22 | 50 | 15 | Good |
| Example 35 | Example 23 | 55 | 10 | Good |
| Example 36 | Example 24 | 60 | 10 | Good |
| Comparative | None | 81 | 25 | Poor |
| Example 8 | | | | |

As is evident from Table 6, the resist pattern of Examples 31 to 36 was confirmed to be significantly superior in both resolution and sensitivity to Comparative Example 8. Also, the resist pattern shapes after development were confirmed to have good rectangularity without pattern collapse. The difference in the resist pattern shapes after development indicated that the underlayer film forming material for lithography of Examples 31 to 36 has good adhesiveness to a resist material.

### Example 37

A SiO₂ substrate having a film thickness of 300 nm was coated with the composition for underlayer film formation for lithography used in Example 19, and baked at 240° C. for 60 seconds and further at 400° C. for 120 seconds to form an underlayer film having a film thickness of 90 nm. This underlayer film was coated with a silicon-containing intermediate layer material and baked at 200° C. for 60 seconds to form an intermediate layer film having a film thickness of 35 nm. This intermediate layer film was further coated with the above resist solution for ArF and baked at 130° C. for 60 seconds to form a photoresist layer having a film thickness of 150 nm. The silicon-containing intermediate layer material used was the silicon atom-containing polymer described in <Synthesis Example 1> of Japanese Patent Laid-Open No. 2007-226170.

Subsequently, the photoresist layer was mask exposed using an electron beam lithography system (manufactured by ELIONIX INC.; ELS-7500, 50 keV), baked (PEB) at 115° C. for 90 seconds, and developed for 60 seconds in 2.38% by mass tetramethylammonium hydroxide (TMAH) aqueous solution to obtain a 45 nm L/S (1:1) positive type resist pattern.

Then, the silicon-containing intermediate layer film (SOG) was dry etched with the obtained resist pattern as a mask using RIE-10NR manufactured by Samco International, Inc. Subsequently, dry etching of the underlayer film with the obtained silicon-containing intermediate layer film pattern as a mask and dry etching of the SiO₂ film with the obtained underlayer film pattern as a mask were performed in order.

Respective etching conditions are as shown below.

Conditions for etching of resist intermediate layer film with resist pattern

Output: 50 W

Pressure: 20 Pa

Time: 1 min

Etching gas

Ar gas flow rate:CF₄ gas flow rate:O₂ gas flow rate=50:8:2 (sccm)

Conditions for etching of resist underlayer film with resist intermediate film pattern

Output: 50 W

Pressure: 20 Pa

Time: 2 min

Etching gas

Ar gas flow rate:CF₄ gas flow rate:O₂ gas flow rate=50:5:5 (sccm)

Conditions for etching of SiO₂ film with resist underlayer film pattern

Output: 50 W

Pressure: 20 Pa

Time: 2 min

Etching gas

Ar gas flow rate: C₅F₁₂ gas flow rate:C₂F₆ gas flow rate:O₂ gas flow rate=50:4:3:1 (sccm)

[Evaluation]

The pattern cross section (the shape of the SiO₂ film after etching) of Example 37 obtained as described above was observed under an electron microscope manufactured by Hitachi, Ltd. (S-4800). As a result, it was confirmed that the shape of the SiO₂ film after etching in a multilayer resist process is a rectangular shape in Examples using the underlayer film of the present invention and is good without defects.

### <Characteristic Evaluation of Resin Film (Resin Single Film)>

### <Preparation of Resin Film>

### Example A01

Using PGMEA as a solvent, the resin R-DHN of Synthesis Example 1 was dissolved to prepare a resin solution having a solid content concentration of 10% by mass (resin solution of Example A01).

The prepared resin solution was formed on a 12 inch silicon wafer using a spin coater Lithius Pro (manufactured by Tokyo Electron Limited), and after forming a film while adjusting the number of revolutions so as to have a film thickness of 200 nm, the baking was performed under the condition of a baking temperature of 250° C. for 1 minute to prepare a substrate on which a film made of the resin of Synthesis Example 1 was laminated. The prepared substrate was further baked under the condition of 350° C. for 1 minute using a hot plate capable of treating at a high temperature to obtain a cured resin film. At this time, when the change in film thickness before and after immersing the obtained cured resin film in the PGMEA tank for 1 minute was 3% or less, it was determined that the film was cured. When the curing was determined to be insufficient, the curing temperature was changed by 50° C. to investigate the curing temperature, and baking for curing was performed under the condition of the lowest temperature in the curing temperature range.

### <Optical Characteristic Values Evaluation>

The prepared resin film was evaluated for optical characteristic values (refractive index n and extinction coefficient k as optical constants) using spectroscopic ellipsometry VUV-VASE (manufactured by J.A. Woollam).

### Examples A02 to A12 and Comparative Example A01

The resin film was prepared in the same manner as in Example A01 except that the resins used were changed from R-DHN to the resins shown in Table 7, and the optical characteristic values were evaluated.

TABLE 7

| | | Optical characteristic values | |
|---|---|---|---|
| | Resin used | n | k |
| Example A01 | R-DHN | 1.22 | 0.27 |
| Example A02 | R-2,6-DHN | 1.22 | 0.27 |
| Example A03 | R-2,7-DHN | 1.22 | 0.27 |
| Example A04 | R-2,3-DHN | 1.22 | 0.27 |
| Example A05 | R-1,5-DHN | 1.22 | 0.25 |
| Example A06 | R-1,6-DHN | 1.22 | 0.23 |
| Example A07 | R-1,7-DHN | 1.22 | 0.23 |
| Example A08 | R-DHN-A1 | 1.30 | 0.28 |
| Example A09 | R-DHN-A2 | 1.30 | 0.26 |
| Example A10 | R-DHN-B1 | 1.22 | 0.26 |
| Example A11 | R-DHN-B2 | 1.22 | 0.25 |
| Example Al2 | R-FLBNDHN | 1.28 | 0.48 |
| Comparative | CR-1 | 1.35 | 0.61 |
| Example A01 | | | |

From the results of Examples A01 to A12, it was found that a polymer film having a low n-value and a low k-value at wavelengths 193 nm used in ArF exposure can be formed by the composition for film formation containing the polycyclic polyphenolic resin according to the present embodiment.

### <Heat Resistance Evaluation of Cured Film>

### Example B01

The heat resistance of the resin film prepared in Example A01 was evaluated by using a lamp annealing oven. For the conditions for heat resistance treatment, the heat treatment was continued at 450° C. under a nitrogen atmosphere, and the film thickness change rate was obtained during the elapsed time of 4 minutes and 10 minutes from the start of heating. The heating was continued at 550° C. under a nitrogen atmosphere, and the film thickness change rate was obtained during the elapsed time of 4 minutes and 550° C. 10 minutes from the start of heating. These film thickness change rates were evaluated as indicators of the heat resistance of the cured film. The film thicknesses before and after the heat resistance test were measured by an interference film thickness meter, and a ratio of the fluctuation value of the film thickness to the film thickness before the heat resistance test treatment was defined as a film thickness change rate (%).

### Examples B02 to B20, Reference Example B01, and Comparative Examples B01 to B02

Heat resistance was evaluated in the same manner as in Example B01 except that the resins used were changed from R-DHN to the resins shown in Table 8.

TABLE 8

| | | Cured film heat resistance Film | |
|---|---|---|---|
| | | thickness change rate (%) | |
| | Resin used | 450° C. | 550° C. |
| Example B01 | R-DHN | 2.3 | 5.4 |
| Example B02 | R-2,6-DHN | 2.2 | 5.6 |
| Example B03 | R-2,7-DHN | 2.5 | 6.1 |
| Example B04 | R-2,3-DHN | 2.3 | 5.8 |
| Example B05 | R-1,5-DHN | 2.1 | 5.5 |
| Example B06 | R-1,6-DHN | 1.9 | 4.7 |
| Example B07 | R-1,7-DHN | 2.0 | 5.1 |
| Example B08 | R-HN-A1 | 2.5 | 6.5 |
| Example B09 | R-HN-A2 | 2.6 | 6.8 |
| Example B10 | R-DHN-B1 | 2.2 | 5.8 |
| Example B11 | R-DHN-B2 | 2.3 | 6.1 |
| Example B12 | R-BiF | 4.6 | 9.6 |
| Example B13 | R-BisN-1 | 4.3 | 8.8 |
| Example B14 | R-BisN-2 | 1.9 | 5.3 |
| Example B15 | R-BisN-3 | 1.5 | 4.8 |
| Example B16 | R-BisN-4 | 1.4 | 4.9 |
| Example B17 | RBiF-1 | 3.4 | 9.5 |
| Example B18 | RBiF-2 | 3.6 | 11.2 |
| Example B19 | RDB-1 | 1.4 | 5.1 |
| Example B20 | R-FLBNDHN | 1.6 | 4.8 |
| Reference | R-NFA01 | 5.8 | 12.4 |
| Example B01 | | | |
| Comparative | CR-1 | 15.8 | 51.2 |
| Example B01 | | | |
| Comparative | NBisN-2 | 11.8 | 31.2 |
| Example B02 | | | |

### Example C01

### <Evaluation of PE-CVD Film Formation>

A 12 inch silicon wafer was subjected to thermal oxidation treatment, and a resin film was formed on the substrate having the obtained silicon oxide film by the same method as in Example A01 using the resin solution of Example A01 with a thickness of 100 nm. A silicon oxide film having a film thickness of 70 nm was formed on the resin film using a film forming apparatus TELINDY (manufactured by Tokyo Electron Limited) and tetraethylsiloxane (TEOS) as a raw material at a substrate temperature of 300° C. The wafer with the cured film in which the prepared silicon oxide film was laminated was further subjected to defect inspection using KLA-Tencor SP-5, and the number of defects of the formed oxide film was evaluated using the number of defects of 21 nm or more as an index.

A number of defects ≤20
B 20≤number of defects ≤50
C 50≤number of defects ≤100
D 100≤number of defects ≤1000
E 1000≤number of defects ≤5000
F 5000≤number of defects

### <SiN Film>

On a cured film formed on a substrate having a silicon oxide film thermally oxidized on a 12 inch silicon wafer with a thickness of 100 nm by the same method as described above, a film forming apparatus TELINDY (manufactured by Tokyo Electron Limited) was used to form a SiN film having a thickness of 40 nm, a refractive index of 1.94, and a film stress of −54 MPa at a substrate temperature of 350° C. using SiN4 (monosilane) and ammonia as raw materials. The wafer with the cured film in which the prepared SiN film was laminated was further subjected to defect inspection using KLA-Tencor SP-5, and the number of defects of the formed oxide film was evaluated using the number of defects of 21 nm or more as an index.

A number of defects ≤20
B 20≤number of defects ≤50
C 50≤number of defects ≤100
D 100≤number of defects ≤1000
E 1000≤number of defects ≤5000
F 5000≤number of defects

### Examples C02 to C20 and Comparative Examples C01 to C02

Heat resistance was evaluated in the same manner as in Example C01 except that the resins used were changed from R-DHN to the resins shown in Table 9.

TABLE 9

| | | PE-CVD defect evaluation | |
|---|---|---|---|
| | Resin used | Oxide film | SiN |
| Example C01 | R-DHN | B | B |
| Example C02 | R-2,6-DHN | B | B |
| Example C03 | R-2,7-DHN | B | B |
| Example C04 | R-2,3-DHN | B | B |
| Example C05 | R-1,5-DHN | B | B |
| Example C06 | R-1,6-DHN | B | B |
| Example C07 | R-1,7-DHN | B | B |
| Example C08 | R-HN-A1 | B | B |
| Example C09 | R-HN-A2 | B | B |
| Example C10 | R-DHN-B1 | A | A |
| Example C11 | R-DHN-B2 | A | A |
| Example C12 | R-BiF | B | B |
| Example C13 | R-BisN-1 | B | B |
| Example C14 | R-BisN-2 | A | A |
| Example C15 | R-BisN-3 | A | A |
| Example C16 | R-BisN-4 | A | A |
| Example C17 | RBiF-1 | B | B |
| Example C18 | RBiF-2 | B | B |
| Example C19 | RDB-1 | A | A |
| Example C20 | R-FLBNDHN | B | B |
| Comparative | CR-1 | F | F |
| Example C01 | | | |
| Comparative | NBisN-2 | E | E |
| Example C02 | | | |

In the silicon oxide film or SiN film formed on the resin film of Examples C01 to C20, the number of defects of 21 nm or more was 50 or less (B or higher), which was smaller than the number of defects of Comparative Examples C01 or C02.

### Example D01

<Etching Evaluation after High Temperature Treatment>

A 12 inch silicon wafer was subjected to thermal oxidation treatment, and a resin film was formed on the substrate having the obtained silicon oxide film by the same method as in Example A01 using the resin solution of Example A01 with a thickness of 100 nm. The resin film was further annealed by heating under the condition of 600° C. for 4 minutes using a hot plate which can be further treated at a high temperature in a nitrogen atmosphere to prepare a wafer on which the annealed resin film was laminated. The prepared annealed resin film was carved out, and the carbon content was determined by elemental analysis.

Furthermore, a 12 inch silicon wafer was subjected to thermal oxidation treatment, and a resin film was formed on the substrate having the obtained silicon oxide film by the same method as in Example A01 using the resin solution of Example A01 with a thickness of 100 nm. The resin film was further annealed by heating under the condition of 600° C. for 4 minutes under a nitrogen atmosphere to form a resin film, and then the substrate was subjected to an etching treatment using an etching apparatus TELIUS (manufactured by Tokyo Electron Limited) under the conditions of using CF₄/Ar as an etching gas and Cl₂/Ar as an etching gas to evaluate an etching rate. The etching rate was evaluated by using a resin film having a film thickness of 200 nm formed by annealing SU8 (manufactured by Nippon Kayaku Co., Ltd.) at 250° C. for 1 minute as a reference and determining the ratio of the etching rate to the SU8 as a relative value.

### Examples D02 to D20, Reference Example D01, and Comparative Examples D01 to D02

Heat resistance was evaluated in the same manner as in Example D01 except that the resins used were changed from R-DHN to the resins shown in Table 10.

TABLE 10

| | | | Etching rate evaluation | |
|---|---|---|---|---|
| | | Carbon | (relative value) | |
| | | content | CF₄/ | Cl₂/ |
| | Resin used | (%) | Ar | Ar |
| Example D01 | R-DHN | 90.2% | 0.82 | 0.81 |
| Example D02 | R-2,6-DHN | 90.2% | 0.83 | 0.83 |
| Example D03 | R-2,7-DHN | 90.4% | 0.80 | 0.82 |
| Example D04 | R-2,3-DHN | 90.5% | 0.79 | 0.82 |
| Example D05 | R-1,5-DHN | 90.4% | 0.81 | 0.80 |
| Example D06 | R-1,6-DHN | 90.3% | 0.82 | 0.82 |
| Example D07 | R-1,7-DHN | 90.3% | 0.82 | 0.83 |
| Example D08 | R-DHN-A1 | 90.5% | 0.78 | 0.79 |
| Example D09 | R-DHN-A2 | 90.5% | 0.78 | 0.79 |
| Example D10 | R-DHN-B1 | 90.3% | 0.83 | 0.77 |
| Example D11 | R-DHN-B2 | 90.4% | 0.81 | 0.80 |
| Example D12 | R-BiF | 91.2% | 0.74 | 0.77 |
| Example D13 | R-BisN-1 | 91.3% | 0.76 | 0.77 |
| Example D14 | R-BisN-2 | 91.6% | 0.72 | 0.73 |
| Example D15 | R-BisN-3 | 91.8% | 0.71 | 0.72 |
| Example D16 | R-BisN-4 | 91.9% | 0.70 | 0.70 |
| Example D17 | RBiF-1 | 90.3% | 0.82 | 0.81 |
| Example D18 | RBiF-2 | 91.2% | 0.77 | 0.81 |
| Example D19 | RDB-1 | 91.8% | 0.70 | 0.70 |
| Example D20 | R-FLBNDHN | 90.2% | 0.82 | 0.81 |
| Reference | R-NFA01 | 86.2% | 0.92 | 0.91 |
| Example D01 | | | | |
| Comparative | CR-1 | 78.2% | 0.98 | 0.98 |
| Example D01 | | | | |
| Comparative | NBisN-2 | 79.7% | 0.95 | 0.95 |
| Example D02 | | | | |

### <Evaluation of Etching Defects on Laminated Film>

The polycyclic polyphenolic resin obtained in Synthesis Example was subjected to quality evaluation before and after the purification treatment. That is, the resin film formed on the wafer using the polycyclic polyphenolic resin was transferred to the substrate side by etching, and then subjected to defect evaluation to evaluate.

A 12-inch silicon wafer was subjected to thermal oxidation treatment to obtain a substrate having a silicon oxide film having a thickness of 100 nm. The resin solution of the polycyclic polyphenolic resin was formed on the substrate by adjusting the spin coating conditions so as to have a thickness of 100 nm, followed by baking at 150° C. for 1 minute, and then baking at 350° C. for 1 minute to prepare a laminated substrate in which the polycyclic polyphenolic resin was laminated on silicon with a thermal oxide film.

Using TELIUS (manufactured by Tokyo Electron Limited) as an etching apparatus, the resin film was etched under the condition of CF₄/O₂/Ar to expose the substrate on the surface of the oxide film. Further, an etching treatment was performed under the condition that the oxide film was etched by 100 nm at the gas composition ratio of CF₄/Ar to prepare an etched wafer.

The prepared etched wafer was measured for the number of defects of 19 nm or more with a defect inspection device SP5 (manufactured by KLA-tencor), and was subjected to defect evaluation by etching treatment of the laminated film.

### (Example E01) Purification of R-DHN-B1 with Acid

In a four necked flask (capacity: 1000 mL, with a detachable bottom), 150 g of a solution (10% by mass) formed by dissolving R-DHN obtained in Synthesis Working Example 1 in PGMEA was charged, and was heated to 80° C. with stirring. Then, 37.5 g of an aqueous oxalic acid solution (pH 1.3) was added thereto, and the resultant mixture was stirred for 5 minutes and then left to stand still for 30 minutes. This separated the mixture into an oil phase and an aqueous phase, and the aqueous phase was thus removed. After repeating this operation once, 37.5 g of ultrapure water was charged to the obtained oil phase, and after stirring for 5 minutes, the mixture was left to stand still for 30 minutes and the aqueous phase was removed. After repeating this operation three times, the residual water and PGMEA were concentrated and distilled off by heating to 80° C. and reducing the pressure in the flask to 200 hPa or less. Then, by diluting with PGMEA of EL grade (a reagent manufactured by Kanto Chemical Co., Inc.) such that the concentration of the PGMEA solution was adjusted to 10% by mass, a PGMEA solution of R-DHN with a reduced metal content was obtained. The polycyclic polyphenolic resin solution thus prepared was filtered with a UPE filter having a nominal pore size of 3 nm, manufactured by Entegris Japan Co., Ltd., under a condition of 0.5 MPa, to prepare a solution sample, and then etching defect evaluation on the laminated film was carried out.

### (Example E02) Purification of RBisN-2 with Acid

In a four necked flask (capacity: 1000 mL, with a detachable bottom), 140 g of a solution (10% by mass) formed by dissolving RBisN-2 obtained in Synthesis Working Example 4-1 in PGMEA was charged, and was heated to 60° C. with stirring. Then, 37.5 g of an aqueous oxalic acid solution (pH 1.3) was added thereto, and the resultant mixture was stirred for 5 minutes and then left to stand still for 30 minutes. This separated the mixture into an oil phase and an aqueous phase, and the aqueous phase was thus removed. After repeating this operation once, 37.5 g of ultrapure water was charged to the obtained oil phase, and after stirring for 5 minutes, the mixture was left to stand still for 30 minutes and the aqueous phase was removed. After repeating this operation three times, the residual water and PGMEA were concentrated and distilled off by heating to 80° C. and reducing the pressure in the flask to 200 hPa or less. Then, by diluting with PGMEA of EL grade (a reagent manufactured by Kanto Chemical Co., Inc.) such that the concentration of the PGMEA solution was adjusted to 10% by mass, a PGMEA solution of RBisN-2 with a reduced metal content was obtained. The polycyclic polyphenolic resin solution thus prepared was filtered with a UPE filter having a nominal pore size of 3 nm, manufactured by Entegris Japan Co., Ltd., under a condition of 0.5 MPa, to prepare a solution sample, and then etching defect evaluation on the laminated film was carried out.

### (Example E03) Purification by Passing Through Filter

In a class 1000 clean booth, 500 g of a solution of 10% by mass concentration of the resin (R-DHN) obtained in Synthesis Example 1 dissolved in propylene glycol monomethyl ether (PGME) was charged in a four necked flask (capacity: 1000 mL, with a detachable bottom), and then the air inside the flask was depressurized and removed, nitrogen gas was introduced to return it to atmospheric pressure, and the oxygen concentration inside was adjusted to less than 1% under the ventilation of 100 mL of nitrogen gas per minute, and the flask was heated to 30° C. with stirring. The solution was drawn out from the bottom-vent valve, and passed through a pressure tube made of fluororesin through a diaphragm pump at a flow rate of 100 mL per minute to a hollow fiber membrane filter (manufactured by KITZ MICRO FILTER CORPORATION, product name: Polyfix Nylon Series) made of nylon with a nominal pore size of 0.01 μm under a filtration pressure of 0.5 MPa by pressure filtration. By diluting the resin solution after filtration with PGMEA of EL grade (a reagent manufactured by Kanto Chemical Co., Inc.) such that the concentration of the PGMEA solution was adjusted to 10% by mass, a PGMEA solution of R-DHN with a reduced metal content was obtained. The polycyclic polyphenolic resin solution thus prepared was filtered with a UPE filter having a nominal pore size of 3 nm, manufactured by Entegris Japan Co., Ltd., under a condition of 0.5 MPa, to prepare a solution sample, and then etching defect evaluation on the laminated film was carried out. The oxygen concentration was measured with an oxygen concentration meter “OM-25MF10” manufactured by AS ONE Corporation (the same applies hereinafter).

### Example E04

As the purification step by the filter, IONKLEEN manufactured by Pall Corporation, a nylon filter manufactured by Pall Corporation, and a UPE filter with a nominal pore size of 3 nm manufactured by Entegris Japan Co., Ltd. were connected in series in this order to construct a filter line. In the same manner as in Example E03, except that the prepared filter line was used instead of the 0.1 μm hollow fiber membrane filter made of nylon, the solution was passed by pressure filtration so that the conditions of the filtration pressure was 0.5 MPa. By diluting with PGMEA of EL grade (a reagent manufactured by Kanto Chemical Co., Inc.) such that the concentration of the PGMEA solution was adjusted to 10% by mass, a PGMEA solution of R-DHN with a reduced metal content was obtained. The polycyclic polyphenolic resin solution thus prepared was subjected to pressure filtration with a UPE filter having a nominal pore size of 3 nm, manufactured by Entegris Japan Co., Ltd., under a condition of the filtration pressure of 0.5 MPa, to prepare a solution sample, and then etching defect evaluation on the laminated film was carried out.

### Example E05

The solvent sample prepared in Example E01 was further subjected to pressure filtration with the filter line prepared in Example E04 under a condition of the filtration pressure of 0.5 MPa, to prepare a solution sample, and then etching defect evaluation on the laminated film was carried out.

### Example E06

For the RBisN-4 prepared in (Synthesis Example 4-3), a solution sample purified by the same method as in Example E05 was prepared, and then an etching defect evaluation on the laminated film was carried out.

### Example E06

For the R-FLBNDHN prepared in (Synthesis Example 1-7), a solution sample purified by the same method as in Example E05 was prepared, and then an etching defect evaluation on the laminated film was carried out.

TABLE 11

| | | PE-CVD defect evaluation | |
|---|---|---|---|
| | Resin used | Oxide film | Oxide film |
| Example E01 | R-DHN | A | A |
| Example E02 | R-2,6-DHN | A | A |
| Example E03 | R-2,7-DHN | A | A |
| Example E04 | R-2,3-DHN | A | A |
| Example E05 | R-1,5-DHN | A | A |
| Example E06 | R-1,6-DHN | A | A |
| Example E07 | R-1,7-DHN | A | A |

### Examples 38 to 43

A SiO₂ substrate having a film thickness of 300 nm was coated with the optical component forming composition having the same composition as that of the solution of the underlayer film forming material for lithography prepared in each of the above Examples 19 to 24 and Comparative Example 5, and baked at 260° C. for 300 seconds to form each film for optical components with a film thickness of 100 nm. Then, tests for the refractive index and the transparency at a wavelength of 633 nm were carried out by using a vacuum ultraviolet with variable angle spectroscopic ellipsometer (VUV-VASE) manufactured by J.A. Woollam Japan, and the refractive index and the transparency were evaluated according to the following criteria. The evaluation results are shown in Table 7.

### [Evaluation Criteria for Refractive Index]

A: the refractive index is 1.65 or more
C: the refractive index is less than 1.65

### [Evaluation Criteria for Transparency]

A: The absorption coefficient is less than 0.03.
C: The absorption coefficient is 0.03 or more.

TABLE 12

| | Optical member forming | Refractive | |
|---|---|---|---|
| | composition | index | Transparency |
| Example 38 | Same composition as Example 19 | A | A |
| Example 39 | Same composition as Example 20 | A | A |
| Example 40 | Same composition as Example 21 | A | A |
| Example 41 | Same composition as Example 22 | A | A |
| Example 42 | Same composition as Example 23 | A | A |
| Example 43 | Same composition as Example 24 | A | A |
| Comparative | Same composition as Comparative | C | C |
| Example 9 | Example 5 | | |

It was found that the optical member forming compositions of Examples 38 to 43 not only had a high refractive index but also a low absorption coefficient and excellent transparency. On the other hand, it was found that the composition of Comparative Example 9 was inferior in performance as an optical member.

The present application claims the priority based on the Japanese patent application (Japanese Patent Application No. 2019-003567) filed on Jan. 11, 2019, the contents of which are incorporated herein by reference.

### INDUSTRIAL APPLICABILITY

The present invention has industrial applicability as a composition that can be used in optical members, photoresist components, resin raw materials for materials for electric or electronic components, raw materials for curable resins such as photocurable resins, resin raw materials for structural materials, or resin curing agents, etc.

1. A composition for film formation comprising a polycyclic polyphenolic resin having repeating units derived from at least one monomer selected from the group consisting of aromatic hydroxy compounds represented by the following formulae (1A) and (1B),
wherein the repeating units are linked to each other by a direct bond between aromatic rings: 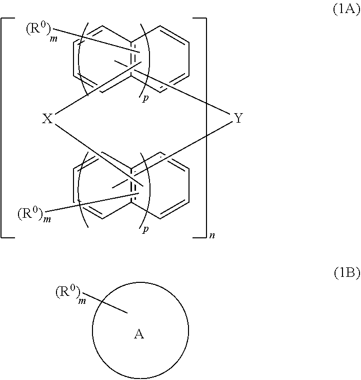
wherein X represents an oxygen atom, a sulfur atom, a single bond, or non-crosslinked state and Y represents a 2n-valent group having 1 to 60 carbon atoms, or a single bond, wherein when X is non-crosslinked state, Y represents the 2n-valent group; A represents a benzene ring or a fused ring; each R⁰ is independently an alkyl group having 1 to 40 carbon atoms and optionally having a substituent, an aryl group having 6 to 40 carbon atoms and optionally having a substituent, an alkenyl group having 2 to 40 carbon atoms and optionally having a substituent, an alkynyl group having 2 to 40 carbon atoms, an alkoxy group having 1 to 40 carbon atoms and optionally having a substituent, a halogen atom, a thiol group, or a hydroxy group, wherein at least one R⁰ is a hydroxy group, and each m is independently an integer of 1 to 9; and n is an integer of 1 to 4, and each p is independently an integer of 0 to 3.

2. The composition for film formation according to claim 1, wherein the aromatic hydroxy compound represented by the formula (1A) is an aromatic hydroxy compound represented by the following formula (1): 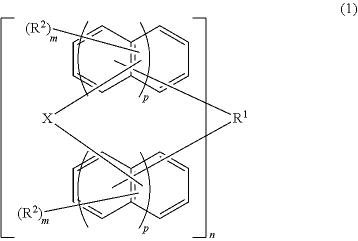
wherein X, m, n, and p are as defined in the formula (1A), R¹ is as defined in Y in the formula (1A), and each R² is independently an alkyl group having 1 to 40 carbon atoms, an aryl group having 6 to 40 carbon atoms, an alkenyl group having 2 to 40 carbon atoms, an alkoxy group having 1 to 40 carbon atoms, a halogen atom, a thiol group, or a hydroxy group, wherein at least one R² is a hydroxy group.

3. The composition for film formation according to claim 2, wherein the aromatic hydroxy compound represented by the formula (1) is an aromatic hydroxy compound represented by the following formula (1-1): 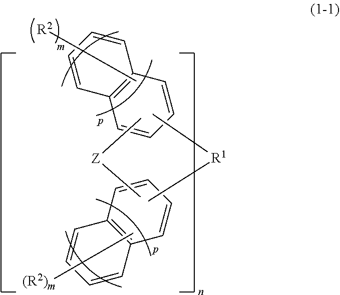
wherein Z represents an oxygen atom or a sulfur atom, and R¹, R², m, p and n are as defined in the formula (1).

4. The composition for film formation according to claim 3, wherein the aromatic hydroxy compound represented by the formula (1-1) is an aromatic hydroxy compound represented by the following formula (1-2): 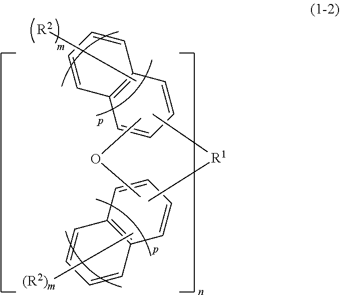
wherein R¹, R², m, p and n are as defined in the formula (1).

5. The composition for film formation according to claim 4, wherein the aromatic hydroxy compound represented by the formula (1-2) is an aromatic hydroxy compound represented by the following formula (1-3): 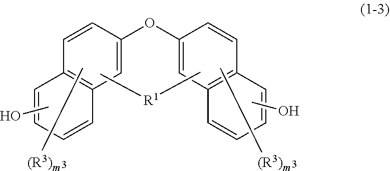
wherein R¹ is as defined in the formula (1), each R³ is independently an alkyl group having 1 to 40 carbon atoms, an aryl group having 6 to 40 carbon atoms, an alkenyl group having 2 to 40 carbon atoms, an alkoxy group having 1 to 40 carbon atoms, a halogen atom, or a thiol group, and each m³ is independently an integer of 0 to 5.

6. The composition for film formation according to claim 1, wherein the aromatic hydroxy compound represented by the formula (1A) is an aromatic hydroxy compound represented by the following formula (2): 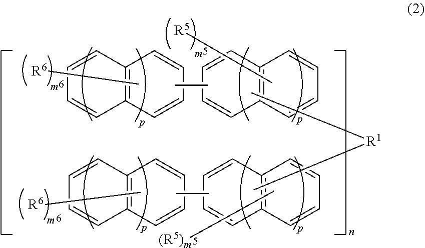
wherein R¹ is as defined in Y in the formula (1A), R⁵, n, and p are as defined in the formula (1A), each R⁶ is independently a hydrogen atom, an alkyl group having 1 to 34 carbon atoms, an aryl group having 6 to 34 carbon atoms, an alkenyl group having 2 to 34 carbon atoms, an alkoxy group having 1 to 34 carbon atoms, a halogen atom, a thiol group, or a hydroxy group, each m⁵ is independently an integer of 1 to 6, each m⁶ is independently an integer of 1 to 7, wherein at least one R⁵ is a hydroxy group.

7. The composition for film formation according to claim 6, wherein the aromatic hydroxy compound represented by the formula (2) is an aromatic hydroxy compound represented by the following formula (2-1): 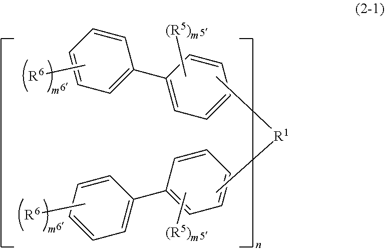
wherein R¹, R⁵, R⁶, and n are as defined in the formula (2), each m^{5′} is independently an integer of 1 to 4, and each m^{6′} is independently an integer of 1 to 5, wherein at least one R⁵ is a hydroxy group.

8. The composition for film formation according to claim 7, wherein the aromatic hydroxy compound represented by the formula (2-1) is an aromatic hydroxy compound represented by the following formula (2-2): 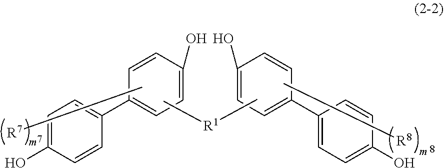
wherein R¹ is as defined in the formula (2), R⁷ and R⁸ are independently a hydrogen atom, an alkyl group having 1 to 40 carbon atoms, an aryl group having 6 to 40 carbon atoms, an alkenyl group having 2 to 40 carbon atoms, an alkoxy group having 1 to 40 carbon atoms, a halogen atom, a thiol group, or a hydroxy group, and m⁷ and m⁸ are independently an integer of 0 to 7.

9. The composition for film formation according to claim 1, wherein the polycyclic polyphenolic resin further has a modified portion derived from a crosslinking compound.

10. (canceled)

11. (canceled)

12. The composition for film formation according to claim 2, wherein R¹ is a group represented by R^{A}—R^{B}, wherein R^{A} is a methine group, and R^{B} is an aryl group having 6 to 30 carbon atoms and optionally having a substituent.

13. The composition for film formation according to claim 1, wherein A in the formula (1B) is the fused ring.

14. A resist composition comprising the composition for film formation according to claim 1

15. (canceled)

16. A method for forming a resist pattern, comprising:
forming a resist film on a substrate using the resist composition according to claim 14;
exposing at least a portion of the formed resist film; and
developing the exposed resist film, thereby forming the resist pattern.

17. A radiation-sensitive composition comprising the composition for film formation according to claim 1, an optically active diazonaphthoquinone compound, and a solvent,
wherein a content of the solvent is 20 to 99% by mass based on 100% by mass in total of the radiation-sensitive composition, and
a content of a solid content except for the solvent is 1 to 80% by mass based on 100% by mass in total of the radiation-sensitive composition.

18. (canceled)

19. (canceled)

20. (canceled)

21. A method for forming a resist pattern, comprising:
forming a resist film on a substrate using the radiation-sensitive composition according to claim 17;
exposing at least a portion of the formed resist film; and
developing the exposed resist film, thereby forming the resist pattern.

22. A composition for underlayer film formation for lithography comprising the composition for film formation according to claim 1.

23. (canceled)

24. A method for producing an underlayer film for lithography, comprising forming the underlayer film on a substrate using the composition for underlayer film formation for lithography according to claim 22.

25. A method for forming a resist pattern, comprising:
forming an underlayer film on a substrate using the composition for underlayer film formation for lithography according to claim 22;
forming at least one photoresist layer on the underlayer film; and
irradiating a predetermined region of the photoresist layer with radiation for development, thereby forming the resist pattern.

26. A method for forming a circuit pattern, comprising:
forming an underlayer film on a substrate using the composition for underlayer film formation for lithography according to claim 22;
forming an intermediate layer film on the underlayer film using a resist intermediate layer film material containing a silicon atom;
forming at least one photoresist layer on the intermediate layer film;
irradiating a predetermined region of the photoresist layer with radiation for development, thereby forming a resist pattern;
etching the intermediate layer film with the resist pattern as a mask, thereby forming an intermediate layer film pattern;
etching the underlayer film with the intermediate layer film pattern as an etching mask, thereby forming an underlayer film pattern; and
etching the substrate with the underlayer film pattern as an etching mask, thereby forming a pattern on the substrate.

27. A composition for optical member formation comprising the composition for film formation according to claim 1.

28. (canceled)
